(19) United States
(12) Patent Application Publication
(10) Pub. No.: US 2025/0143175 A1
(43) Pub. Date: May 1, 2025

(54) OPTOELECTRONIC DEVICE AND ELECTRONIC APPARATUS INCLUDING THE SAME

(71) Applicant: Samsung Display Co., Ltd., Yongin-si (KR)

(72) Inventors: Seran Kim, Yongin-si (KR); Minsoo Choi, Yongin-si (KR); Hoilim Kim, Yongin-si (KR); Seungin Baek, Yongin-si (KR); Dongsun Yoo, Yongin-si (KR); Seokgyu Yoon, Yongin-si (KR); Jinsoo Jung, Yongin-si (KR); Hyejin Jung, Yongin-si (KR); Youngeun Choi, Yongin-si (KR)

(21) Appl. No.: 18/774,780

(22) Filed: Jul. 16, 2024

(30) Foreign Application Priority Data
Oct. 27, 2023 (KR) 10-2023-0145423

(51) Int. Cl. H10K 85/60; B60K 35/10; G06V 40/13; H10K 39/34

(52) U.S. Cl. CPC H10K 85/621; H10K 85/657; H10K 85/6576; B60K 35/10; G06V 40/1318; H10K 39/34

(57) ABSTRACT

An optoelectronic device includes a first electrode, a second electrode facing the first electrode, and a photoactive layer between the first electrode and the second electrode, where the photoactive layer may include an acceptor satisfying Expression 1 and a donor having a maximum absorption wavelength of about 600 nm to about 750 nm, and Expression 2 may be satisfied:

$$3 eV \leq {E}_{LUMO}^{A} - {E}_{HOMO}^{A} \leq 4 eV \qquad Expression 1$$

$$0.05 \leq ( {E}_{LUMO}^{D} - {E}_{LUMO}^{A} ) / ( {E}_{LUMO}^{D} - {E}_{HOMO}^{D} ) \leq 0.5 . \qquad Expression 2$$

### CROSS-REFERENCE TO RELATED APPLICATION

The present application claims priority to and the benefit of Korean Patent Application No. 10-2023-0145423, filed on Oct. 27, 2023, in the Korean Intellectual Property Office, the entire content of which is incorporated herein by reference.

### BACKGROUND

### 1. Field

One or more embodiments of the present disclosure relate to an optoelectronic device and an electronic apparatus including the optoelectronic device.

### 2. Description of the Related Art

Optoelectronic devices are devices that convert optical energy and/or optical signals into electrical energy and/or electrical signals. Examples of an optoelectronic device are (1) an optical or solar cell, which converts optical energy into electrical energy, (2) an optical detector or sensor, which detects and converts optical energy into electrical signals, and/or (3) the like.

Electronic apparatuses including optoelectronic devices and light-emitting devices have been developed. Light emitted from a light-emitting device may be reflected from an object (e.g., a finger of a user) in contact with the electronic apparatus, and then incident on an optoelectronic device. As the optoelectronic device detects incident light energy and converts it into electrical signals, the contact of the object with the electronic apparatus may be recognized.

### SUMMARY

One or more aspects of embodiments of the present disclosure are directed toward an optoelectronic device and an electronic apparatus employing the optoelectronic device, the optoelectronic device having excellent or suitable external quantum efficiency by enhancing or optimizing energy relation between a donor and an acceptor included in a photoactive layer absorbing red light.

Additional aspects will be set forth in part in the description which follows and, in part, will be apparent from the description, or may be learned by practice of the presented embodiments of the disclosure.

According to one or more embodiments of the present disclosure, an optoelectronic device includes a first electrode, a second electrode facing (e.g., opposite to and facing) the first electrode, and a photoactive layer between the first electrode and the second electrode, wherein the photoactive layer may include an acceptor satisfying Expression 1 and a donor having a maximum absorption wavelength of about 600 nanometer (nm) to about 750 nm, and Expression 2 may be satisfied:

$$3 eV \leq {E}_{LUMO}^{A} - {E}_{HOMO}^{A} \leq 4 eV \qquad Expression 1$$

$$0.05 \leq ( {E}_{LUMO}^{D} - {E}_{LUMO}^{A} ) / ( {E}_{LUMO}^{D} - {E}_{HOMO}^{D} ) \leq 0.5 \qquad Expression 2$$

wherein, in Expressions 1 and 2,
E^{D}_{LUMO} represents a lowest unoccupied molecular orbital (LUMO) energy level of the donor,
E^{D}_{HOMO} represents a highest occupied molecular orbital (HOMO) energy level of the donor,
E^{A}_{LUMO} represents a LUMO energy level of the acceptor, and
E^{A}_{HOMO} represents a HOMO energy level of the acceptor.

In one or more embodiments, the donor may satisfy Expression 3:

$$1. eV \leq {E}_{LUMO}^{D} - {E}_{HOMO}^{D} \leq 2.5 eV \qquad Expression 3$$

wherein, in Expression 3,
E^{D}_{LUMO} and E^{D}_{HOMO} are each the same as described in the present disclosure.

In one or more embodiments, the optoelectronic device may further satisfy Expression 4:

$${E}_{LUMO}^{A} \leq {E}_{LUMO}^{D} \qquad Expression 4$$

wherein, in Expression 4,
E^{D}_{LUMO} and E^{A}_{LUMO} are each the same as described in the present disclosure.

In one or more embodiments, the optoelectronic device may further satisfy Expression 5:

$${E}_{HOMO}^{A} \leq {E}_{HOMO}^{D} \qquad Expression 5$$

wherein, in Expression 5,
E^{D}_{HOMO} and E^{A}_{HOMO} are each the same as described in the present disclosure.

In one or more embodiments, the acceptor may not include (e.g., may exclude) a (e.g., any) fullerene-based compound.

In one or more embodiments, the acceptor may not include (e.g., may exclude) a (e.g., any) 5-membered ring.

In one or more embodiments, the acceptor may be transparent in the visible light region (e.g., having no optical absorption band in a wavelength range of about 380 nm to about 700 nm).

In one or more embodiments, the acceptor may be represented by Formula 1:

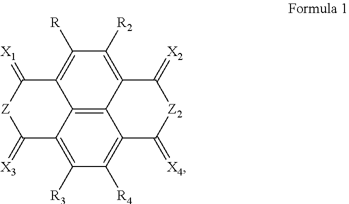

wherein the detailed description of Formula 1 is the same as described in the present disclosure.

In one or more embodiments, the acceptor may be at least one selected from among Compounds C1 to C17 described in the present disclosure.

In one or more embodiments, a maximum absorption wavelength of the donor may be about 630 nm to about 700 nm.

In one or more embodiments, the donor may not include (e.g., may exclude) boron.

In one or more embodiments, the donor may be represented by any one selected from among Formulae 2 and 3:

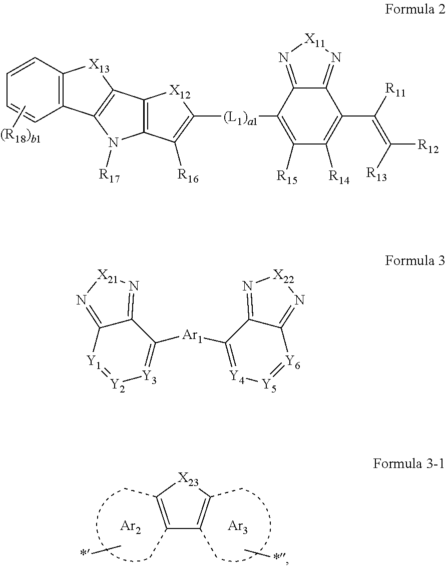

wherein, in Formula 3, Ar₁ may be a group represented by Formula 3-1, and
Formulae 2, 3, and 3-1 are each the same as described in the present disclosure.

In one or more embodiments, the donor may be at least one selected from among Compounds A1 to A32, Compounds B1 to B50, and combinations thereof, described in the present disclosure.

In one or more embodiments, the photoactive layer may be formed by vacuum deposition.

In one or more embodiments, the photoactive layer may be a single layer.

In one or more embodiments, the optoelectronic device may further include a hole transport region between the first electrode and the photoactive layer, and an electron transport region between the photoactive layer and the second electrode.

In one or more embodiments, the photoactive layer may include a first layer adjacent to the hole transport region, and a second layer adjacent to the electron transport region, wherein the first layer may include the donor, and the second layer may include the acceptor.

In one or more embodiments, the photoactive layer may further include a third layer between the first layer and the second layer, wherein the third layer may include the donor and the acceptor.

According to one or more embodiments of the present disclosure, an electronic apparatus includes the optoelectronic device and a light-emitting device including an emission layer which does not overlap with the photoactive layer.

According to one or more embodiments of the present disclosure, an electronic equipment includes the electronic apparatus, wherein

the electronic equipment may be at least one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, a signboard, and combinations thereof.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a schematic view of an electronic apparatus according to one or more embodiments of the present disclosure;

FIG. 2 is a schematic view of an electronic apparatus according to one or more embodiments of the present disclosure;

FIG. 3 is a schematic view of a light-emitting device included in the electronic apparatus of FIG. 1, according to one or more embodiments of the present disclosure;

FIG. 4 is a schematic view of an optoelectronic device included in the electronic apparatus of FIG. 1, according to one or more embodiments of the present disclosure;

FIG. 5 is a schematic view of an optoelectronic device according to one or more embodiments of the present disclosure;

FIG. 6 is a schematic view of an optoelectronic device according to one or more embodiments of the present disclosure;

FIG. 7 is a schematic perspective view of electronic equipment including an optoelectronic device according to one or more embodiments of the present disclosure;

FIG. 8 is a diagram schematically illustrating an exterior of a vehicle as electronic equipment including an optoelectronic device according to one or more embodiments of the present disclosure; and

FIGS. 9A, 9B, and 9C are each a diagram schematically illustrating an interior of the vehicle of FIG. 8 according to one or more embodiments of the present disclosure.

### DETAILED DESCRIPTION

Reference will now be made in more detail to embodiments, examples of which are illustrated in the accompanying drawings, wherein like reference numerals refer to like elements throughout the present disclosure, and duplicative descriptions thereof may not be provided for conciseness. In this regard, the embodiments of the present disclosure may have different forms and should not be construed as being limited to the descriptions set forth herein. Accordingly, the embodiments of the present disclosure are merely described, by referring to the drawings, to explain aspects of the present disclosure. As utilized herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

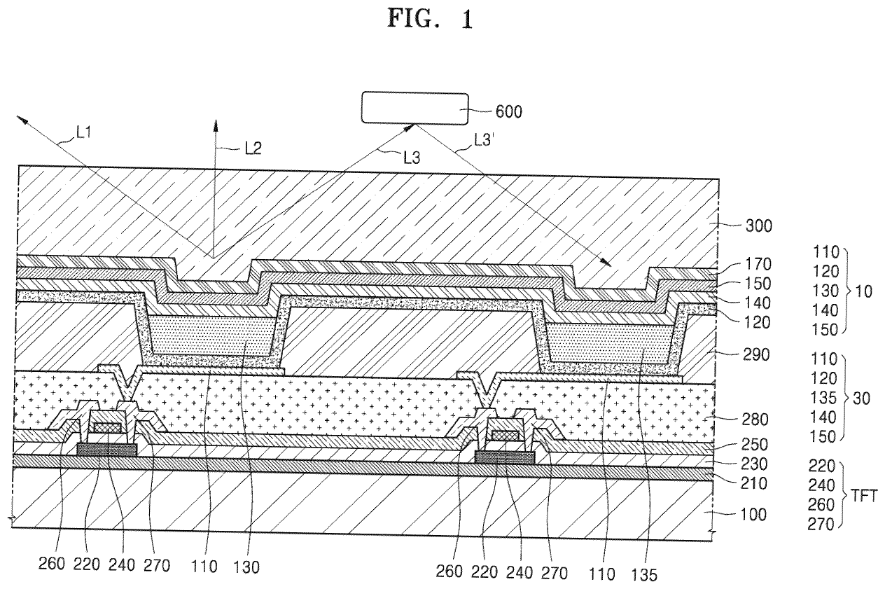

FIG. 1 is a schematic view of an electronic apparatus according to one or more embodiments of the present disclosure.

According to one or more aspects of embodiments of the disclosure, an electronic apparatus may include an optoelectronic device 30 and a light-emitting device 10. Light L3 from among light (L1, L2, and L3) emitted from the light-emitting device 10 may be incident onto an object 600 outside the electronic apparatus. For example, the object 600 may be a finger of a user of the electronic apparatus. Light L3′ reflected from the object 600 may be incident onto the optoelectronic device 30. Accordingly, the optoelectronic device 30 may function as an optical sensor, and the optoelectronic device 30 and the light-emitting device 10 are to be described in more detail later in the present disclosure.

The electronic apparatus may be a display apparatus, a light-emitting apparatus, an authentication apparatus, etc. The authentication apparatus may be, for example, a biometric authentication apparatus that authenticates an individual by utilizing biometric information of a living body (for example, fingertips, pupils, and/or the like). For example, the electronic apparatus may be to emit light and collect biometric information.

The electronic apparatus may be applied to one or more of displays, light sources, lighting, personal computers (e.g., a mobile personal computer), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, sensors (e.g., sensors for vehicles, sensors for home, fingerprint recognition sensor, or blood pressure recognition sensor), solar cells, and/or the like.

Referring to FIG. 1, in one or more embodiments, the electronic apparatus may further include a substrate 100 arranged under (e.g., on) a first electrode 100, a thin-film transistor (TFT), etc., may further include a pixel-defining film 290 distinguishing the first electrode 110, and/or may further include a capping layer 170 on a second electrode 150, an encapsulation portion 300, etc.

The substrate 100 may be a flexible substrate, a glass substrate, or a metal substrate. A buffer layer 210 may be on the substrate 100. The buffer layer 210 may prevent or reduce penetration of impurities through the substrate 100 and may provide a flat surface on the substrate 100.

The TFT may be on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating the activation layer 220 from the gate electrode 240 may be on the activation layer 220, and the gate electrode 240 may be on the gate insulating film 230.

An interlayer insulating film 250 may be on the gate electrode 240. The interlayer insulating film 250 may be located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220.

The TFT may be electrically connected to each of the light-emitting device 10 and the optoelectronic device 30 to drive the light-emitting device 10 or transmit electrical signals generated by the light absorbed by the optoelectronic device 30, and may be covered and protected by a passivation layer 280. The passivation layer 280 may include an inorganic insulating film, an organic insulating film, or any combination thereof. The light-emitting device 10 and the optoelectronic device 30 may be arranged on the passivation layer 280. The light-emitting device 10 may include the first electrode 110, a hole transport region 120, an emission layer 130, an electron transport region 140, and the second electrode 150. The optoelectronic device 30 may include a first electrode 110, a hole transport region 120, a photoactive layer 135, an electron transport region 140, and a second electrode 150.

The first electrodes 110 may be arranged on the passivation layer 280. The passivation layer 280 may be located to expose a portion of the source electrode 260 and a portion of the drain electrode 270, not fully covering the source electrode 260 and the drain electrode 270, and the first electrode 110 may be located to be connected to the exposed portion of the source electrode 260 (e.g., in the optoelectronic device 30 at, e.g., the right side of FIG. 1) or the exposed portion of the drain electrode 270 (e.g., in the light-emitting device 10 at, e.g., the lift side of FIG. 1).

The pixel-defining film 290 including an insulating material may be arranged partially on the first electrode 110. The pixel-defining film 290 may expose a region of the first electrode 110, and the emission layer 130 and the photoactive layer 135 may each be separately formed in the exposed region of the respective first electrodes 110. The pixel-defining film 290 may be a polyimide or polyacrylic organic film.

The second electrode 150 may be on the emission layer 130, and the capping layer 170 may be additionally formed on the second electrode 150. The capping layer 170 may be formed to cover the second electrode 150.

The encapsulation portion 300 may be on the capping layer 170. The encapsulation portion 300 may be arranged on the light-emitting device 10 and the optoelectronic device 30 to protect the light-emitting device 10 and the optoelectronic device 30 from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; or any combination of the inorganic films and the organic films.

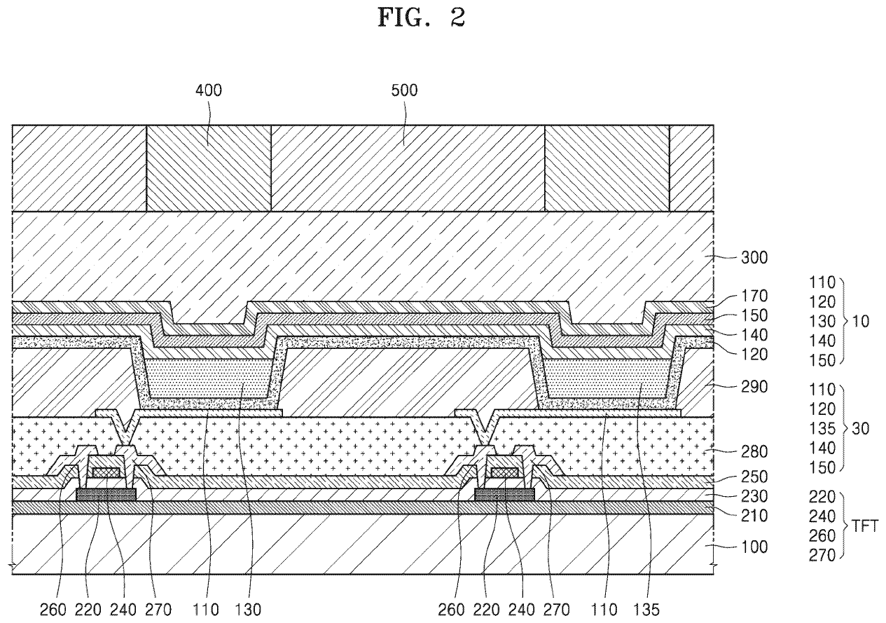

FIG. 2 is a schematic view of an electronic apparatus according to one or more embodiments of the present disclosure.

The electronic apparatus of FIG. 2 is substantially the same as the electronic apparatus of FIG. 1, except that a light-shielding pattern 500 and a functional region 400 are additionally arranged on the encapsulation portion 300. In the functional region 400, i) a color filter, ii) a color conversion layer, or iii) a combination of a color filter and a color conversion layer may be provided and arranged. In one or more embodiments, Various functional layers may be additionally provided and arranged on the encapsulation portion 300, in addition to the color filter and/or the color conversion layer, according to utilization of the electronic apparatus. Examples of the functional layers may include a touch screen layer, a polarizing layer, and/or the like. The touch screen layer may be a pressure-sensitive touch screen layer, a capacitive touch screen layer, or an infrared touch screen layer.

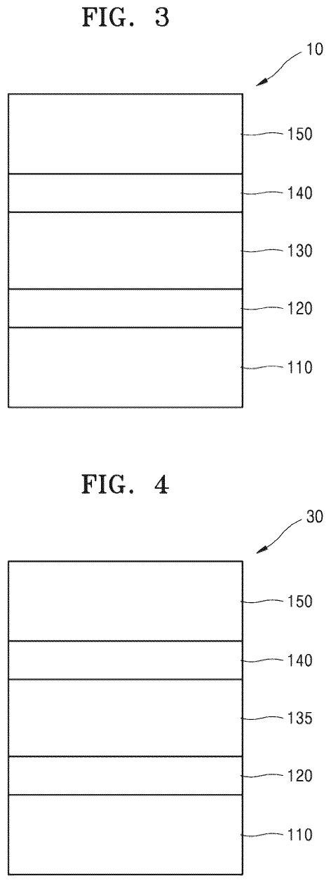

FIG. 3 is a schematic view of the light-emitting device 10 included in the electronic apparatus of FIG. 1 according to one or more embodiments of the present disclosure.

Referring to FIG. 3, the light-emitting device 10 may include the first electrode 110, the second electrode 150 facing to the first electrode 110, the emission layer 130 between the first electrode 110 and the second electrode 150, the hole transport region 120 between the first electrode 110 and the emission layer 130, and the electron transport region 140 between the emission layer 130 and the second electrode 150.

FIG. 4 is a schematic view of the optoelectronic device 30 included in the electronic apparatus of FIG. 1, according to one or more embodiments of the present disclosure.

Referring to FIG. 4, the optoelectronic device 30 may include the first electrode 110, the second electrode 150 facing to the first electrode 110, the photoactive layer 135 between the first electrode 110 and the second electrode 150, the hole transport region 120 between the first electrode 110 and the photoactive layer 135, and the electron transport region 140 between the photoactive layer 135 and the second electrode 150.

Referring to FIGS. 1 to 4, in one or more embodiments, the first electrode 110 of the light-emitting device 10 and the first electrode 110 of the optoelectronic device 30 may include the same material, and may be formed substantially concurrently (e.g., simultaneously). The hole transport region 120 of the light-emitting device 10 and the hole transport region 120 of the optoelectronic device 30 may include the same material, may be formed substantially concurrently (e.g., simultaneously), and may have substantially one body. The electron transport region 140 of the light-emitting device 10 and the electron transport region 140 of the optoelectronic device 30 may include the same material, may be formed substantially concurrently (e.g., simultaneously), and may have substantially one body. The second electrode 150 of the light-emitting device 10 and the second electrode 150 of the optoelectronic device 30 may include the same material, may be formed substantially concurrently (e.g., simultaneously), and may have substantially one body.

According to one or more embodiments of the present disclosure, the optoelectronic device 30 may include: the first electrode 110, the second electrode 150 facing (e.g., opposite to and facing) the first electrode 110, and the photoactive layer 135 between the first electrode 110 and the second electrode 150, wherein the photoactive layer 135 may include an acceptor satisfying Expression 1, and a donor having a maximum absorption wavelength of about 600 nm to about 750 nm, and the optoelectronic device 30 (specifically, the photoactive layer 135) may satisfy Expression 2:

$$3 eV \leq {E}_{LUMO}^{A} - {E}_{HOMO}^{A} \leq 4 eV \qquad Expression 1$$

$$0.05 \leq ( {E}_{LUMO}^{D} - {E}_{LUMO}^{A} ) / ( {E}_{LUMO}^{D} - {E}_{HOMO}^{D} ) \leq 0.5 \qquad Expression 2$$

wherein, in Expressions 1 and 2,
E^{D}_{LUMO} represents a LUMO energy level of the donor,
E^{D}_{HOMO} represents a HOMO energy level of the donor,
E^{A}_{LUMO} represents a LUMO energy level of the acceptor, and
E^{A}_{HOMO} represents a HOMO energy level of the acceptor.

In one or more embodiments, the optoelectronic device may further satisfy Expression 4:

$${E}_{LUMO}^{A} \leq {E}_{LUMO}^{D} \qquad Expression 4$$

wherein, in Expression 4,
E^{D}_{LUMO} and E^{A}_{LUMO} are each the same as described in the present disclosure.

In one or more embodiments, the optoelectronic device may further satisfy Expression 5:

$${E}_{HOMO}^{A} \leq {E}_{HOMO}^{D} \qquad Expression 5$$

wherein, in Expression 5,
E^{D}_{HOMO} and E^{A}_{HOMO} are each the same as described in the present disclosure.

For example, in one or more embodiments, “E^{D}_{HOMO}≤E^{A}_{LUMO}≤E^{D}_{LUMO}” may be satisfied. In one or more embodiments, “E^{A}_{HOMO}≤E^{D}_{HOMO}≤E^{A}_{LUMO}≤E^{D}_{LUMO}” may be satisfied.

E^{A}_{HOMO}, E^{D}_{HOMO}, E^{A}_{LUMO}, and E^{D}_{LUMO} may each have a negative value.

In one or more embodiments, an amount of the donor may be about 10 parts by weight to about 50 parts by weight based on 100 parts by weight of the photoactive layer 135. For example, in some embodiments, based on 100 parts by weight of the photoactive layer 135, the amount of the donor may be about 30 parts by weight to about 50 parts by weight, about 40 parts by weight to about 50 parts by weight, or 45 parts by weight.

In one or more embodiments, an amount of the acceptor may be about 50 parts by weight to about 90 parts by weight based on 100 parts by weight of the photoactive layer 135. For example, in some embodiments, based on 100 parts by weight of the photoactive layer 135, the amount of the acceptor may be about 50 parts by weight to about 70 parts by weight, about 50 parts by weight to about 60 parts by weight, or 55 parts by weight.

In one or more embodiments, a thickness of the photoactive layer 135 may be about 40 nm to about 50 nm.

### Acceptor

In one or more embodiments, the acceptor may satisfy Expression 1:

$$3 eV \leq {E}_{LUMO}^{A} - {E}_{HOMO}^{A} \leq 4 eV \qquad Expression 1$$

wherein, in Expression 1,
E^{A}_{LUMO} and E^{A}_{HOMO} are each the same as described in the present disclosure.

In one or more embodiments, the acceptor may not include (e.g., may exclude) a (e.g., any) fullerene-based compound. For example, the acceptor may not include (e.g., may exclude) Fullerene 60 and/or Fullerene 70:

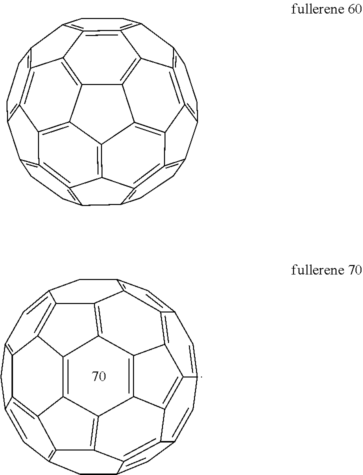

In one or more embodiments, the acceptor may not include (e.g., may exclude) a (e.g., any) 5-membered ring.

In one or more embodiments, the acceptor may be transparent in the visible light region (e.g., having no optical absorption band in a wavelength range of about 380 nm to about 700 nm).

In one or more embodiments, the acceptor may be represented by Formula 1:

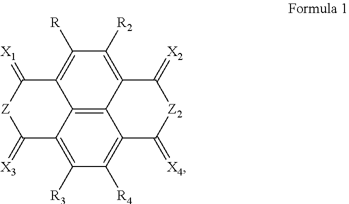

wherein, in Formula 1,
X₁ to X₄ may each independently be O, S, or Se,
Z₁ may be O or N(R₅),
Z₂ may be O or N(R₆),
R₁ to R₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In one or more embodiments, in Formula 1, at least one selected from among X₁ to X₄ may be O. X₁ to X₄ may be identical to or different from each other.

In one or more embodiments, in Formula 1, Z₁ may be N(R₅), Z₂ may be N(R₆), and R₁ to R₆ may each independently be selected from:
hydrogen, deuterium, —F, —Cl, or a cyano group;
a C₁-C₁₀ alkyl group unsubstituted or substituted with deuterium, —F, —Cl, a cyano group, or any combination thereof;
a C₆-C₁₀ aryl group unsubstituted or substituted with deuterium, —F, —Cl, a cyano group, —CF₃, or any combination thereof; and
a C₆-C₁₀ heteroaryl group unsubstituted or substituted with deuterium, —F, —Cl, a cyano group, —CF₃, or any combination thereof.

In one or more embodiments, the HOMO energy level of the acceptor may be about −8 eV to about −6 eV.

In one or more embodiments, the LUMO energy level of the acceptor may be about −5 eV to about −3 eV.

In one or more embodiments, the acceptor may be at least one selected from among Compounds C₁ to C₁₇, but embodiments of the disclosure are not limited thereto:

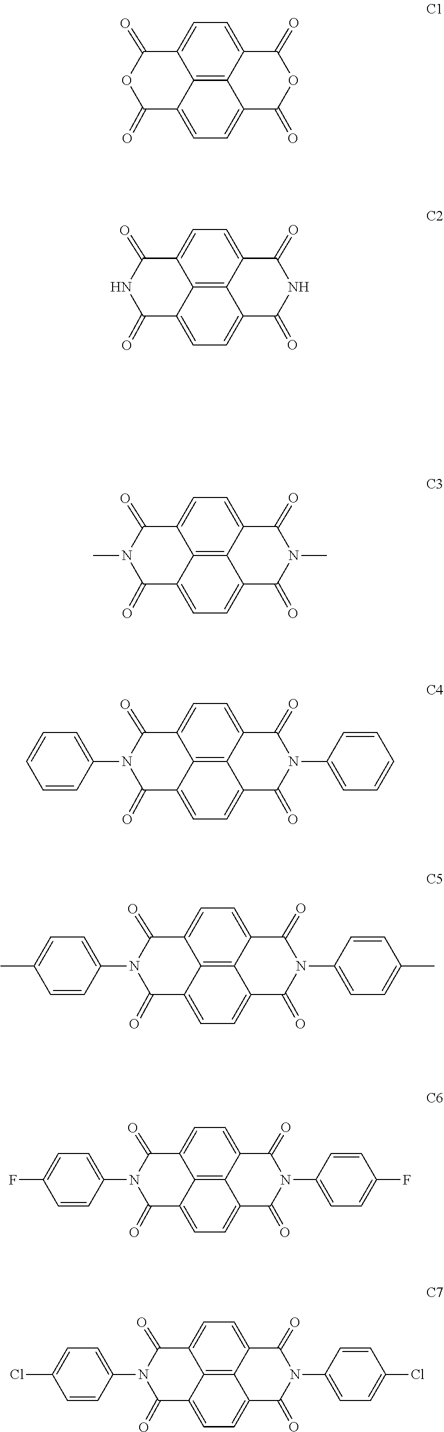

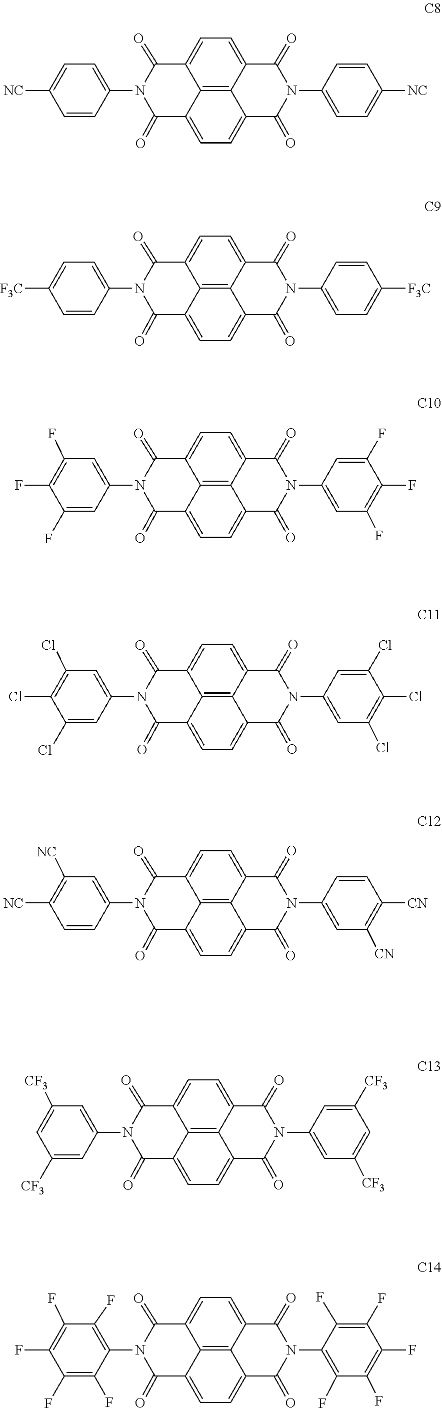

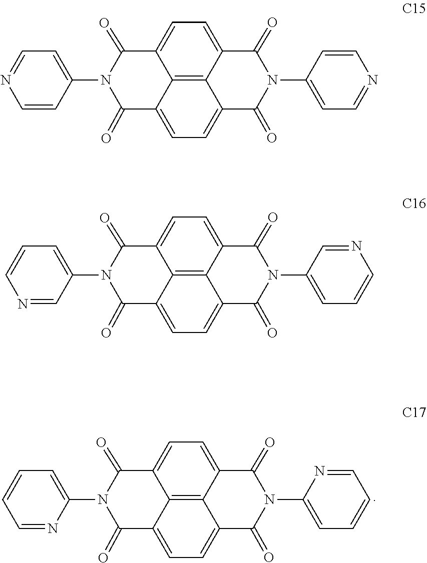 [SMILES: O=C1c2ccc3c4c(ccc(c24)C(=O)N1c1ccncc1)C(=O)N(c1ccncc1)C3=O ; O=C1c2ccc3c4c(ccc(c24)C(=O)N1c1cccnc1)C(=O)N(c1cccnc1)C3=O ; O=C1c2ccc3c4c(ccc(c24)C(=O)N1c1ccccn1)C(=O)N(c1ccccn1)C3=O]

### Donor

The donor may have a maximum absorption wavelength of about 600 nm to about 750 nm. In one or more embodiments, the maximum absorption wavelength of the donor may be about 600 nm to about 700 nm. For example, in some embodiments, the maximum absorption wavelength of the donor may be greater than or equal to 600 nm and less than or equal to 700 nm. In one or more embodiments, the maximum absorption wavelength of the donor may be about 610 nm to about 700 nm, about 620 nm to about 680 nm, about 630 nm to about 660 nm, or about 630 nm to about 650 nm. For example, the donor may be to absorb red light to the maximum, and may be clearly different from a compound absorbing green light to the maximum. For example, the donor may be clearly different from SubPC:

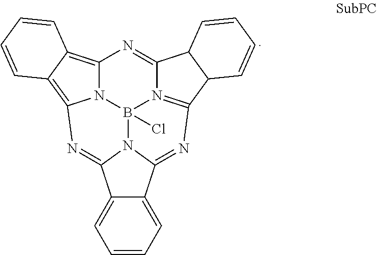

In one or more embodiments, the donor may not include (e.g., may exclude) boron. For example, the donor may not include (e.g., may exclude) a (e.g., any) subnaphthalocyanine-based compound. For example, the donor may not include (e.g., may exclude) SubNC:

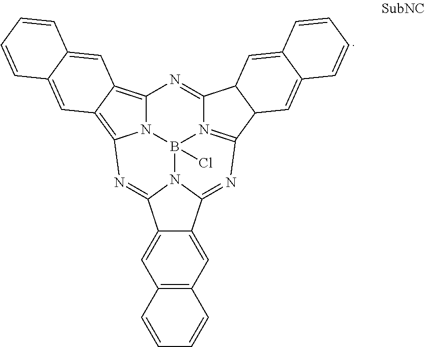

In one or more embodiments, the donor may satisfy Expression 3:

$$1. eV \leq {E}_{LUMO}^{D} - {E}_{HOMO}^{D} \leq 2.5 eV \qquad Expression 3$$

wherein, in Expression 3,
E^{D}_{LUMO} and E^{D}_{HOMO} are each the same as described in the present disclosure.

In one or more embodiments, the donor may be represented by any one selected from among Formulae 2 and 3:

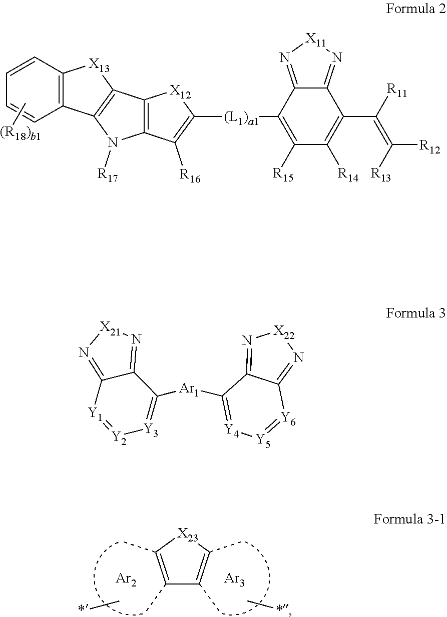

wherein, in Formulae 2, 3, and 3-1,
L₁ may be a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
a1 may be an integer from 1 to 3,
Ar₁ may be a group represented by Formula 3-1,
Ar₂ and Ar₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₁₁ to X₁₃ may each independently be O, S, or Se,
X₂₁ may be N(R₂₁), O, S, or Se,
X₂₂ may be N(R₂₂), O, S, or Se,
X₂₃ may be C(R₂₃ₐ)(R_{23b}), N(R₂₃), O, S, or Se,
Y₁ may be N or C(R₂₄), Y₂ may be N or C(R₂₅), Y₃ may be N or C(R₂₆), Y4 may be N or C(R₂₇), Y₅ may be N or C(R₂₈), Y₆ may be N or C(R₂₉),
R₁₁ to R₁₈, R₂₁ to R₂₉, R₂₃ₐ, and R_{23b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b1 may be an integer from 0 to 4,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof, and
*′ and *″ each indicate a binding site to a neighboring atom.

In one or more embodiments, in Formula 2, X₁₁ to X₁₃ may be identical to or different from each other. In some embodiments, at least two selected from among X₁₁ to X₁₃ may be identical to each other.

In one or more embodiments, in Formula 2, R₁₂ and R₁₃ may each independently be selected from
hydrogen, deuterium, —F, —Cl, a cyano group, and
a C₁-C₁₀ alkyl group unsubstituted or substituted with deuterium, —F, —Cl, a cyano group, or any combination thereof.

In one or more embodiments, in Formula 2, L₁ may be a single bond. For example, in some embodiments, -(L₁)ₐ₁- may be a single bond.

In one or more embodiments, in Formula 2, R₁₇ may be hydrogen, deuterium, or a C₁-C₆₀ alkyl group unsubstituted or substituted with at least one R₁₀ₐ. The C₁-C₆₀ alkyl group may be a chained or branched group.

In one or more embodiments, in Formula 3, X₂₁ and X₂₂ may be identical to each other.

In Formula 3, Ar₁ may be a group represented by Formula 3-1. In Formula 3-1, Ar₂ and Ar₃ may each independently be a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ. For example, in one or more embodiments, a moiety (i.e., a group) represented by Formula 3-1 may be a condensed ring in which three single rings are condensed. Accordingly, the moiety represented by Formula 3-1 may be clearly different from a condensed ring in which two, four, or five single rings are condensed.

In one or more embodiments, in Formula 3-1, Ar₂ and Ar₃ may each independently be a cyclopentadiene group unsubstituted or substituted with at least one R₁₀ₐ, a benzene group unsubstituted or substituted with at least one R₁₀ₐ, a pyrimidine group unsubstituted or substituted with at least one R₁₀ₐ, a thiophene group unsubstituted or substituted with at least one R₁₀ₐ, a pyrrole group unsubstituted or substituted with at least one R₁₀ₐ, or a furan group unsubstituted or substituted with at least one R₁₀ₐ.

In one or more embodiments, a moiety represented by Formula 3-1 may be one of moieties represented by Formulae 3-1A to 3-1I:

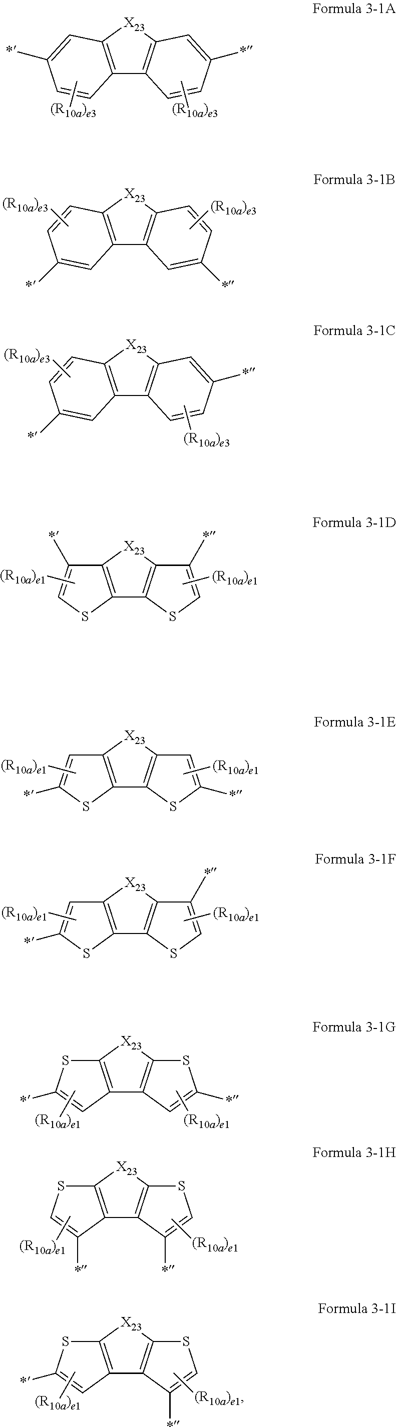

wherein, in Formulae 3-1A to 3-1I,
X₂₃, R₁₀ₐ, *′, and *″ are each the same as described in the present disclosure, and
e1 may be 0 or 1.
e3 may be an integer from 0 to 3.
In one or more embodiments, in Formulae 3-1 and 3-1A to 3-1I,
X₂₃ may be C(R₂₃ₐ)(R_{23b}) or N(R₂₃), and
R₂₃, R₂₃ₐ, and R_{23b} may each independently be selected from:
hydrogen; deuterium; —F, —Cl; a cyano group; and
a C₁-C₁₀ alkyl group, a C₆-C₆₀ aryl group, and a C₁-C₆₀ heteroaryl group, each unsubstituted or substituted with deuterium, —F, —Cl, a cyano group, or any combination thereof.

In one or more embodiments, in Formula 3, X₂₁ may be N(R₂₁) or S, X₂₂ may be N(R₂₂) or S, and
R₂₁ and R₂₂ may each independently be selected from:
hydrogen; deuterium; —F; —Cl; a cyano group; and
a C₁-C₁₀ alkyl group, a C₆-C₆₀ aryl group, and a C₁-C₆₀ heteroaryl group, each unsubstituted or substituted with deuterium, —F, —Cl, a cyano group, or any combination thereof.

In one or more embodiments, in Formula 3, at least two selected from among Y₁ to Y₃ may be N, and at least two selected from among Y₄ to Y₆ may be N.

In one or more embodiments, in Formula 3, Y₁ may be C(R₂₄), Y₂ may be N or C(R₂₅), Y₃ may be N or C(R₂₆), Y₄ may be N or C(R₂₇), Y₅ may be N or C(R₂₈), Y₆ may be C(R₂₉), and
R₂₄ to R₂₉ may each independently be selected from:
hydrogen, deuterium, —F, —Cl, —Br, —I, and a cyano group;
a C₁-C₁₀ alkyl group unsubstituted or substituted with deuterium, —F, —Cl, —Br, —I, a cyano group, or any combination thereof; and
a C₆-C₁₀ aryl group unsubstituted or substituted with deuterium, —F, —Cl, —Br, —I, a cyano group, or any combination thereof.

In an embodiment, at least one selected from among R₂₄ to R₂₉ may be selected from:
hydrogen, deuterium, —F, and a cyano group;
a C₁-C₁₀ alkyl group unsubstituted or substituted with deuterium, —F, a cyano group, or any combination thereof; and
a C₆-C₁₀ aryl group unsubstituted or substituted with deuterium, —F, a cyano group, or any combination thereof.

In one or more embodiments, the HOMO energy level of the donor may be about −6 eV to about −5 eV.

In one or more embodiments, the LUMO energy level of the donor may be about −4 eV to about −3 eV.

In one or more embodiments, the donor may be at least one selected from among Compounds A1 to A32, Compounds B1 to B50, and combinations thereof, but embodiments of the present disclosure are not limited thereto:

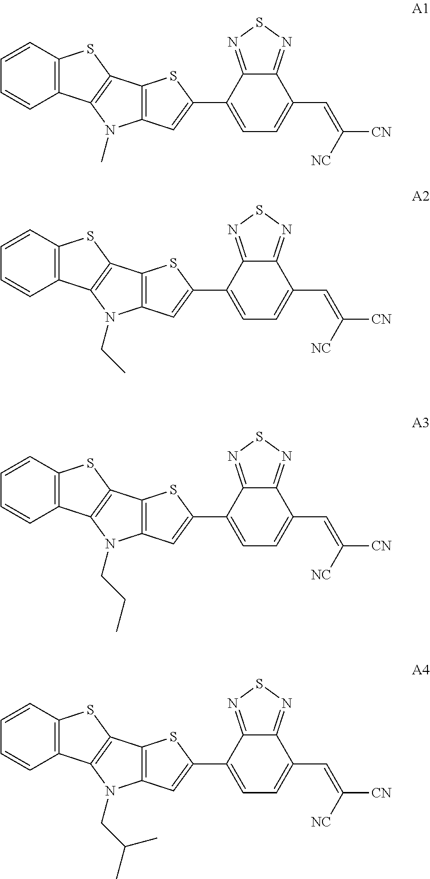 [SMILES: Cn1c2cc(-c3ccc(C=C(C#N)C#N)c4nsnc34)sc2c2sc3ccccc3c21 ; CCn1c2cc(-c3ccc(C=C(C#N)C#N)c4nsnc34)sc2c2sc3ccccc3c21 ; CCCn1c2cc(-c3ccc(C=C(C#N)C#N)c4nsnc34)sc2c2sc3ccccc3c21 ; CC(C)Cn1c2cc(-c3ccc(C=C(C#N)C#N)c4nsnc34)sc2c2sc3ccccc3c21]

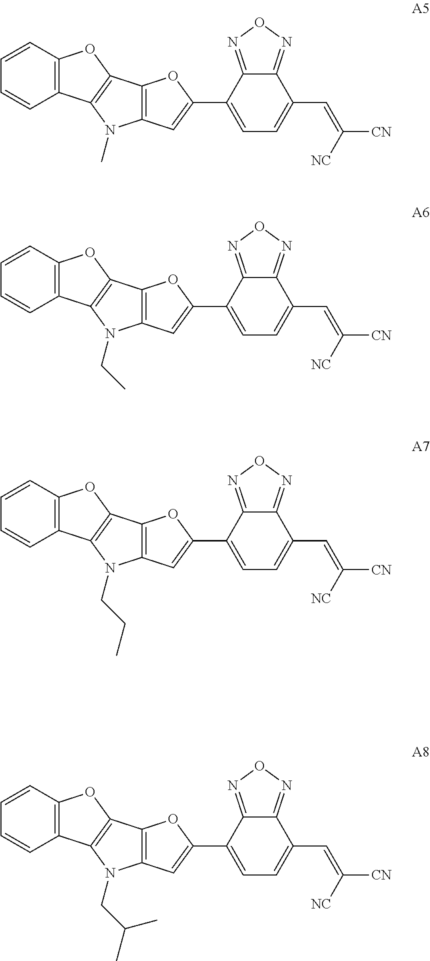 [SMILES: Cn1c2cc(-c3ccc(C=C(C#N)C#N)c4nonc34)oc2c2oc3ccccc3c21 ; CCn1c2cc(-c3ccc(C=C(C#N)C#N)c4nonc34)oc2c2oc3ccccc3c21 ; CCCn1c2cc(-c3ccc(C=C(C#N)C#N)c4nonc34)oc2c2oc3ccccc3c21 ; CC(C)Cn1c2cc(-c3ccc(C=C(C#N)C#N)c4nonc34)oc2c2oc3ccccc3c21]

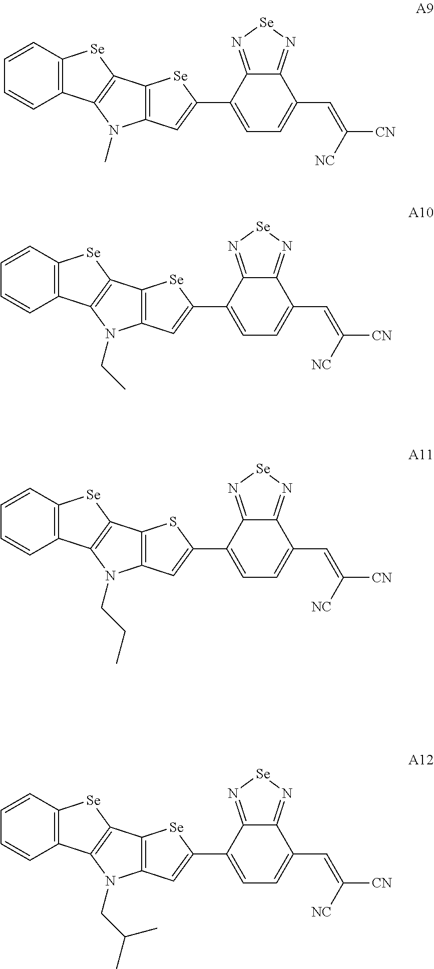 [SMILES: Cn1c2cc(-c3ccc(C=C(C#N)C#N)c4n[se]nc34)[se]c2c2[se]c3ccccc3c21 ; CCn1c2cc(-c3ccc(C=C(C#N)C#N)c4n[se]nc34)[se]c2c2[se]c3ccccc3c21 ; CCCn1c2cc(-c3ccc(C=C(C#N)C#N)c4n[se]nc34)sc2c2[se]c3ccccc3c21 ; CC(C)Cn1c2cc(-c3ccc(C=C(C#N)C#N)c4n[se]nc34)[se]c2c2[se]c3ccccc3c21]

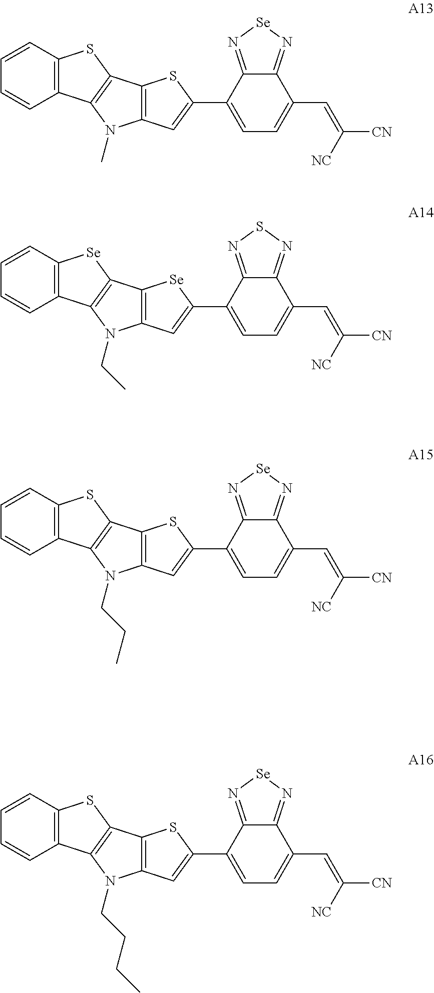 [SMILES: Cn1c2cc(-c3ccc(C=C(C#N)C#N)c4n[se]nc34)sc2c2sc3ccccc3c21 ; CCn1c2cc(-c3ccc(C=C(C#N)C#N)c4nsnc34)[se]c2c2[se]c3ccccc3c21 ; CCCn1c2cc(-c3ccc(C=C(C#N)C#N)c4n[se]nc34)sc2c2sc3ccccc3c21 ; CCCCn1c2cc(-c3ccc(C=C(C#N)C#N)c4n[se]nc34)sc2c2sc3ccccc3c21]

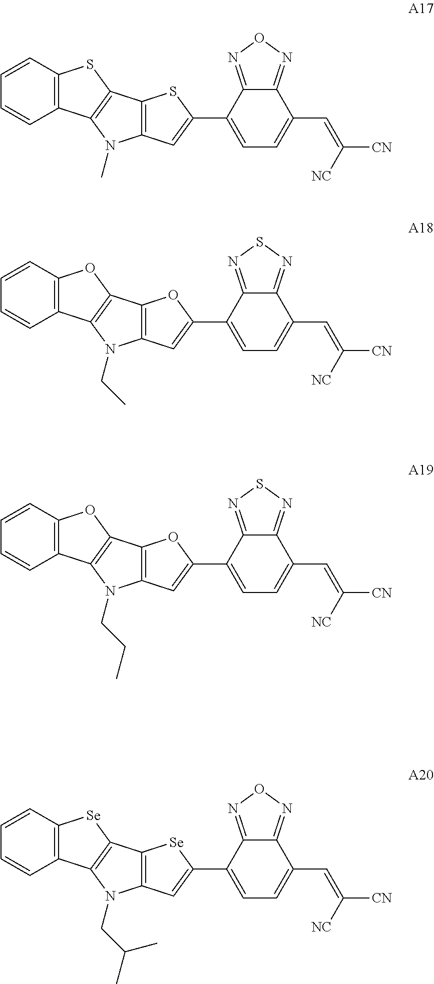 [SMILES: Cn1c2cc(-c3ccc(C=C(C#N)C#N)c4nonc34)sc2c2sc3ccccc3c21 ; CCn1c2cc(-c3ccc(C=C(C#N)C#N)c4nsnc34)oc2c2oc3ccccc3c21 ; CCCn1c2cc(-c3ccc(C=C(C#N)C#N)c4nsnc34)oc2c2oc3ccccc3c21 ; CC(C)Cn1c2cc(-c3ccc(C=C(C#N)C#N)c4nonc34)[se]c2c2[se]c3ccccc3c21]

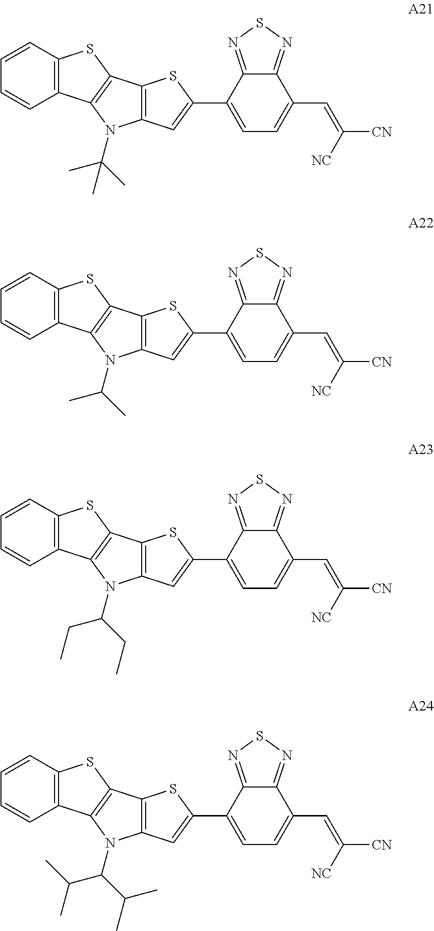 [SMILES: CC(C)(C)n1c2cc(-c3ccc(C=C(C#N)C#N)c4nsnc34)sc2c2sc3ccccc3c21 ; CC(C)n1c2cc(-c3ccc(C=C(C#N)C#N)c4nsnc34)sc2c2sc3ccccc3c21 ; CCC(CC)n1c2cc(-c3ccc(C=C(C#N)C#N)c4nsnc34)sc2c2sc3ccccc3c21 ; CC(C)C(C(C)C)n1c2cc(-c3ccc(C=C(C#N)C#N)c4nsnc34)sc2c2sc3ccccc3c21]

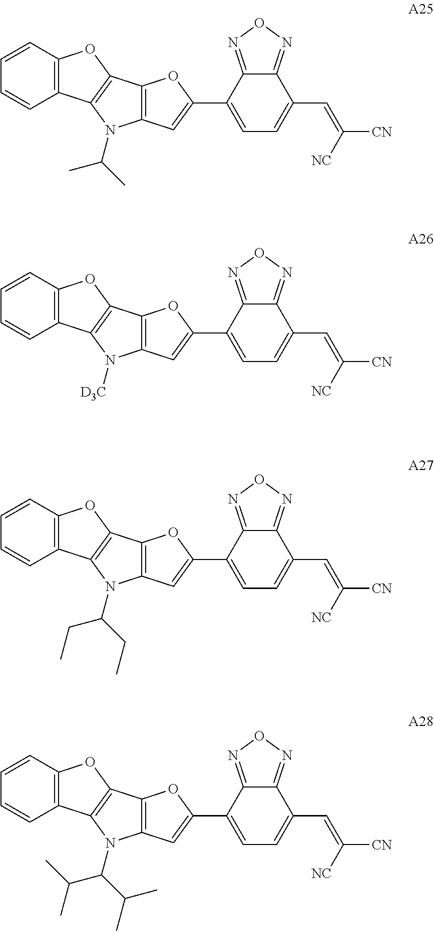 [SMILES: CC(C)n1c2cc(-c3ccc(C=C(C#N)C#N)c4nonc34)oc2c2oc3ccccc3c21 ; [2H]C([2H])([2H])n1c2cc(-c3ccc(C=C(C#N)C#N)c4nonc34)oc2c2oc3ccccc3c21 ; CCC(CC)n1c2cc(-c3ccc(C=C(C#N)C#N)c4nonc34)oc2c2oc3ccccc3c21 ; CC(C)C(C(C)C)n1c2cc(-c3ccc(C=C(C#N)C#N)c4nonc34)oc2c2oc3ccccc3c21]

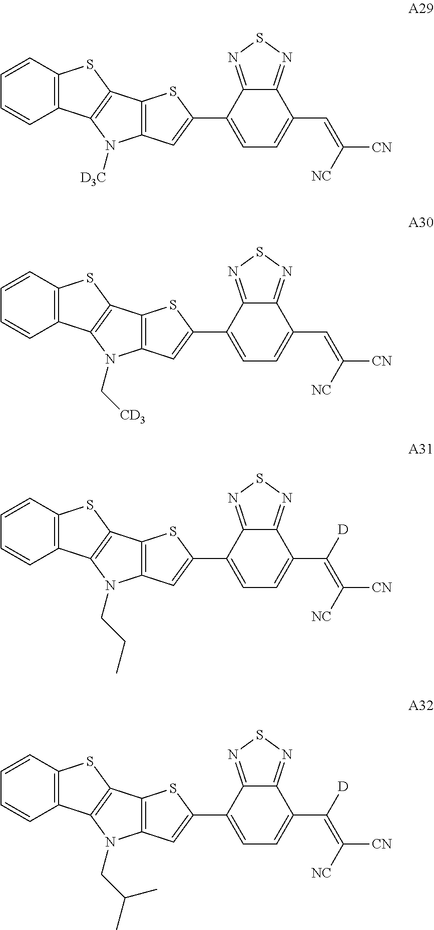 [SMILES: [2H]C([2H])([2H])n1c2cc(-c3ccc(C=C(C#N)C#N)c4nsnc34)sc2c2sc3ccccc3c21 ; [2H]C([2H])([2H])Cn1c2cc(-c3ccc(C=C(C#N)C#N)c4nsnc34)sc2c2sc3ccccc3c21 ; [2H]C(=C(C#N)C#N)c1ccc(-c2cc3c(s2)c2sc4ccccc4c2n3CCC)c2nsnc12 ; [2H]C(=C(C#N)C#N)c1ccc(-c2cc3c(s2)c2sc4ccccc4c2n3CC(C)C)c2nsnc12]

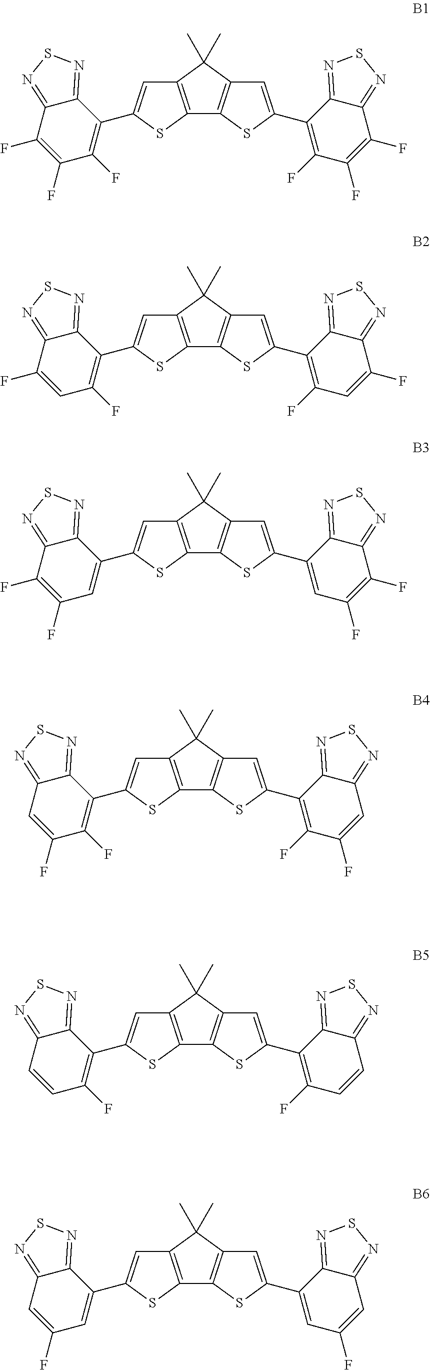 [SMILES: CC1(C)c2cc(-c3c(F)c(F)c(F)c4nsnc34)sc2-c2sc(-c3c(F)c(F)c(F)c4nsnc34)cc21 ; CC1(C)c2cc(-c3c(F)cc(F)c4nsnc34)sc2-c2sc(-c3c(F)cc(F)c4nsnc34)cc21 ; CC1(C)c2cc(-c3cc(F)c(F)c4nsnc34)sc2-c2sc(-c3cc(F)c(F)c4nsnc34)cc21 ; CC1(C)c2cc(-c3c(F)c(F)cc4nsnc34)sc2-c2sc(-c3c(F)c(F)cc4nsnc34)cc21 ; CC1(C)c2cc(-c3c(F)ccc4nsnc34)sc2-c2sc(-c3c(F)ccc4nsnc34)cc21 ; CC1(C)c2cc(-c3cc(F)cc4nsnc34)sc2-c2sc(-c3cc(F)cc4nsnc34)cc21]

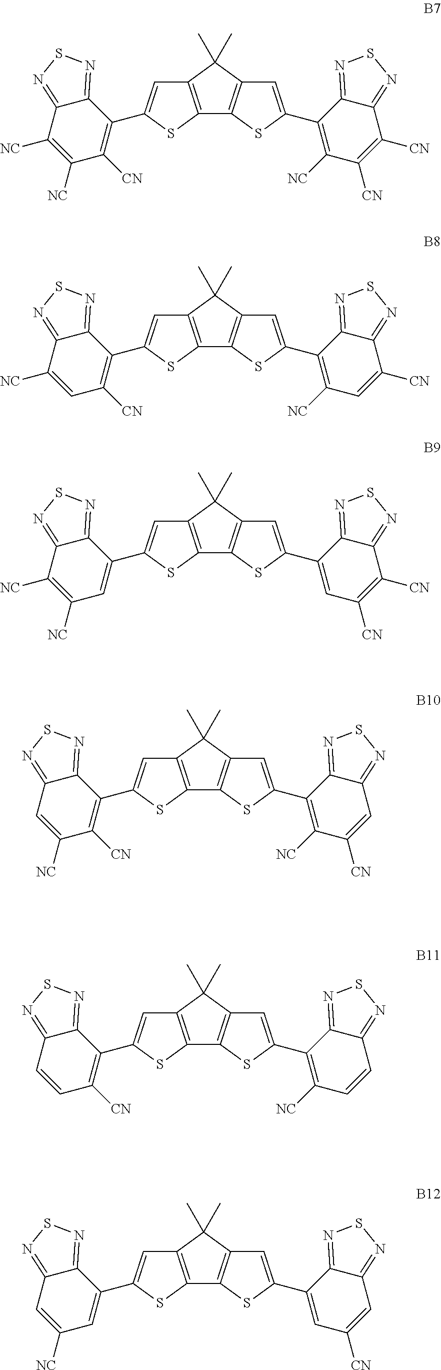 [SMILES: CC1(C)c2cc(-c3c(C#N)c(C#N)c(C#N)c4nsnc34)sc2-c2sc(-c3c(C#N)c(C#N)c(C#N)c4nsnc34)cc21 ; CC1(C)c2cc(-c3c(C#N)cc(C#N)c4nsnc34)sc2-c2sc(-c3c(C#N)cc(C#N)c4nsnc34)cc21 ; CC1(C)c2cc(-c3cc(C#N)c(C#N)c4nsnc34)sc2-c2sc(-c3cc(C#N)c(C#N)c4nsnc34)cc21 ; CC1(C)c2cc(-c3c(C#N)c(C#N)cc4nsnc34)sc2-c2sc(-c3c(C#N)c(C#N)cc4nsnc34)cc21 ; CC1(C)c2cc(-c3c(C#N)ccc4nsnc34)sc2-c2sc(-c3c(C#N)ccc4nsnc34)cc21 ; CC1(C)c2cc(-c3cc(C#N)cc4nsnc34)sc2-c2sc(-c3cc(C#N)cc4nsnc34)cc21]

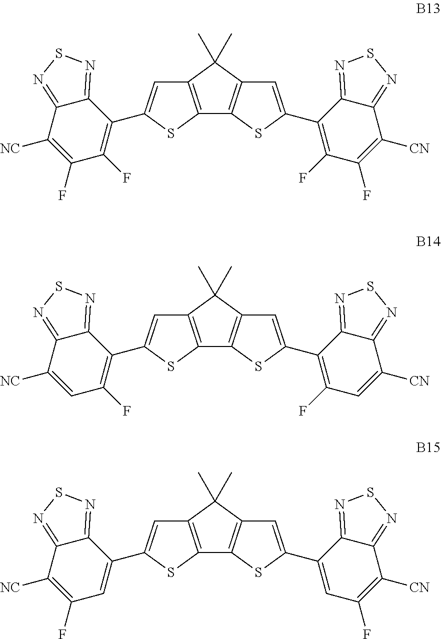 [SMILES: CC1(C)c2cc(-c3c(F)c(F)c(C#N)c4nsnc34)sc2-c2sc(-c3c(F)c(F)c(C#N)c4nsnc34)cc21 ; CC1(C)c2cc(-c3c(F)cc(C#N)c4nsnc34)sc2-c2sc(-c3c(F)cc(C#N)c4nsnc34)cc21 ; CC1(C)c2cc(-c3cc(F)c(C#N)c4nsnc34)sc2-c2sc(-c3cc(F)c(C#N)c4nsnc34)cc21]

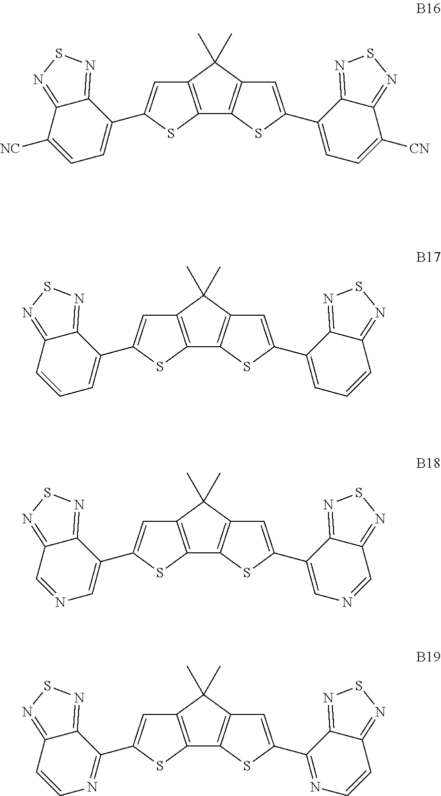 [SMILES: CC1(C)c2cc(-c3ccc(C#N)c4nsnc34)sc2-c2sc(-c3ccc(C#N)c4nsnc34)cc21 ; CC1(C)c2cc(-c3cccc4nsnc34)sc2-c2sc(-c3cccc4nsnc34)cc21 ; CC1(C)c2cc(-c3cncc4nsnc34)sc2-c2sc(-c3cncc4nsnc34)cc21 ; CC1(C)c2cc(-c3nccc4nsnc34)sc2-c2sc(-c3nccc4nsnc34)cc21]

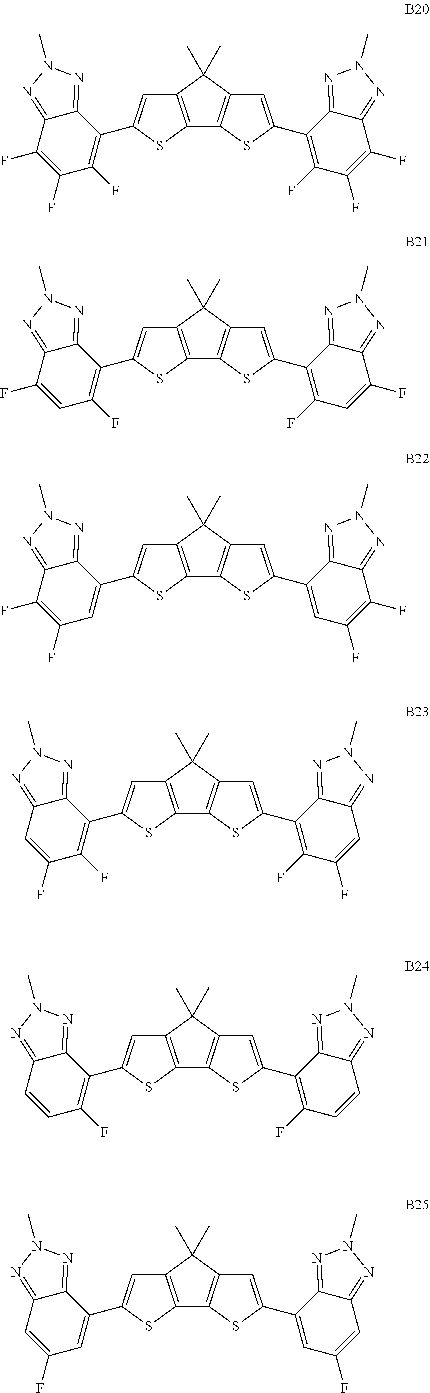 [SMILES: Cn1nc2c(F)c(F)c(F)c(-c3cc4c(s3)-c3sc(-c5c(F)c(F)c(F)c6nn(C)nc56)cc3C4(C)C)c2n1 ; Cn1nc2c(F)cc(F)c(-c3cc4c(s3)-c3sc(-c5c(F)cc(F)c6nn(C)nc56)cc3C4(C)C)c2n1 ; Cn1nc2c(-c3cc4c(s3)-c3sc(-c5cc(F)c(F)c6nn(C)nc56)cc3C4(C)C)cc(F)c(F)c2n1 ; Cn1nc2cc(F)c(F)c(-c3cc4c(s3)-c3sc(-c5c(F)c(F)cc6nn(C)nc56)cc3C4(C)C)c2n1 ; Cn1nc2ccc(F)c(-c3cc4c(s3)-c3sc(-c5c(F)ccc6nn(C)nc56)cc3C4(C)C)c2n1 ; Cn1nc2cc(F)cc(-c3cc4c(s3)-c3sc(-c5cc(F)cc6nn(C)nc56)cc3C4(C)C)c2n1]

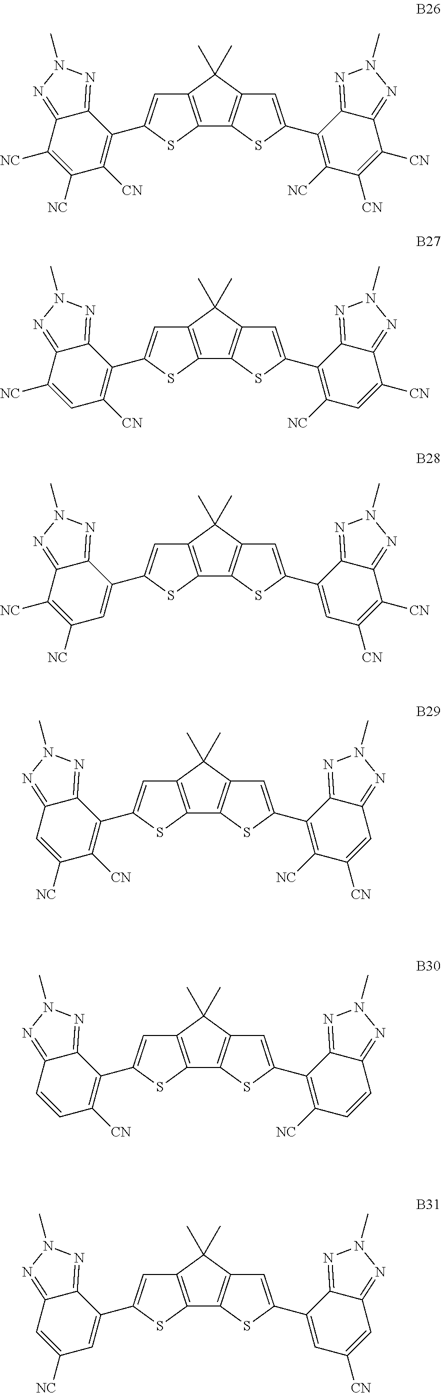 [SMILES: Cn1nc2c(C#N)c(C#N)c(C#N)c(-c3cc4c(s3)-c3sc(-c5c(C#N)c(C#N)c(C#N)c6nn(C)nc56)cc3C4(C)C)c2n1 ; Cn1nc2c(C#N)cc(C#N)c(-c3cc4c(s3)-c3sc(-c5c(C#N)cc(C#N)c6nn(C)nc56)cc3C4(C)C)c2n1 ; Cn1nc2c(-c3cc4c(s3)-c3sc(-c5cc(C#N)c(C#N)c6nn(C)nc56)cc3C4(C)C)cc(C#N)c(C#N)c2n1 ; Cn1nc2cc(C#N)c(C#N)c(-c3cc4c(s3)-c3sc(-c5c(C#N)c(C#N)cc6nn(C)nc56)cc3C4(C)C)c2n1 ; Cn1nc2ccc(C#N)c(-c3cc4c(s3)-c3sc(-c5c(C#N)ccc6nn(C)nc56)cc3C4(C)C)c2n1 ; Cn1nc2cc(C#N)cc(-c3cc4c(s3)-c3sc(-c5cc(C#N)cc6nn(C)nc56)cc3C4(C)C)c2n1]

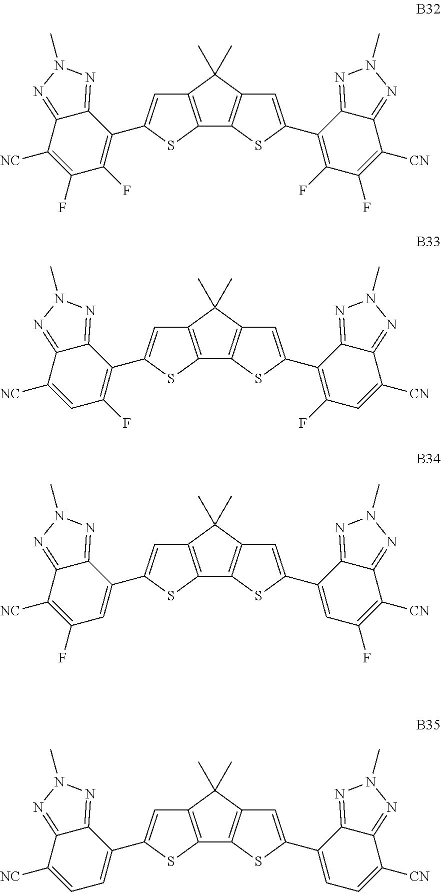 [SMILES: Cn1nc2c(C#N)c(F)c(F)c(-c3cc4c(s3)-c3sc(-c5c(F)c(F)c(C#N)c6nn(C)nc56)cc3C4(C)C)c2n1 ; Cn1nc2c(C#N)cc(F)c(-c3cc4c(s3)-c3sc(-c5c(F)cc(C#N)c6nn(C)nc56)cc3C4(C)C)c2n1 ; Cn1nc2c(-c3cc4c(s3)-c3sc(-c5cc(F)c(C#N)c6nn(C)nc56)cc3C4(C)C)cc(F)c(C#N)c2n1 ; Cn1nc2c(C#N)ccc(-c3cc4c(s3)-c3sc(-c5ccc(C#N)c6nn(C)nc56)cc3C4(C)C)c2n1]

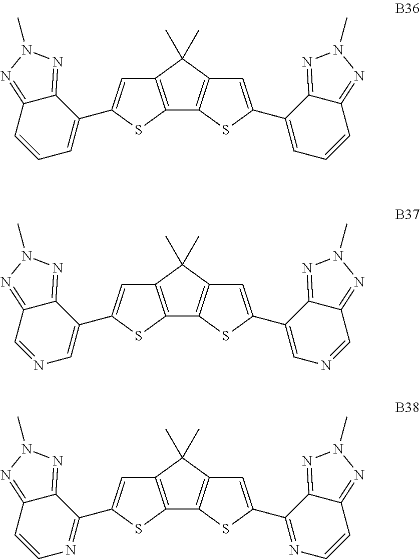 [SMILES: Cn1nc2cccc(-c3cc4c(s3)-c3sc(-c5cccc6nn(C)nc56)cc3C4(C)C)c2n1 ; Cn1nc2cncc(-c3cc4c(s3)-c3sc(-c5cncc6nn(C)nc56)cc3C4(C)C)c2n1 ; Cn1nc2ccnc(-c3cc4c(s3)-c3sc(-c5nccc6nn(C)nc56)cc3C4(C)C)c2n1]

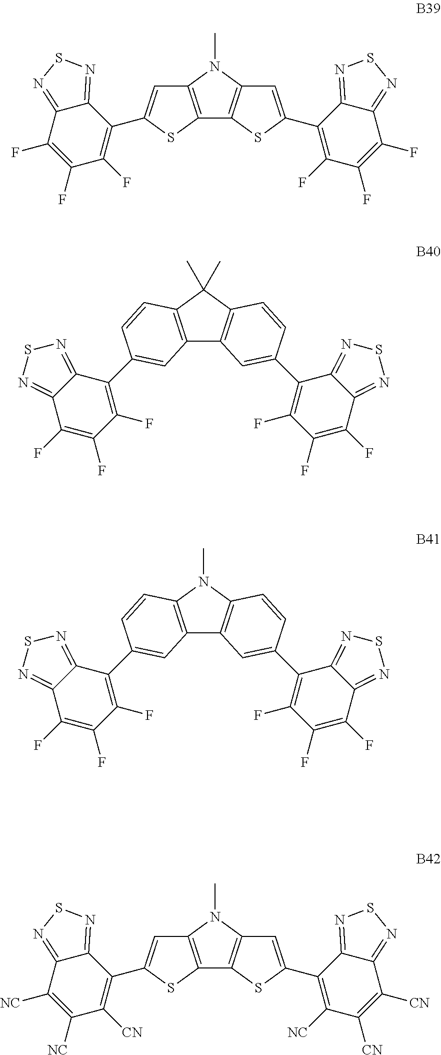 [SMILES: Cn1c2cc(-c3c(F)c(F)c(F)c4nsnc34)sc2c2sc(-c3c(F)c(F)c(F)c4nsnc34)cc21 ; CC1(C)c2ccc(-c3c(F)c(F)c(F)c4nsnc34)cc2-c2cc(-c3c(F)c(F)c(F)c4nsnc34)ccc21 ; Cn1c2ccc(-c3c(F)c(F)c(F)c4nsnc34)cc2c2cc(-c3c(F)c(F)c(F)c4nsnc34)ccc21 ; Cn1c2cc(-c3c(C#N)c(C#N)c(C#N)c4nsnc34)sc2c2sc(-c3c(C#N)c(C#N)c(C#N)c4nsnc34)cc21]

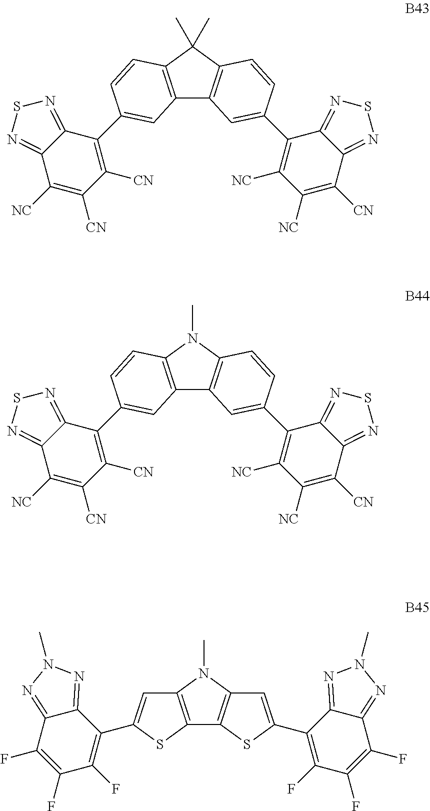 [SMILES: CC1(C)c2ccc(-c3c(C#N)c(C#N)c(C#N)c4nsnc34)cc2-c2cc(-c3c(C#N)c(C#N)c(C#N)c4nsnc34)ccc21 ; Cn1c2ccc(-c3c(C#N)c(C#N)c(C#N)c4nsnc34)cc2c2cc(-c3c(C#N)c(C#N)c(C#N)c4nsnc34)ccc21 ; Cn1nc2c(F)c(F)c(F)c(-c3cc4c(s3)c3sc(-c5c(F)c(F)c(F)c6nn(C)nc56)cc3n4C)c2n1]

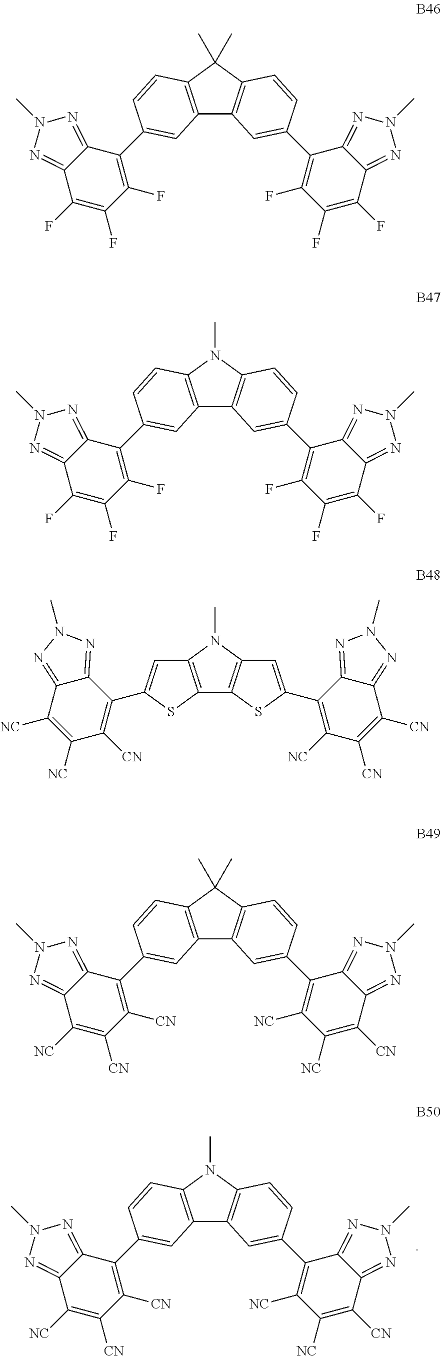

By including the acceptor of which E^{A}_{LUMO}−E^{A}_{HOMO} value is in a range of about 3 eV to about 4 eV, the energy level between the acceptor and the donor absorbing red light may be easily adjusted, and the processability may be secured.

By adjusting E^{D}_{LUMO} to be greater than or equal to E^{A}_{LUMO}, the charge-transporting characteristics of the optoelectronic device may be improved. As a value of (E^{D}_{LUMO}−E^{A}_{LUMO})/(E^{D}_{LUMO}−E^{D}_{HOMO}) is about 0.05 or greater, excitons generated at the donor may be easily transported to the acceptor. Accordingly, the charge-transporting characteristics of the optoelectronic device may be enhanced.

As the value of (E^{D}_{LUMO}−E^{A}_{LUMO})/(E^{D}_{LUMO}−E^{D}_{HOMO}) is about 0.5 or less, the holes of the donor and the electrons of the acceptor may combine, thereby easily forming excitons. Accordingly, the exciton-generating characteristics of the optoelectronic device may be improved. By adjusting E^{A}_{LUMO} to be greater than or equal to E^{D}_{HOMO}, the exciton-generating characteristics of the optoelectronic device may be enhanced.

Thus, according to one or more embodiments of the present disclosure, conditions for an acceptor and a relational formula between a donor and an acceptor may be provided as criteria for selecting an acceptor suitable for utilization with a donor absorbing red light to the maximum.

### First Electrode 110

In one or more embodiments, the substrate 100 may be additionally provided and arranged under (e.g., on) the first electrode 110 or above (e.g., on) the second electrode 150. In some embodiments, a glass substrate or a plastic substrate may be utilized as the substrate 100. In some embodiments, the substrate 100 may be a flexible substrate. For example, the substrate 100 may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by depositing or sputtering a material for forming the first electrode 110 on the substrate 100. When the first electrode 110 is an anode, a material for forming the first electrode 110 may be a high work function material to facilitate injection of holes.

The first electrode 110 may be a reflective electrode, a semi-transmissive electrode, or a transmissive electrode. In one or more embodiments, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multi-layer structure including multiple layers. For example, in some embodiments, the first electrode 110 may have a three-layer structure of ITO/Ag/ITO.

### Hole Transport Region 120

The hole transport region 120 may have i) a single-layer structure including (e.g., consisting of) a single layer including a single material, ii) a single-layer structure including (e.g., consisting of) a single layer including multiple materials that are different from each other, or iii) a multi-layer structure including (e.g., consisting of) multiple layers including multiple different materials that are different from each other.

The hole transport region 120 may include a hole injection layer, a hole transport layer, an emission auxiliary layer, an electron-blocking layer, or any combination thereof.

For example, in one or more embodiments, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein constituent layers of each structure are stacked sequentially from the first electrode 110 in the stated order.

In one or more embodiments, the hole transport region 120 may include a compound represented by Formula 201, a compound represented by Formula 202, or any combination thereof:

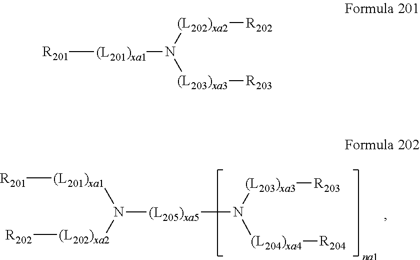

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group and/or the like) unsubstituted or substituted with at least one R₁₀ₐ (for example, see Compound HT16),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

For example, in some embodiments, each of Formulae 201 and 202 may include at least one selected from among groups represented by Formulae CY201 to CY217:

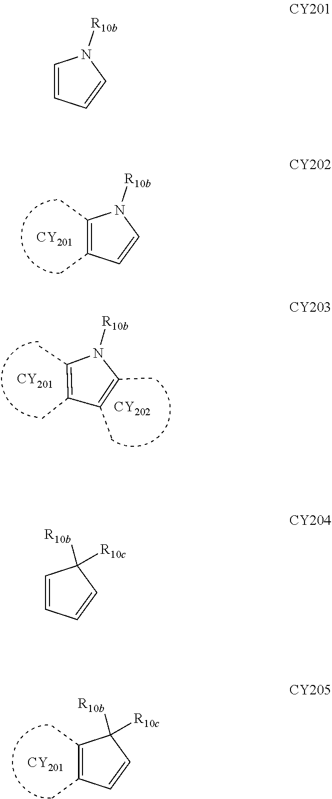

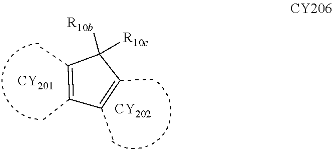

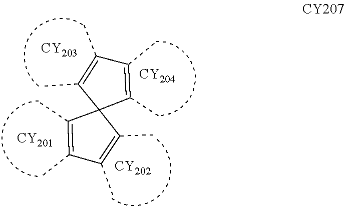

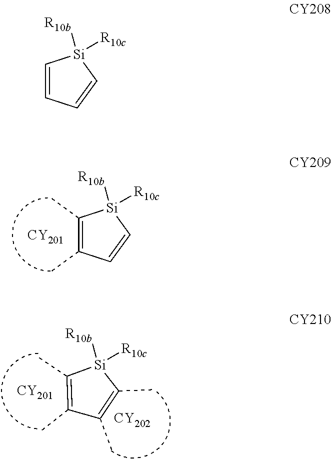

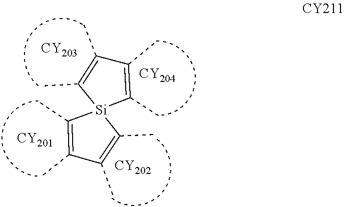

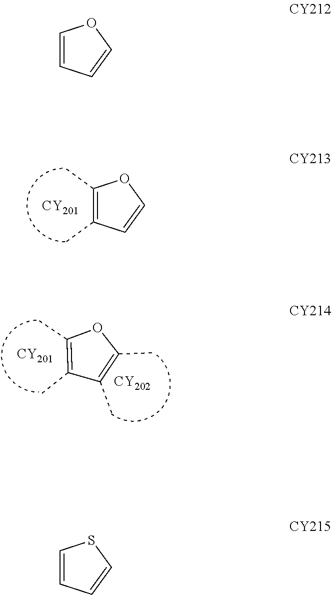

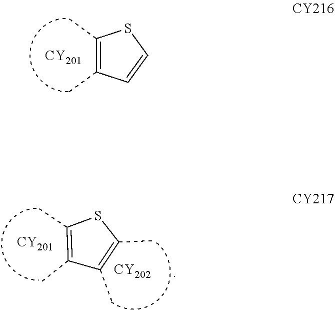

In Formulae CY201 to CY217, R_{10b} and R_{10c} may each be the same as described with respect to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one selected from among groups represented by Formulae CY201 to CY203.

According to one or more embodiments, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include (e.g., may exclude) any group represented by one selected from among Formulae CY201 to CY203.

In one or more embodiments, Formulae 201 and 202 may each not include (e.g., may exclude) any of the groups represented by Formulae CY201 to CY203, and may include at least one selected from among the groups represented by Formulae CY204 to CY217.

In one or more embodiments, each of Formulae 201 and 202 may not include (e.g., may exclude) any group represented by one selected from among Formulae CY201 to CY217. In present disclosure, “not include a or any ‘component’” “exclude a or any ‘component’”, “‘component’-free”, and/or the like refers to that the “component” not being added, selected, or utilized as a component in the composition/formula/structure, but, in some embodiments, the “component” of less than a suitable amount may still be included due to other impurities and/or external factors.

For example, in one or more embodiments, the hole transport region 120 may include at least one selected from Compounds HT1 to HT46, 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), N,N′-di(naphthalen-1-yl)-N,N′-diphenyl-benzidine (NPB(NPD)), β-NPB, TPD, Spiro-TPD, Spiro-NPB, methylated NPB, 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

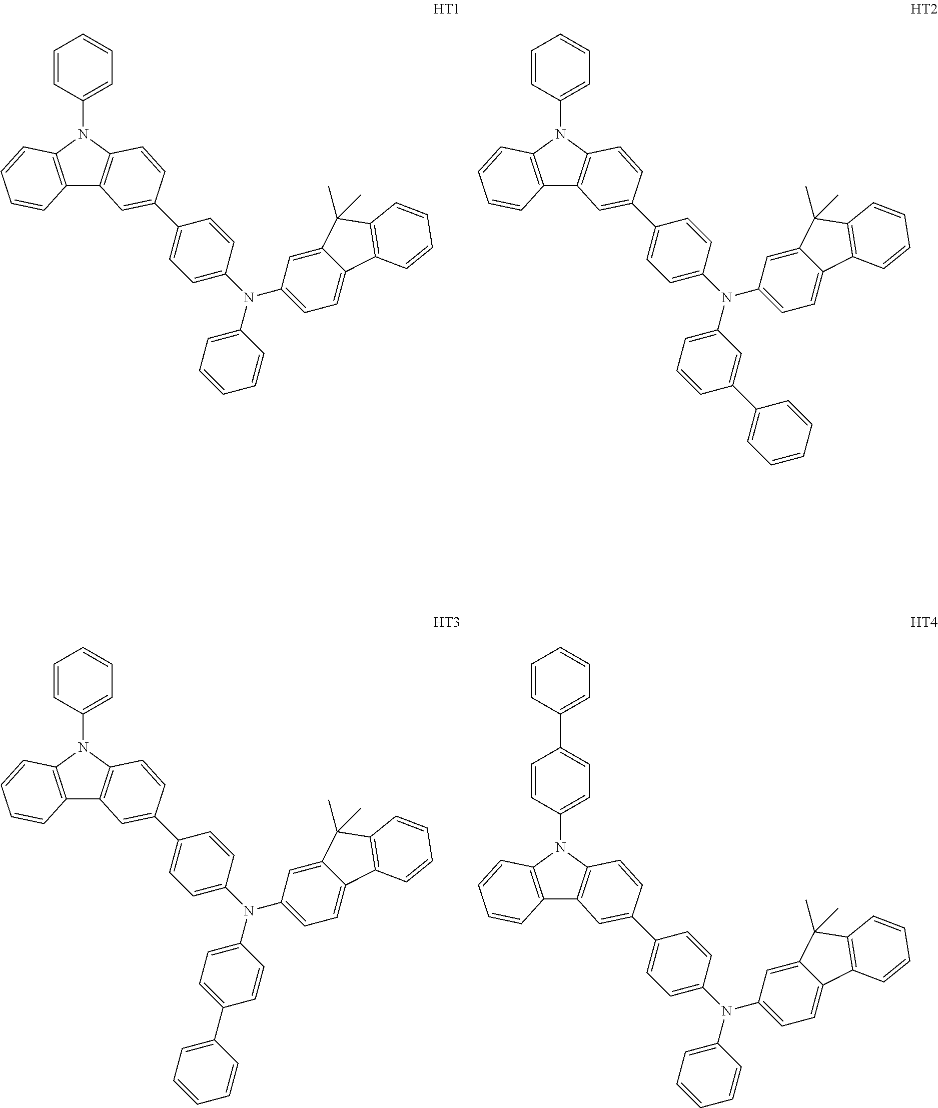 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

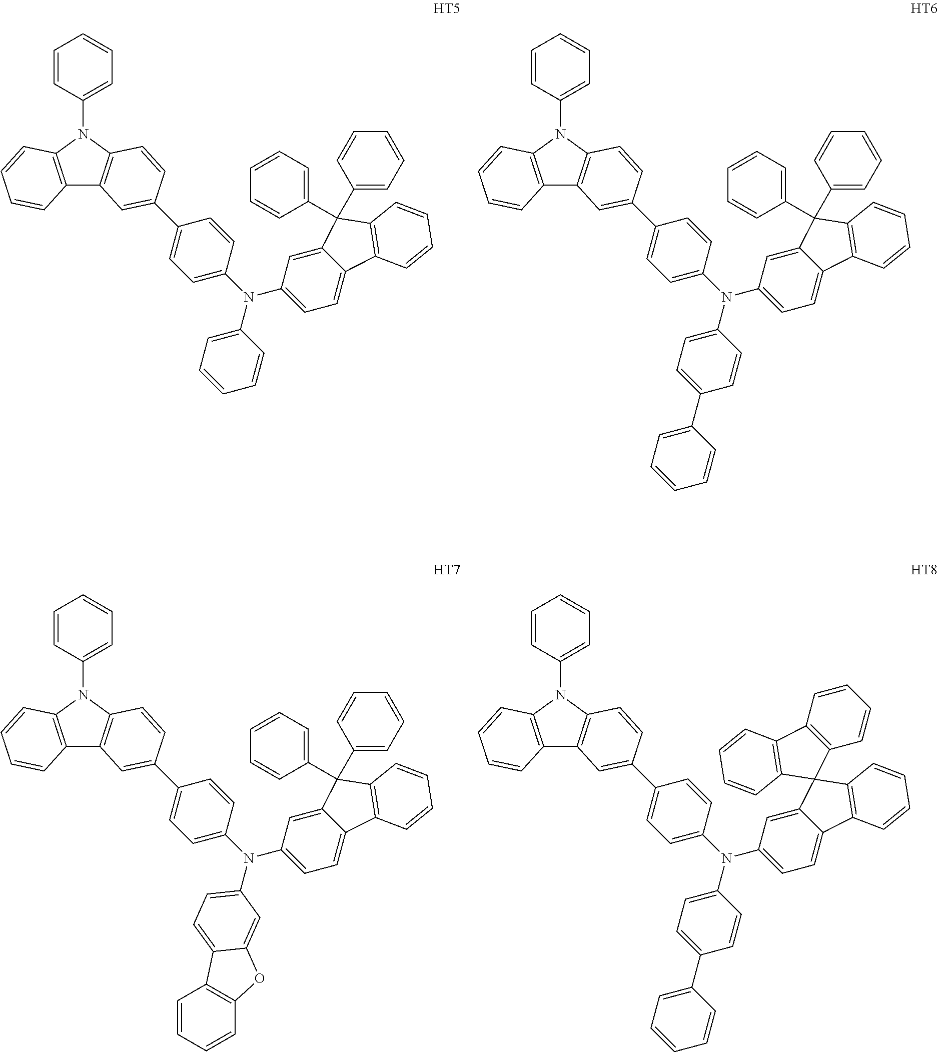 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

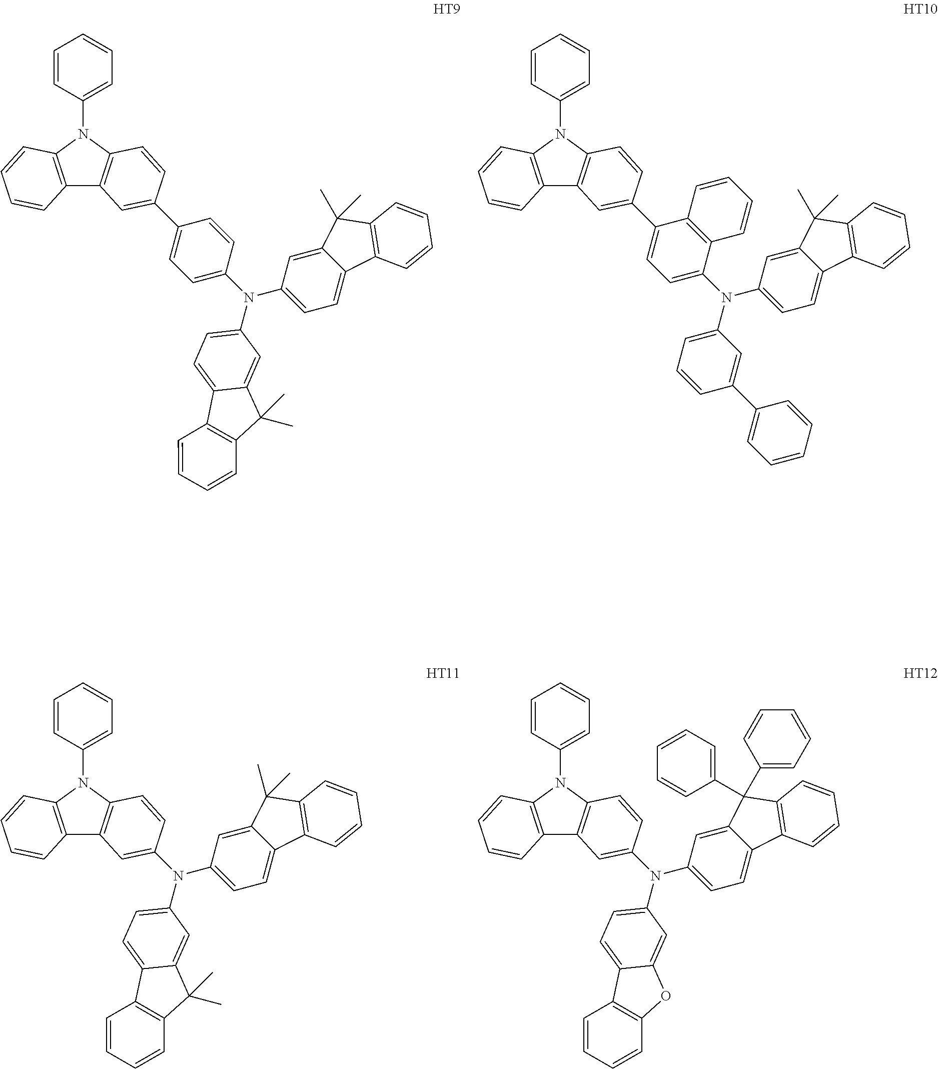 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

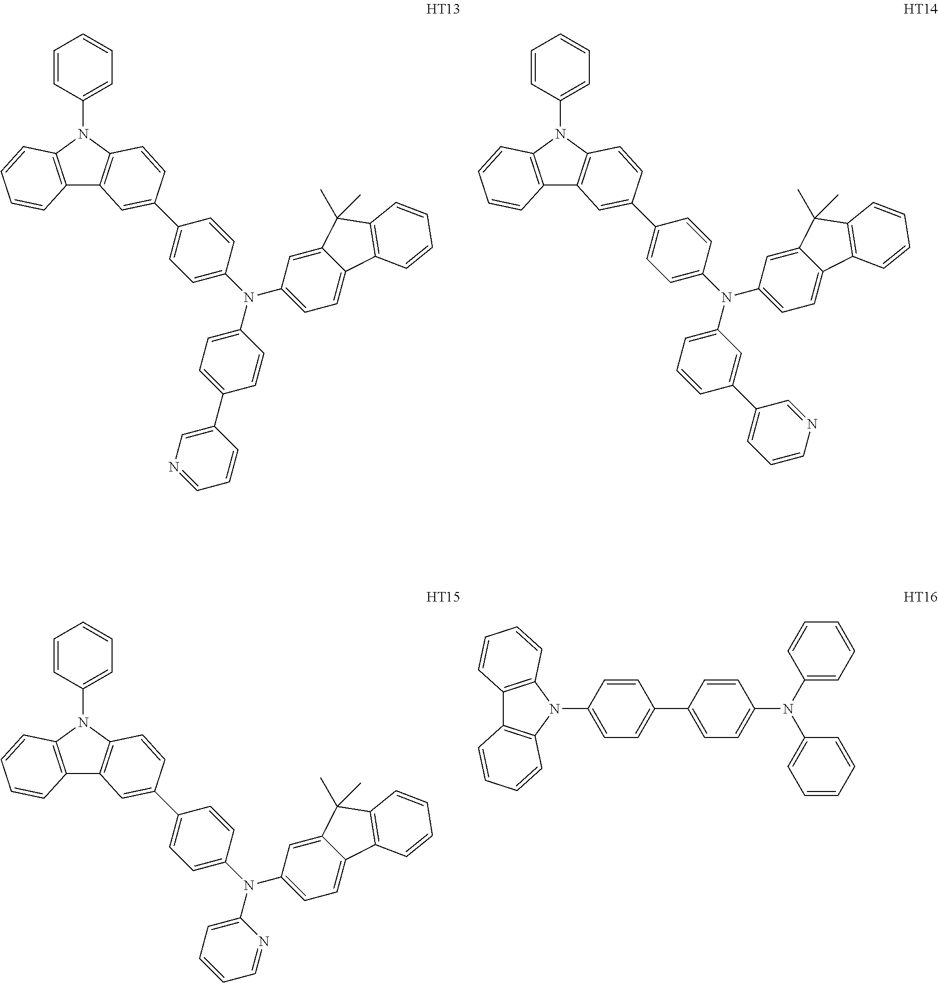 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

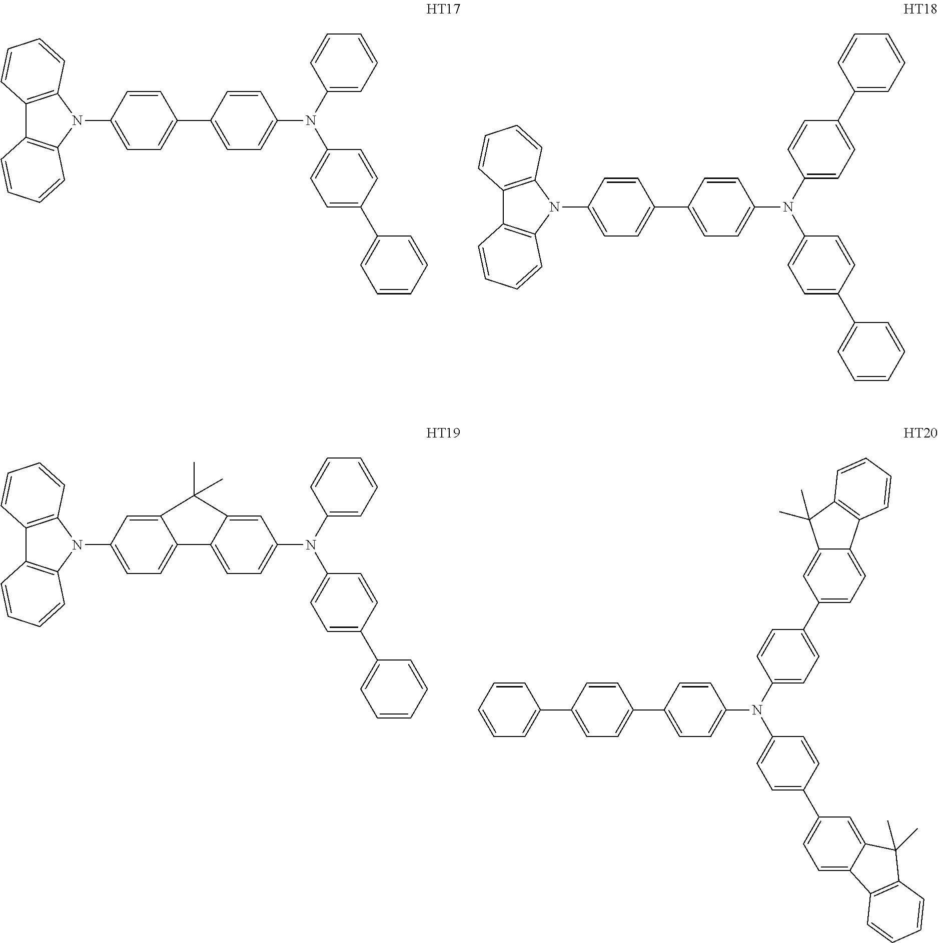 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

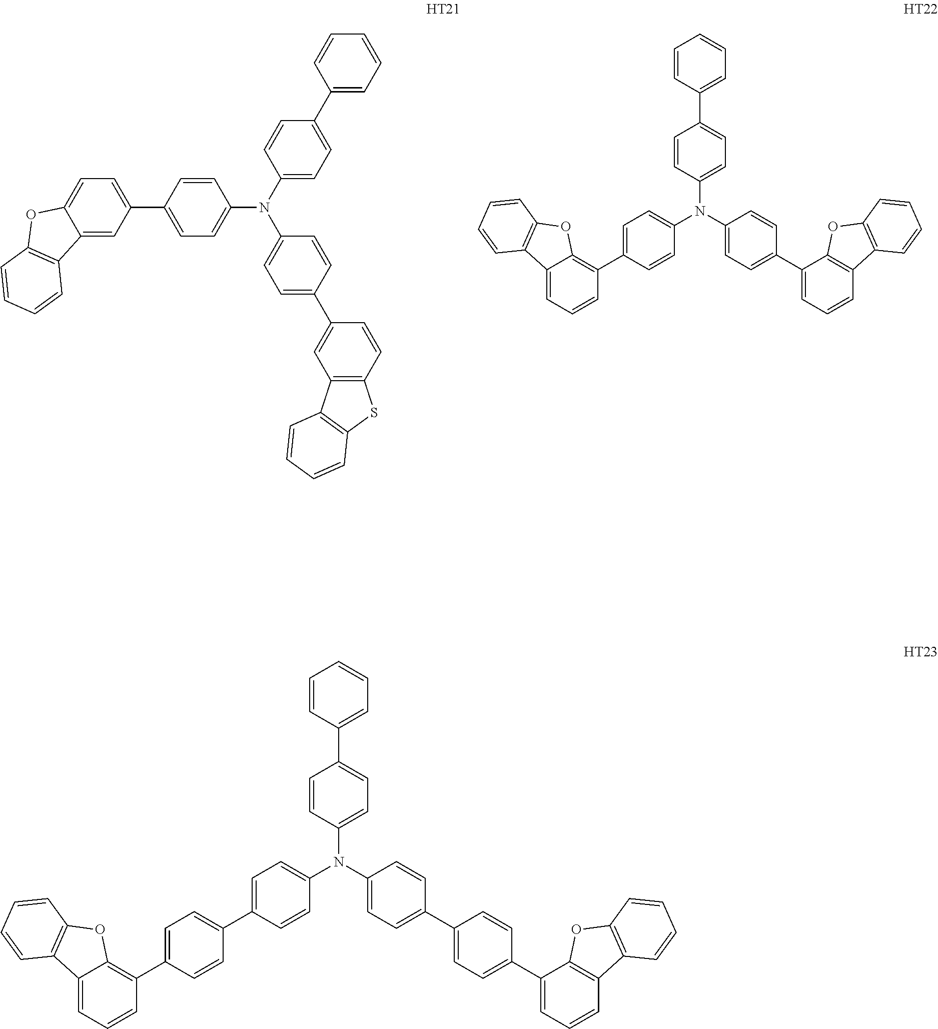 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

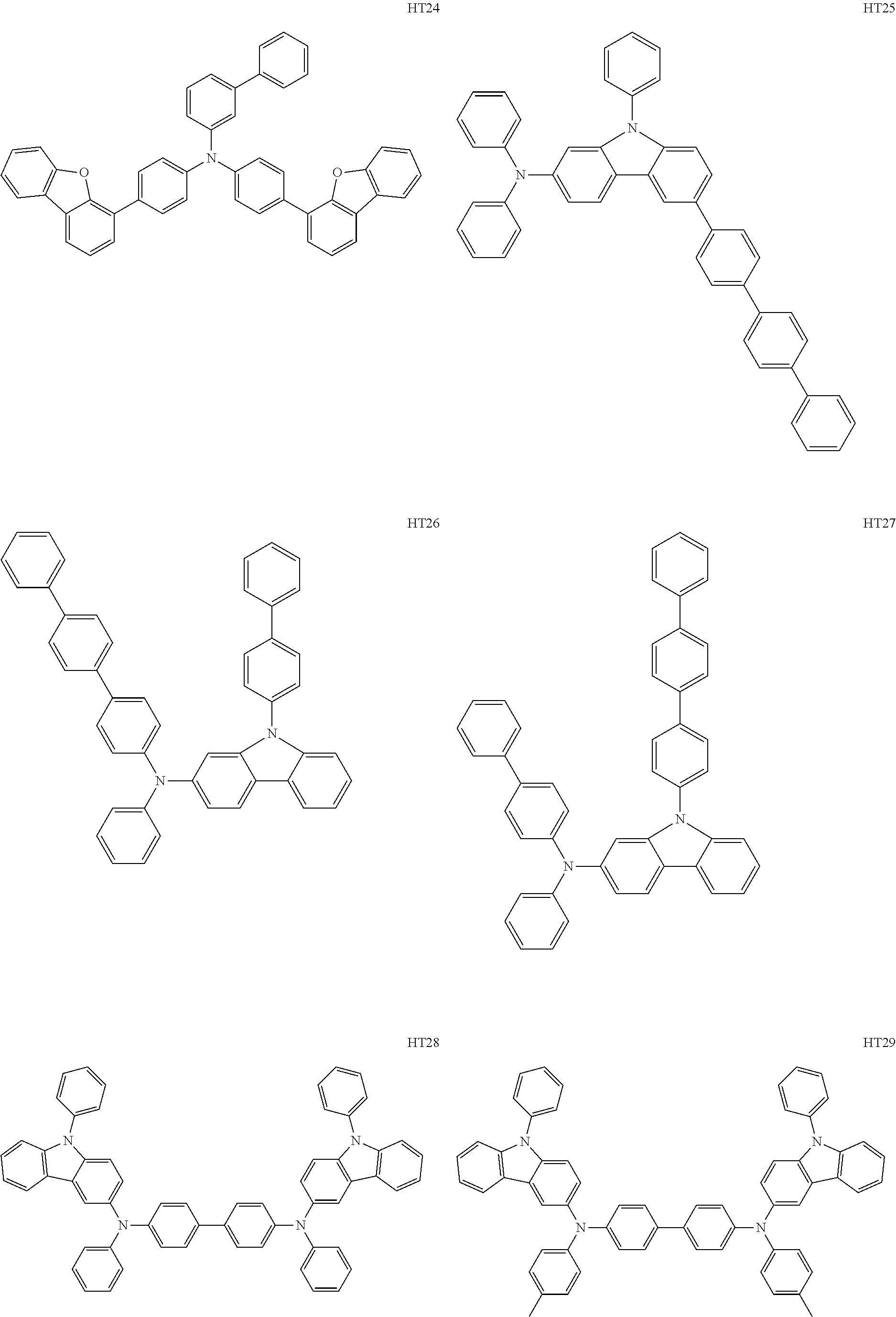

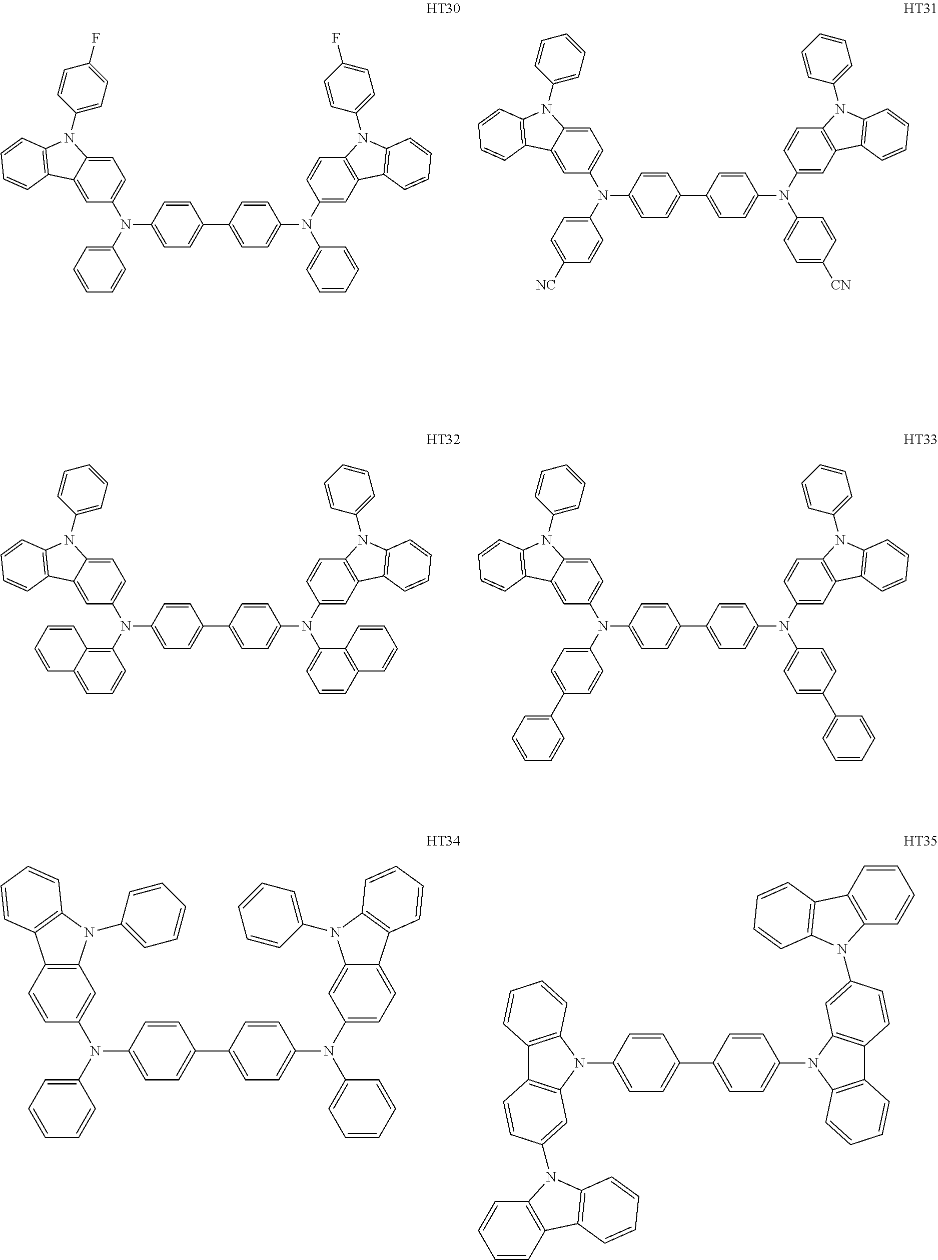

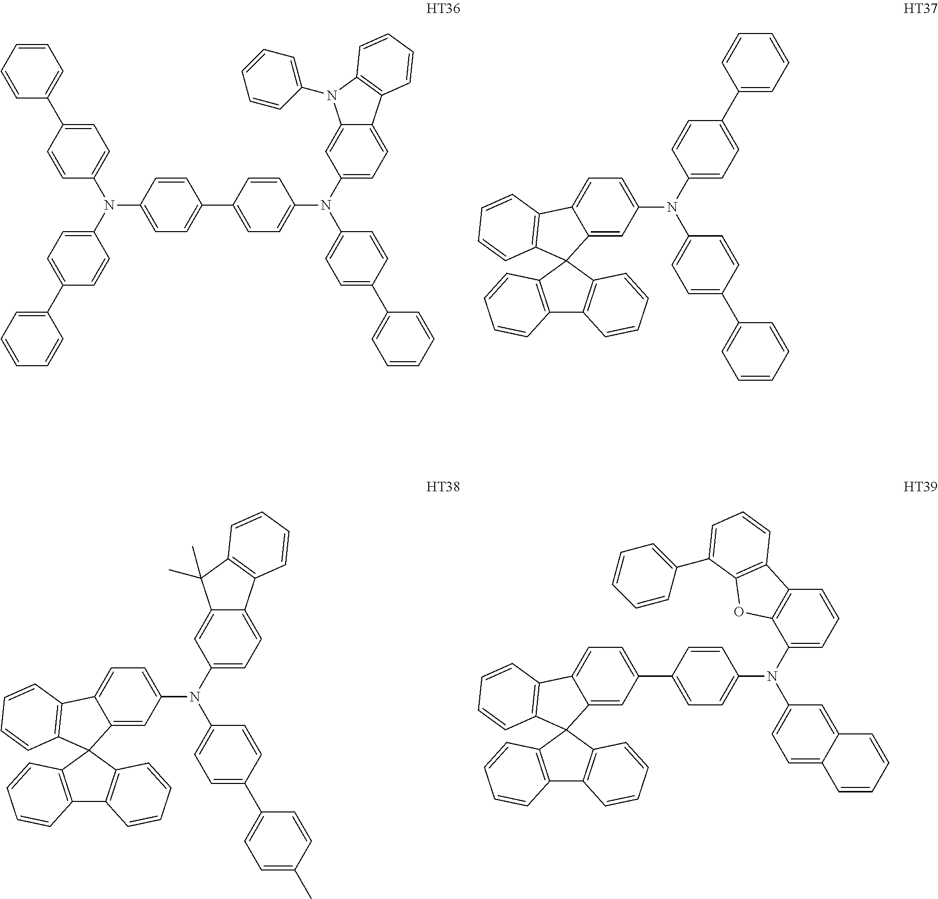 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

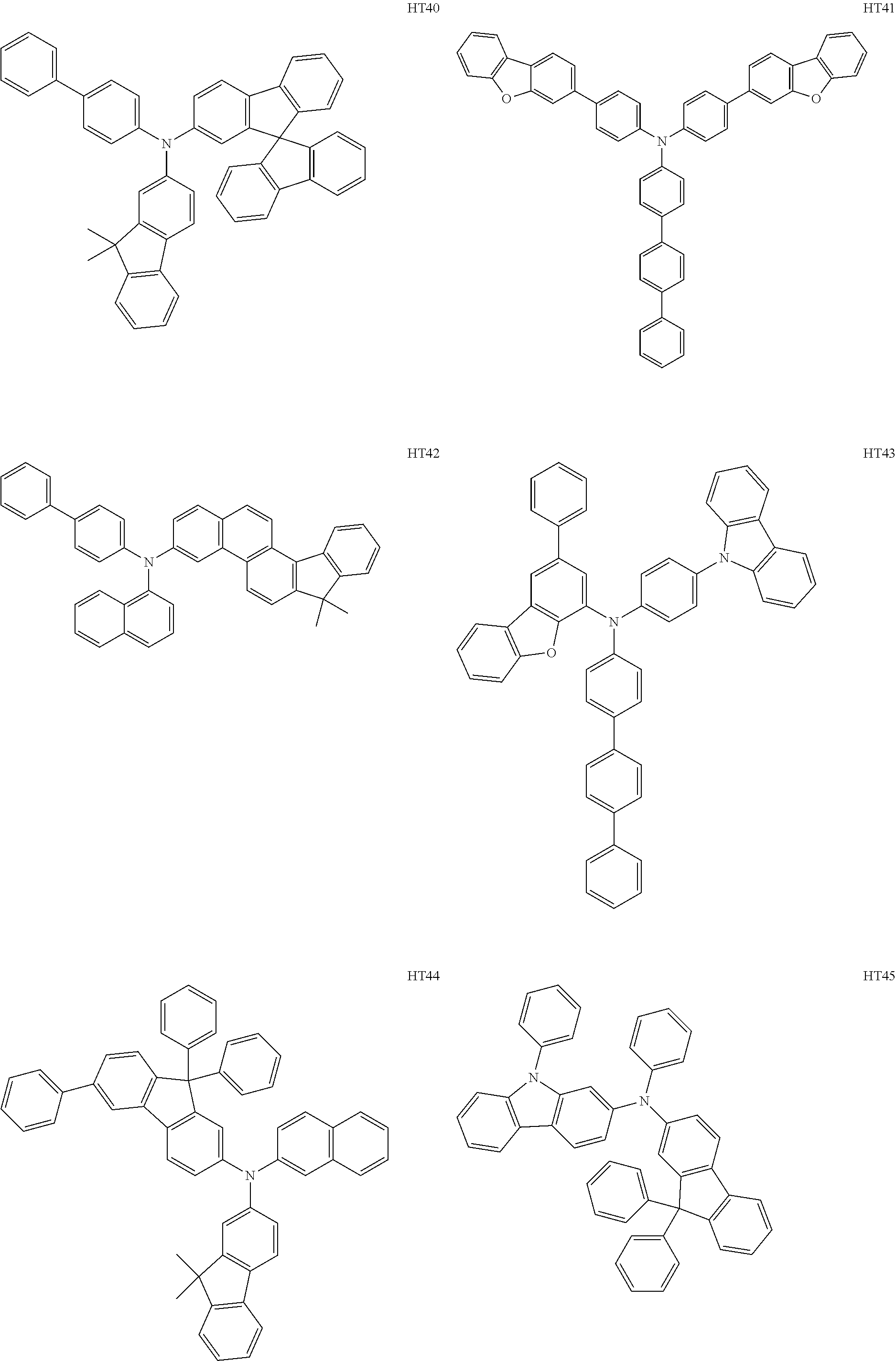

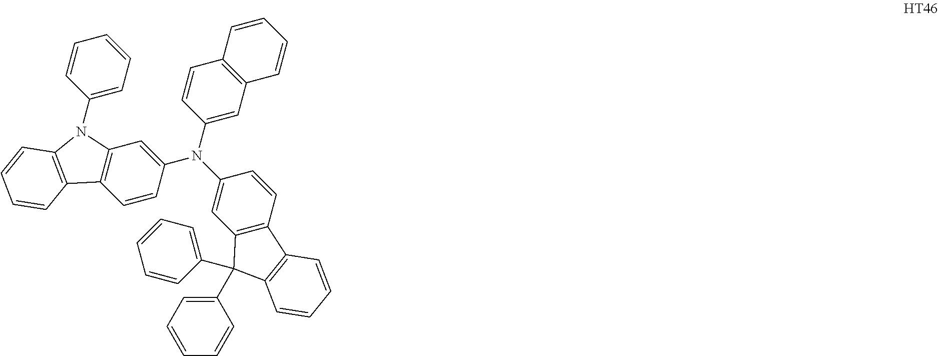 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

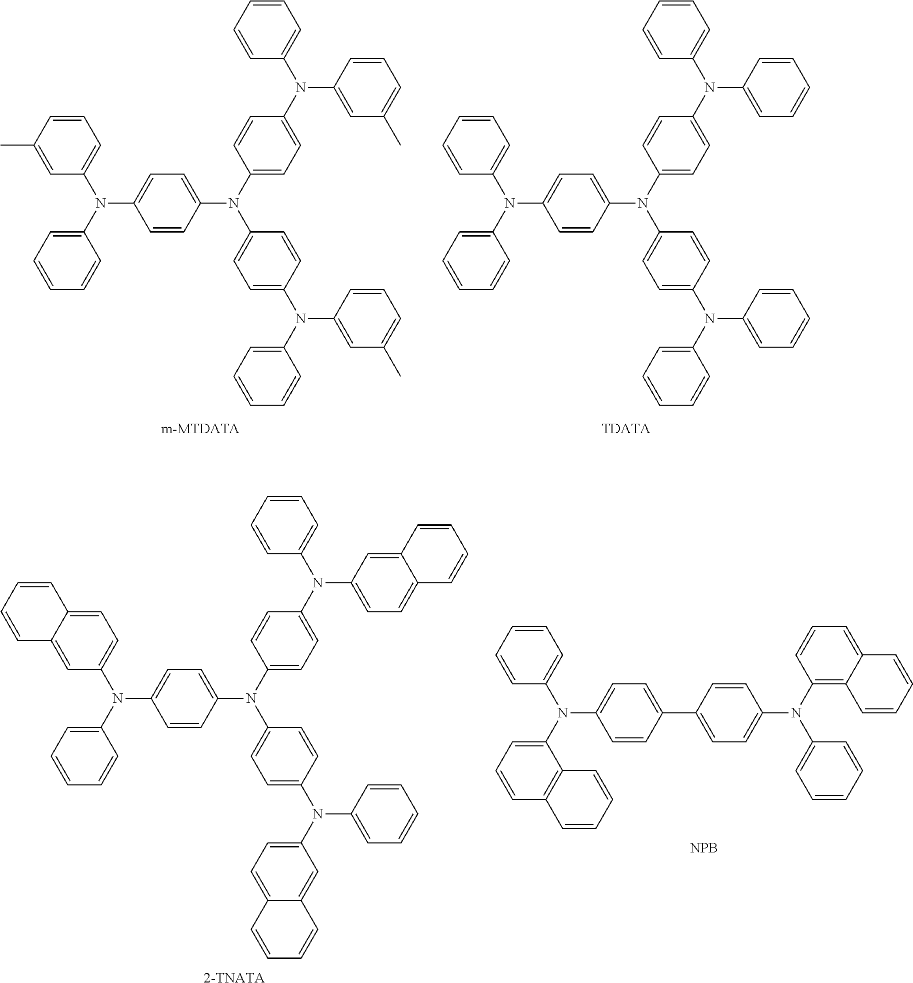

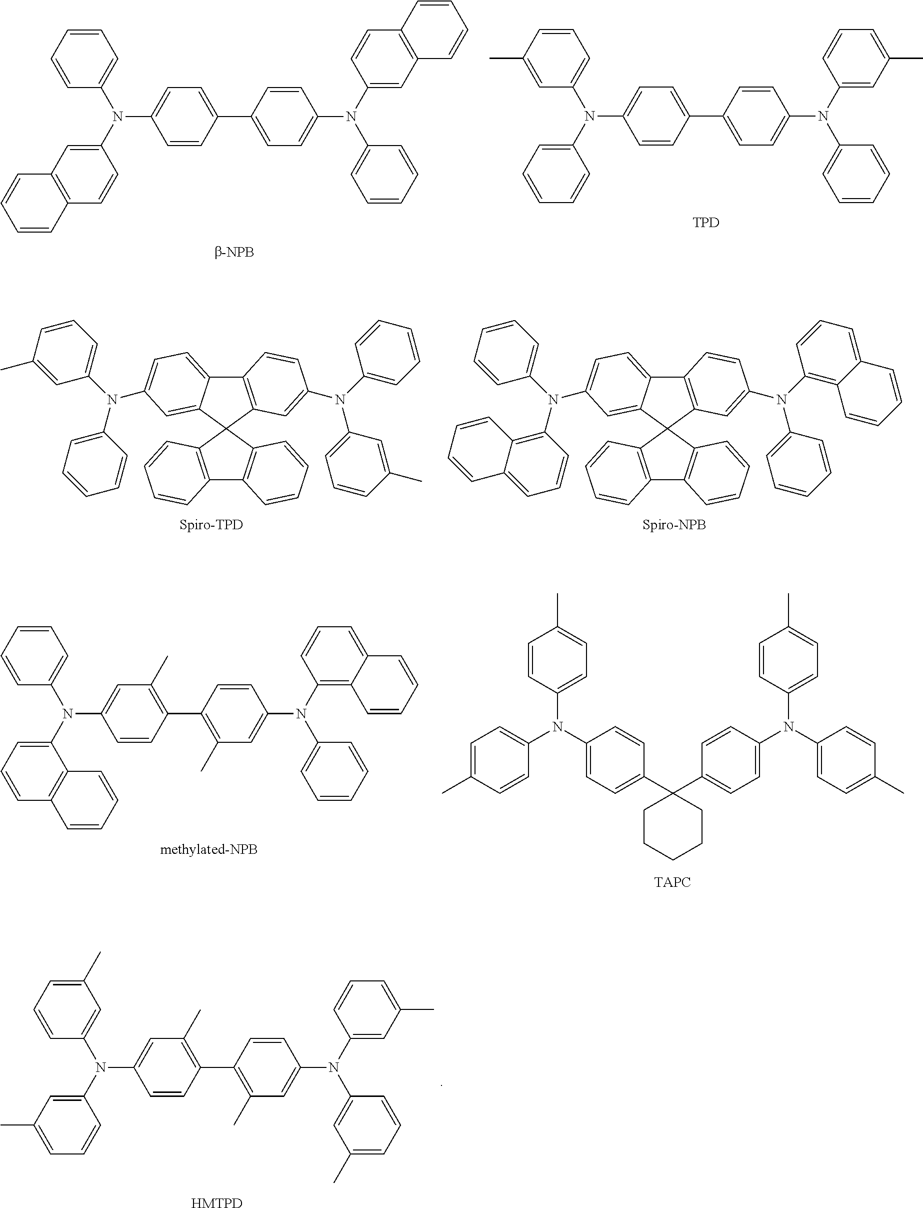

A thickness of the hole transport region 120 may be in a range of about 50 Å to about 10,000 Å, for example, about 100 Å to about 4,000 Å. When the hole transport region 120 includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region 120, the hole injection layer, and the hole transport layer are within these ranges, satisfactory hole-transporting characteristics may be obtained without a substantial increase in driving voltage.

The emission auxiliary layer may increase light-emission efficiency by compensating for an optical resonance distance according to the wavelength of light emitted by the emission layer, and the electron-blocking layer may block or reduce the leakage of electrons from the emission layer to the hole transport region. Materials that may be included in the hole transport region 120 may be included in the emission auxiliary layer and the electron-blocking layer.

p-dopant

In one or more embodiments, the hole transport region 120 may further include, in addition to one or more of the aforementioned materials, a charge-generation material for the improvement of conductive properties. The charge-generating material may be substantially homogeneously or non-homogeneously dispersed (for example, as a single layer including (e.g., consisting of) charge generating material) in the hole transport region 120.

The charge-generation material may be, for example, a p-dopant.

For example, in one or more embodiments, the p-dopant may have a LUMO energy level of about −3.5 eV or less.

In one or more embodiments, the p-dopant may include a quinone derivative, a cyano group-containing compound, a compound including element EL1 and element EL2, or any combination thereof.

Non-limiting examples of the quinone derivative may be tetracyanoquinodimethane (TCNQ), 2,3,5,6-tetrafluoro-7,7,8,8-tetracyanoquinodimethane (F4-TCNQ), etc.

Non-limiting examples of the cyano group-containing compound may be dipyrazino[2,3-f: 2′,3′-h]quinoxaline-2,3,6,7,10,11-hexacarbonitrile (HAT-CN), and a compound represented by Formula 221:

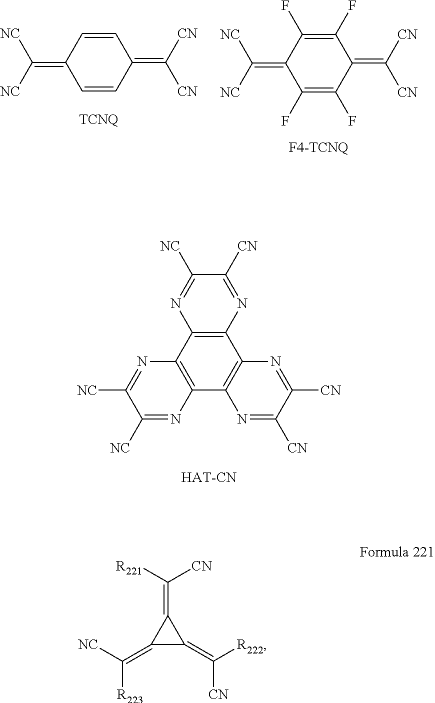

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Non-limiting examples of the metal may be an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and/or a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Non-limiting examples of the metalloid may be silicon (Si), antimony (Sb), and/or tellurium (Te).

Non-limiting examples of the non-metal may be oxygen (O) and/or a halogen (for example, F, Cl, Br, I, etc.).

Non-limiting examples of the compound including element EL1 and element EL2 may be metal oxides, metal halides (for example, metal fluorides, metal chlorides, metal bromides, or metal iodides), metalloid halides (for example, metalloid fluorides, metalloid chlorides, metalloid bromides, or metalloid iodides), metal tellurides, or any combination thereof.

Non-limiting examples of the metal oxide may be tungsten oxides (for example, WO, W₂O₃, WO₂, WO₃, W₂O₅, etc.), vanadium oxides (for example, VO, V₂O₃, VO₂, V₂O₅, etc.), molybdenum oxides (for example, MoO, Mo₂O₃, MoO₂, MoO₃, Mo₂O₅, etc.), rhenium oxides (for example, ReO₃, etc.), and/or the like.

Non-limiting examples of the metal halide may be alkali metal halides, alkaline earth metal halides, transition metal halides, post-transition metal halides, and/or lanthanide metal halides.

Non-limiting examples of the alkali metal halide may be LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Non-limiting examples of the alkaline earth metal halide may be BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and/or BaI₂.

Non-limiting examples of the transition metal halide may be titanium halides (for example, TiF₄, TiCl₄, TiBr₄, TiI₄, etc.), zirconium halides (for example, ZrF₄, ZrCl₄, ZrBr₄, ZrI₄, etc.), hafnium halides (for example, HfF₄, HfCl₄, HfBr₄, HfI₄, etc.), vanadium halides (for example, VF₃, VCl₃, VBr₃, VI₃, etc.), niobium halides (for example, NbF₃, NbCl₃, NbBr₃, NbI₃, etc.), tantalum halides (for example, TaF₃, TaCl₃, TaBr₃, TaI₃, etc.), chromium halides (for example, CrF₃, CrCl₃, CrBr₃, CrI₃, etc.), molybdenum halides (for example, MoF₃, MoCl₃, MoBr₃, Mol₃, etc.), tungsten halides (for example, WF₃, WCl₃, WBr₃, WI₃, etc.), manganese halides (for example, MnF₂, MnCl₂, MnBr₂, MnI₂, etc.), technetium halides (for example, TcF₂, TcCl₂, TcBr₂, TcI₂, etc.), rhenium halides (for example, ReF₂, ReCl₂, ReBr₂, Rel₂, etc.), ferrous halides (for example, FeF₂, FeCl₂, FeBr₂, Fel₂, etc.), ruthenium halides (for example, RuF₂, RuCl₂, RuBr₂, RuI₂, etc.), osmium halides (for example, OsF₂, OsCl₂, OsBr₂, Os₁₂, etc.), cobalt halides (for example, CoF₂, COCl₂, CoBr₂, CoI₂, etc.), rhodium halides (for example, RhF₂, RhCl₂, RhBr₂, RhI₂, etc.), iridium halides (for example, IrF₂, IrCl₂, IrBr₂, IrI₂, etc.), nickel halides (for example, NiF₂, NiCl₂, NiBr₂, NiI₂, etc.), palladium halides (for example, PdF₂, PdCl₂, PdBr₂, PdI₂, etc.), platinum halides (for example, PtF₂, PtCl₂, PtBr₂, PtI₂, etc.), cuprous halides (for example, CuF, CuCl, CuBr, CuI, etc.), silver halides (for example, AgF, AgCl, AgBr, AgI, etc.), and/or gold halides (for example, AuF, AuCl, AuBr, AuI, etc.).

Non-limiting examples of the post-transition metal halide may be zinc halides (for example, ZnF₂, ZnCl₂, ZnBr₂, ZnI₂, etc.), indium halides (for example, InI₃, etc.), tin halides (for example, SnI₂, etc.), and/or the like.

Non-limiting examples of the lanthanide metal halide may be YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Non-limiting examples of the metalloid halide may be antimony halides (for example, SbCl₅ and/or the like) and/or the like.

Non-limiting examples of the metal telluride may be alkali metal tellurides (for example, Li₂Te, Na₂Te, K₂Te, Rb₂Te, Cs₂Te, etc.), alkaline earth metal tellurides (for example, BeTe, MgTe, CaTe, SrTe, BaTe, etc.), transition metal tellurides (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal tellurides (for example, ZnTe, etc.), and/or lanthanide metal tellurides (for example, LaTe, CeTe, PrTe, NdTe, PmTe, EuTe, GdTe, TbTe, DyTe, HoTe, ErTe, TmTe, YbTe, LuTe, etc.).

### Emission Layer 130

The light-emitting device 10 may include an emission layer 130 on the hole transport region 120.

In one or more embodiments, the emission layer 130 may further include, in addition to one or more suitable organic materials, a metal-containing compound such as an organometallic compound, an inorganic material such as a quantum dot, and/or the like.

The emission layer 130 may include i) two or more emitting units sequentially stacked between the first electrode 110 and the second electrode 150, and ii) a charge generation layer located between the two or more emitting units. When the emission layer 130 includes the emitting units and the charge generation layer as described herein, the light-emitting device 10 may be a tandem light-emitting device.

When the light-emitting device 10 is a full-color light-emitting device, the emission layer may be patterned into a red emission layer, a green emission layer, and/or a blue emission layer, according to a sub-pixel. In one or more embodiments, the emission layer 130 may have a stacked structure of two or more layers selected from the red emission layer, the green emission layer, and the blue emission layer, in which the two or more layers contact each other or are separated from each other to emit white light (e.g., combined white light). In one or more embodiments, the emission layer 130 may include two or more materials selected from a red light-emitting material, a green light-emitting material, and a blue light-emitting material, in which the two or more materials are mixed with each other in a single layer to emit white light (e.g., combined white light).

In one or more embodiments, the emission layer 130 may include a host and a dopant. The dopant may include a phosphorescent dopant, a fluorescent dopant, or any combination thereof.

An amount of the dopant in the emission layer 130 may be from about 0.01 part by weight to about 15 parts by weight with respect to 100 parts by weight of the host.

In one or more embodiments, the emission layer 130 may include a quantum dot.

In one or more embodiments, the emission layer 130 may include a delayed fluorescence material. The delayed fluorescence material may act as a host or a dopant in the emission layer.

A thickness of the emission layer 130 may be in a range of about 100 Å to about 1,000 Å, and, in some embodiments, about 200 Å to about 600 Å. When the thickness of the emission layer 130 is within the range, excellent or suitable luminescence characteristics may be obtained without a substantial increase in driving voltage.

### Host

In one or more embodiments, the host may include a compound represented by Formula 301:

[Ar₃₀₁]_{xb11}-[(L₃₀₁)_{xb1}-R₃₀₁]_{xb21}, Formula 301
wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ are each the same as described herein with respect to Q₁.

For example, in some embodiments, when xb11 in Formula 301 is 2 or more, two or more of Ar₃₀₁ (s) may be linked to each other via a single bond.

In one or more embodiments, the host may include a compound represented by Formula 301-1, a compound represented by Formula 301-2, or any combination thereof:

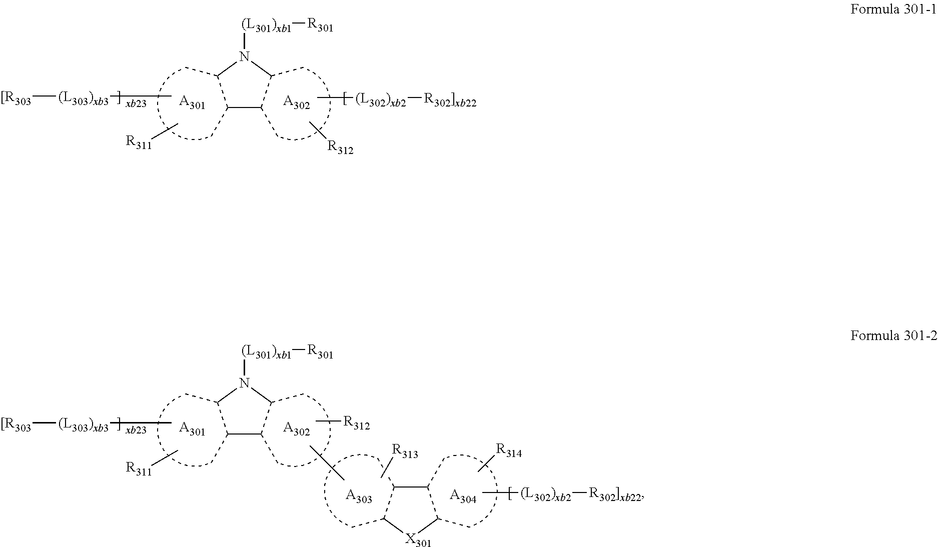

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described herein with respect to with L₃₀₁,
xb2 to xb4 may each independently be the same as described herein with respect to xb1, and
R₃₀₂ to R₃₀₅ and R₃₁₁ to R₃₁₄ may each be the same as described herein with respect to R₃₀₁.

In one or more embodiments, the host may include an alkaline earth metal complex, a post-transition metal complex, or any combination thereof. For example, the host may include a Be complex (for example, Compound H55), an Mg complex, a Zn complex, or any combination thereof.

In one or more embodiments, the host may include: at least one selected from among Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di(9H-carbazol-9-yl)benzene (mCP); 1,3,5-tri(carbazol-9-yl)benzene (TCP); or any combination thereof:

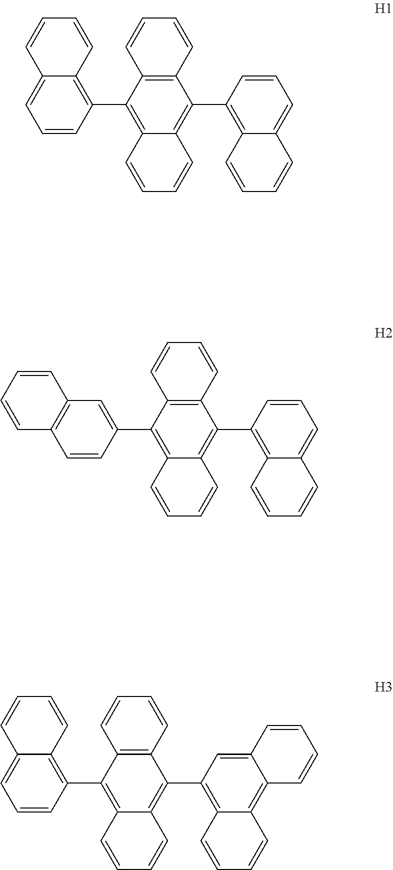

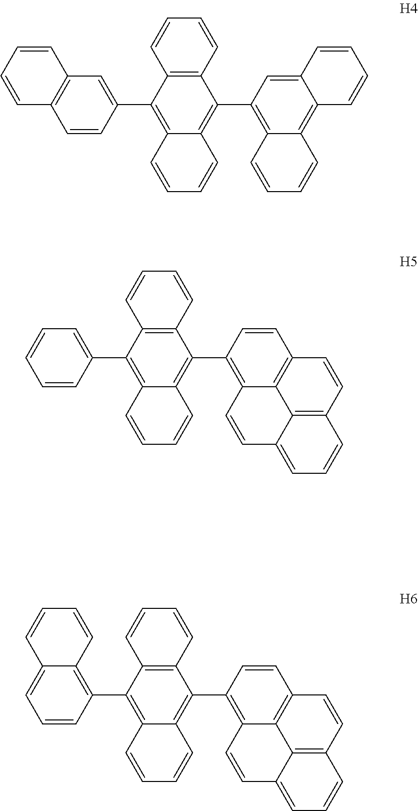

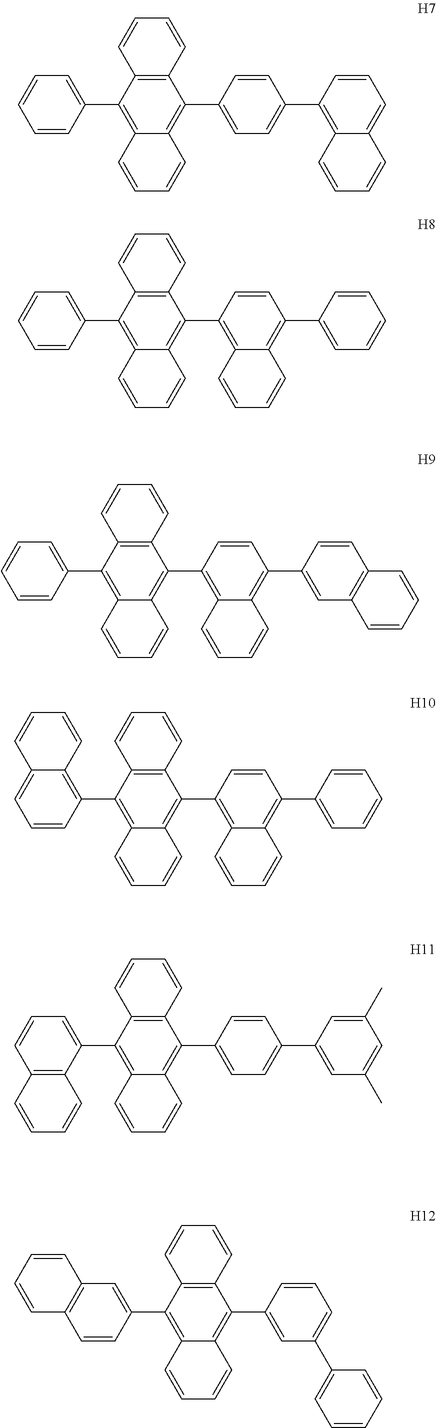

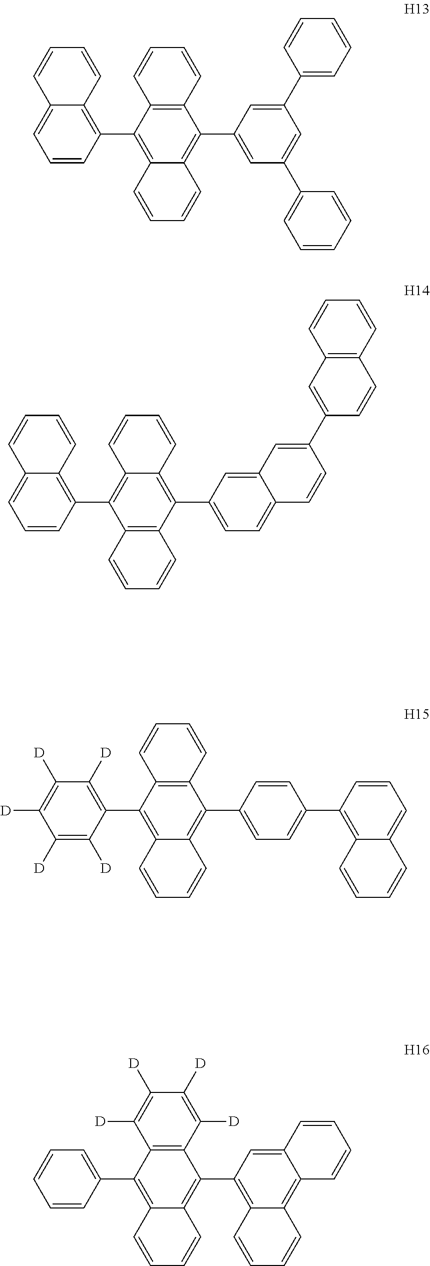

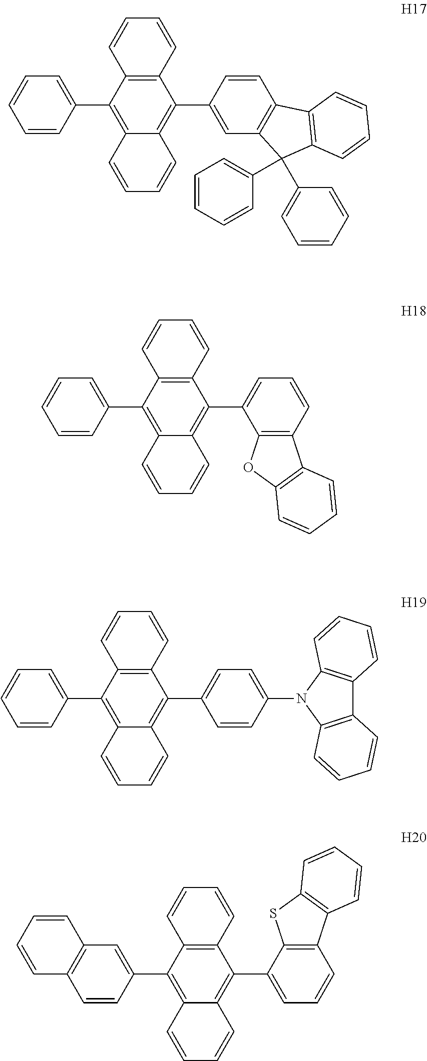

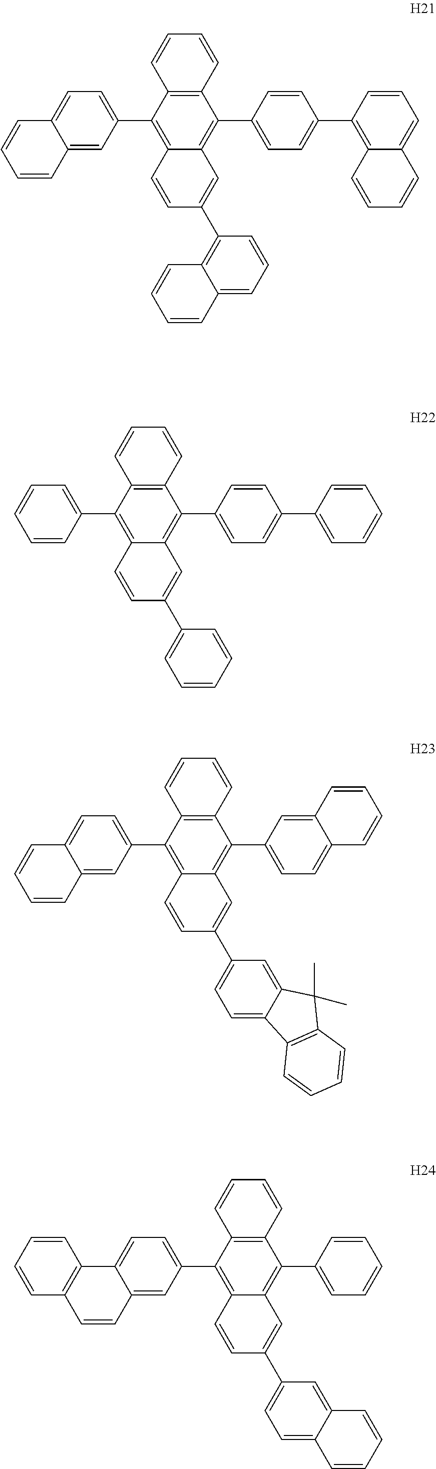

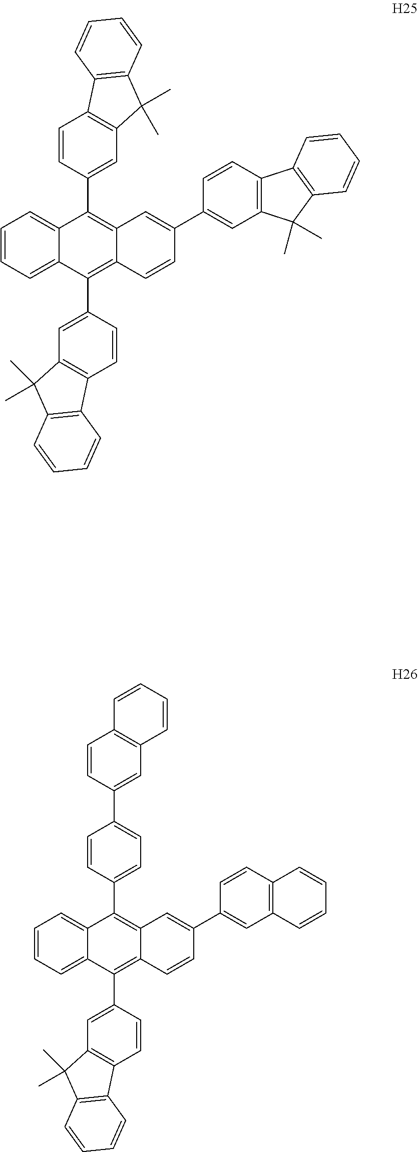

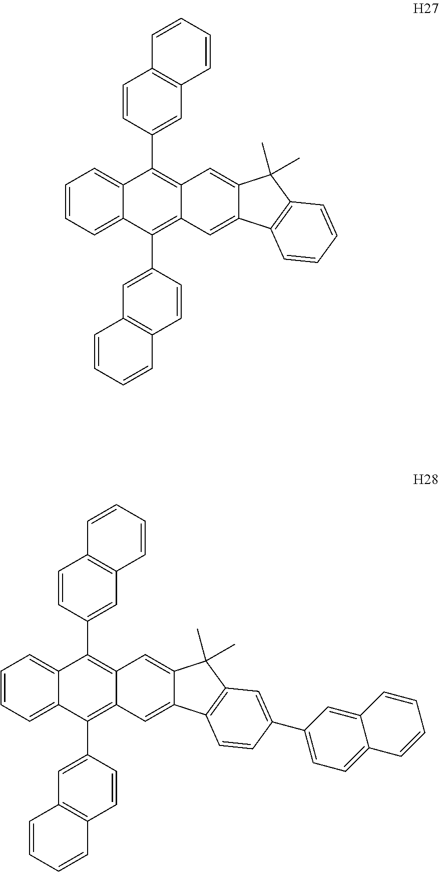

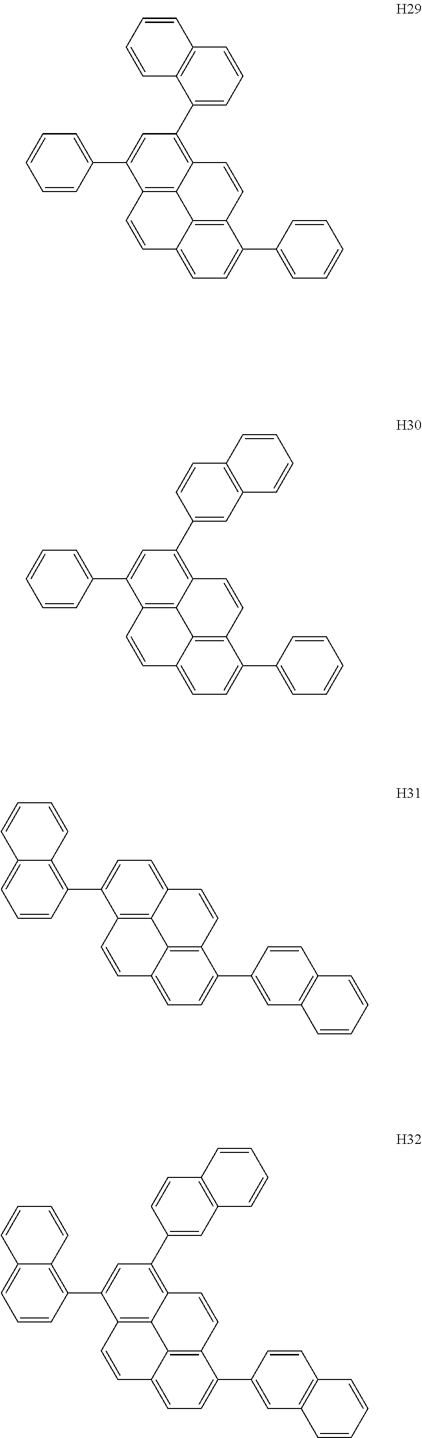

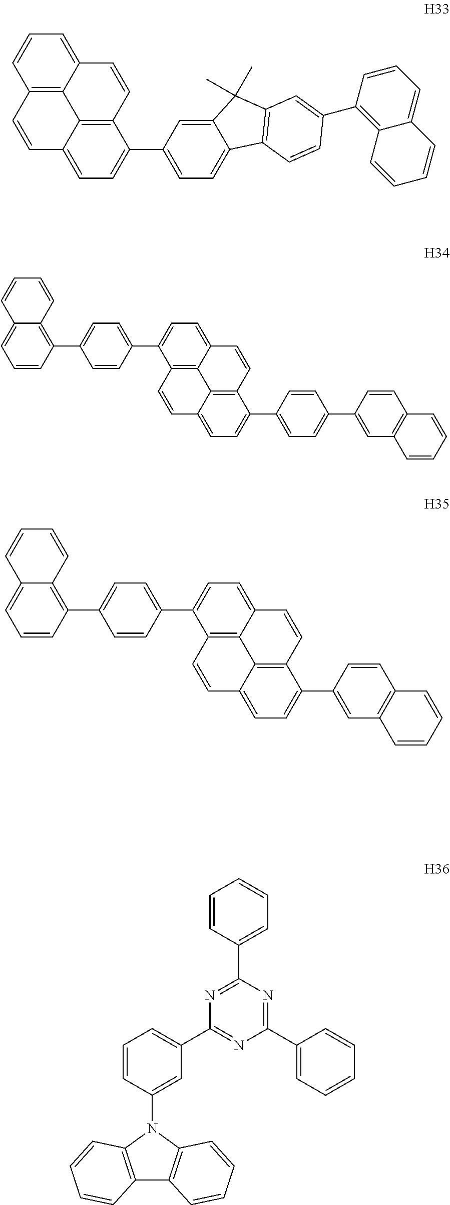

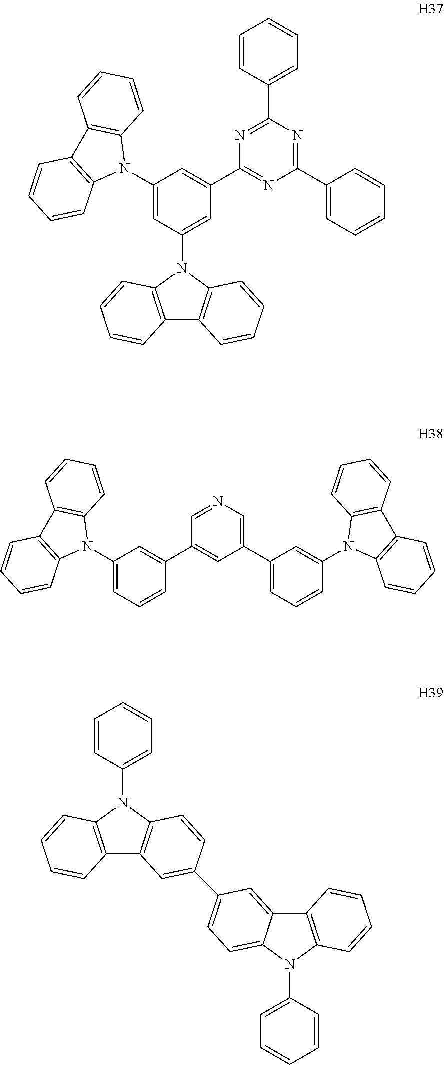 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

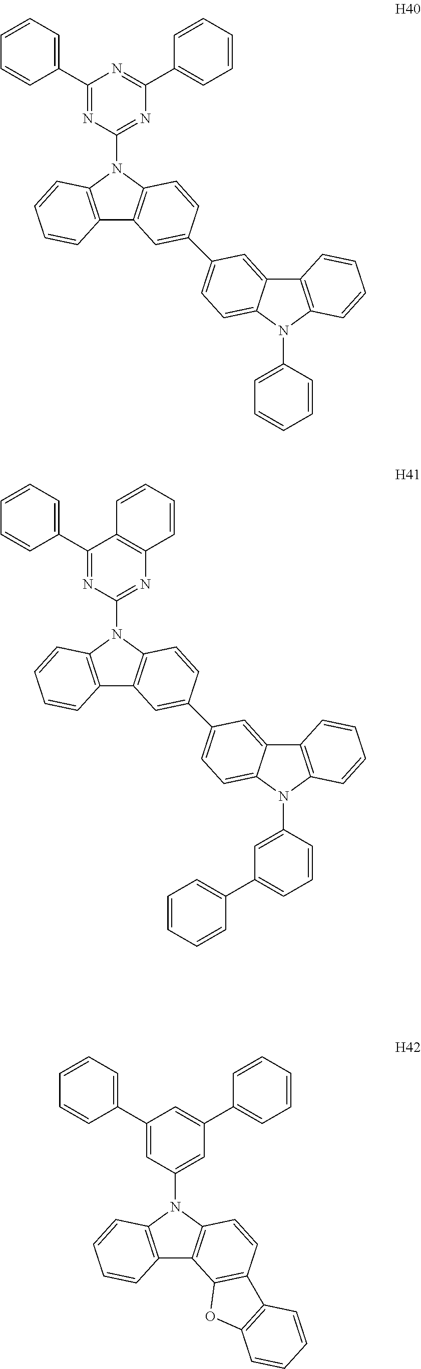 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

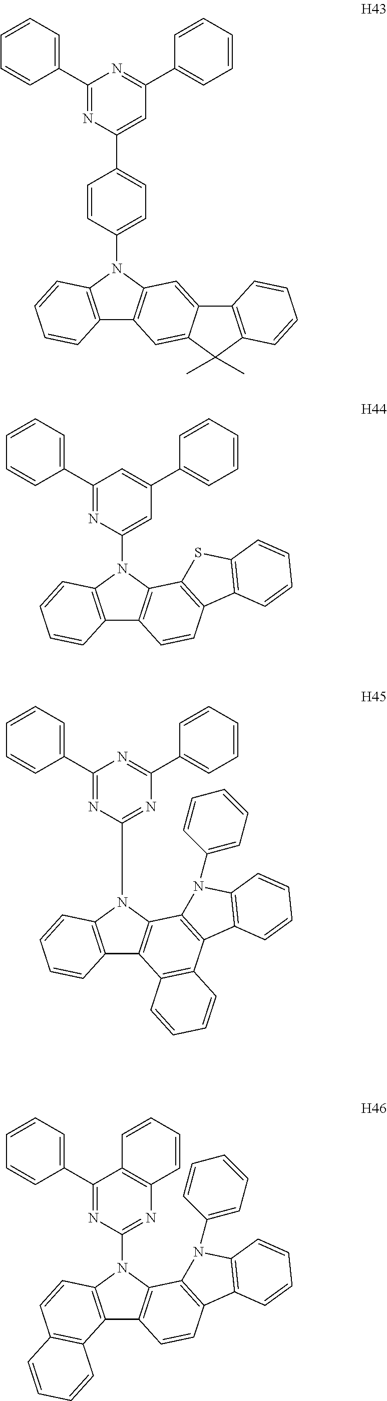 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

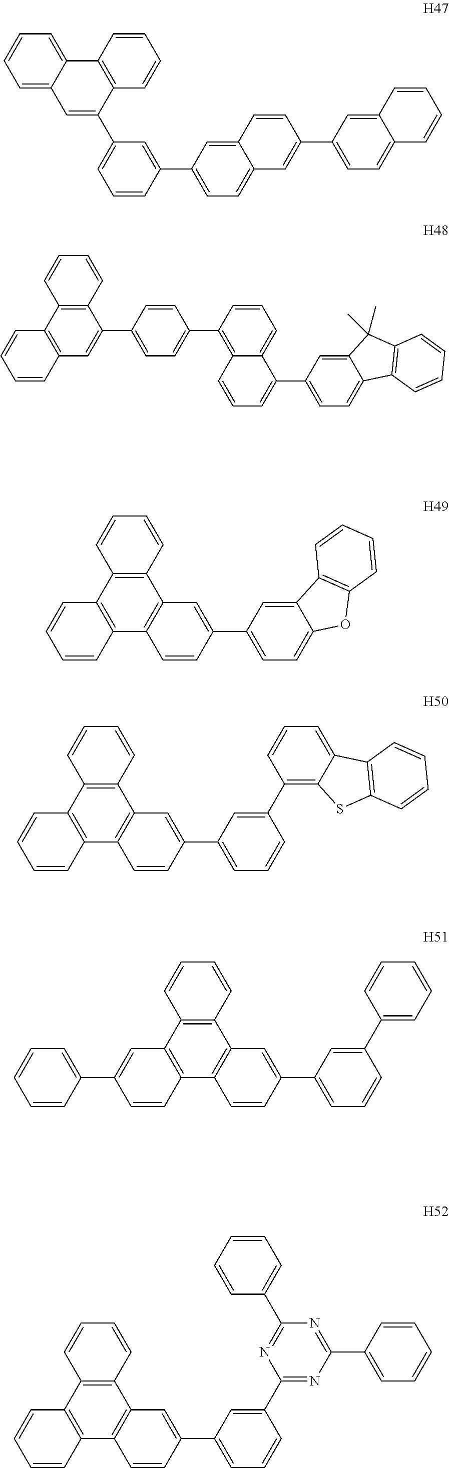

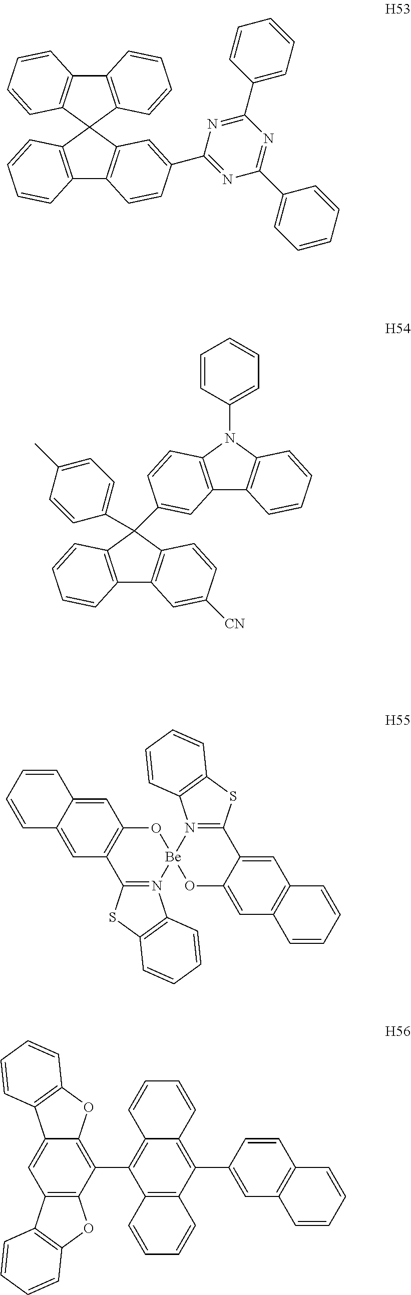

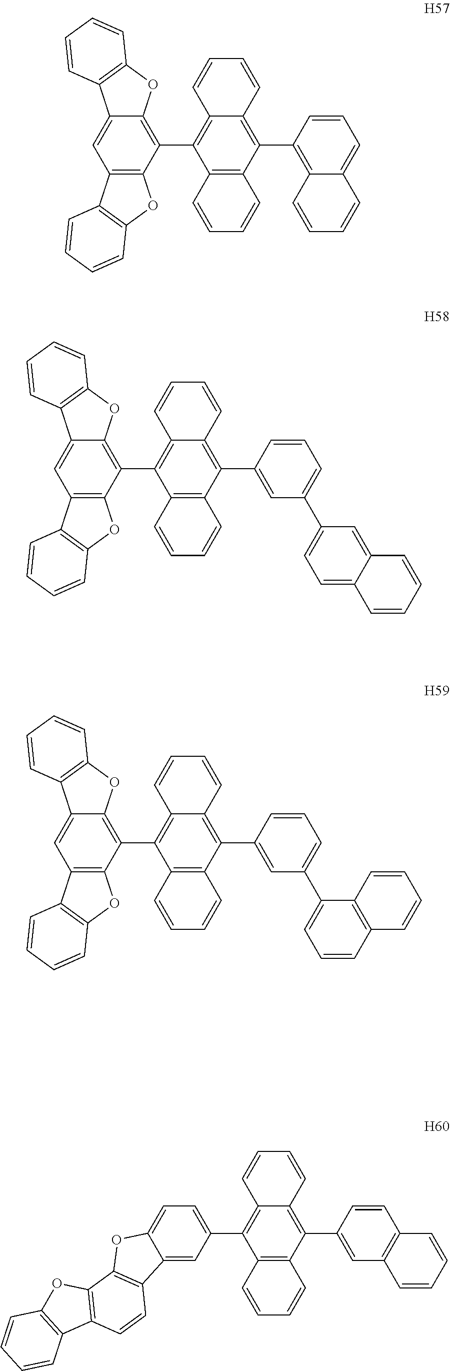 [SMILES: c1ccc2c(-c3c4ccccc4c(-c4c5oc6ccccc6c5cc5c4oc4ccccc45)c4ccccc34)cccc2c1 ; c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1]

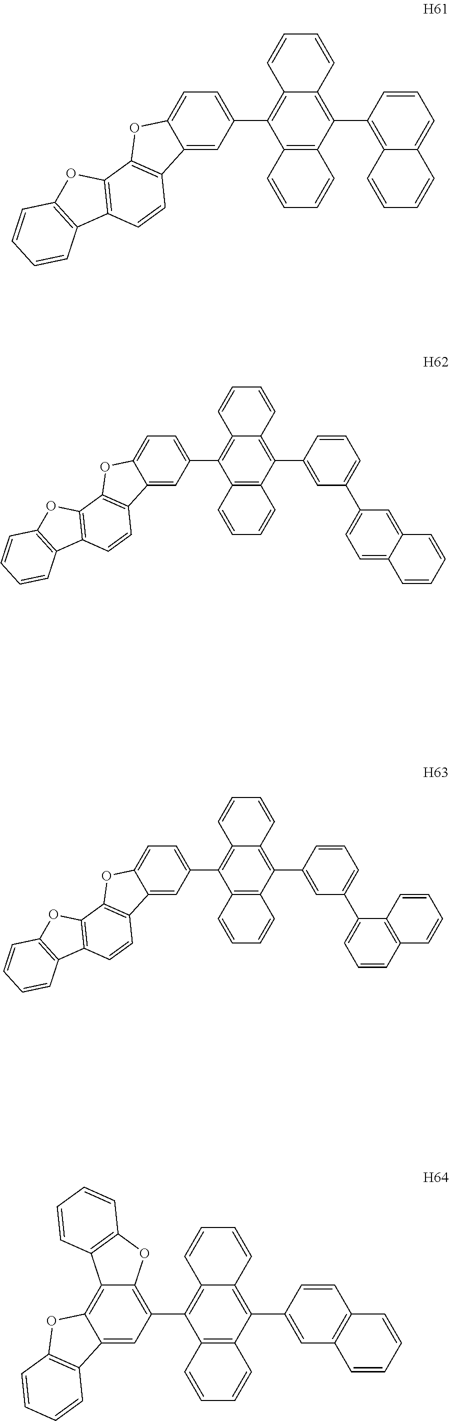 [SMILES: c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

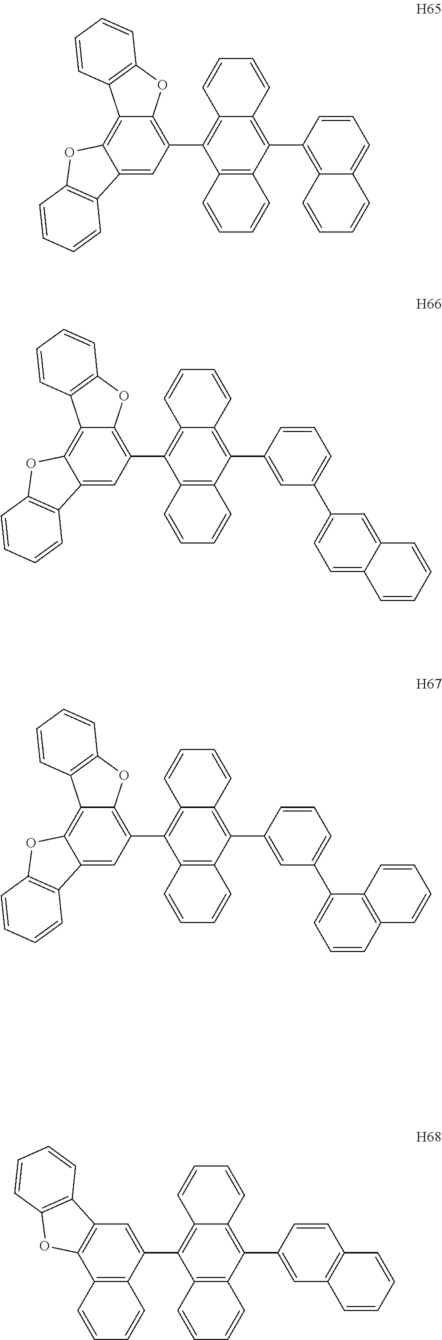 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1]

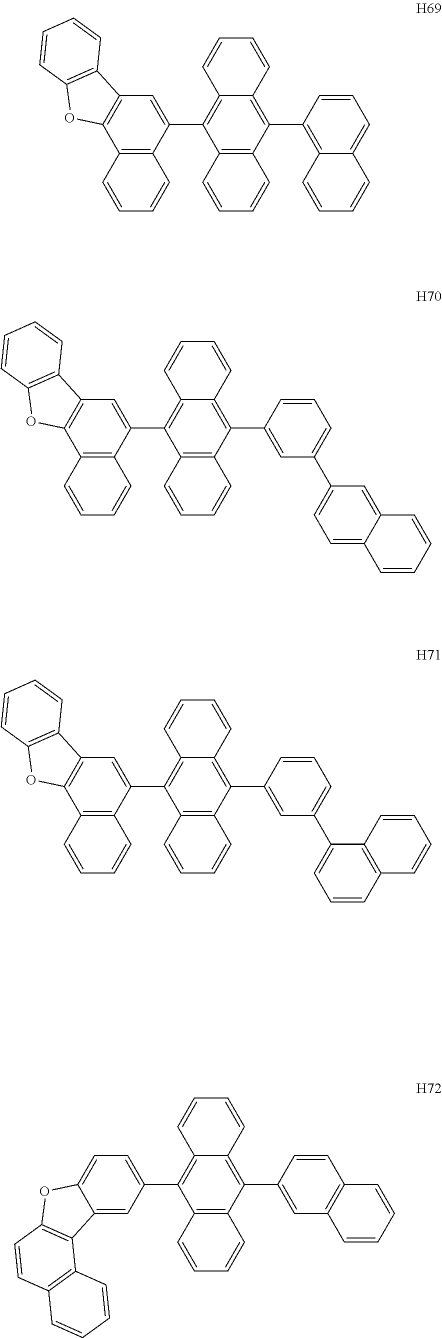 [SMILES: c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

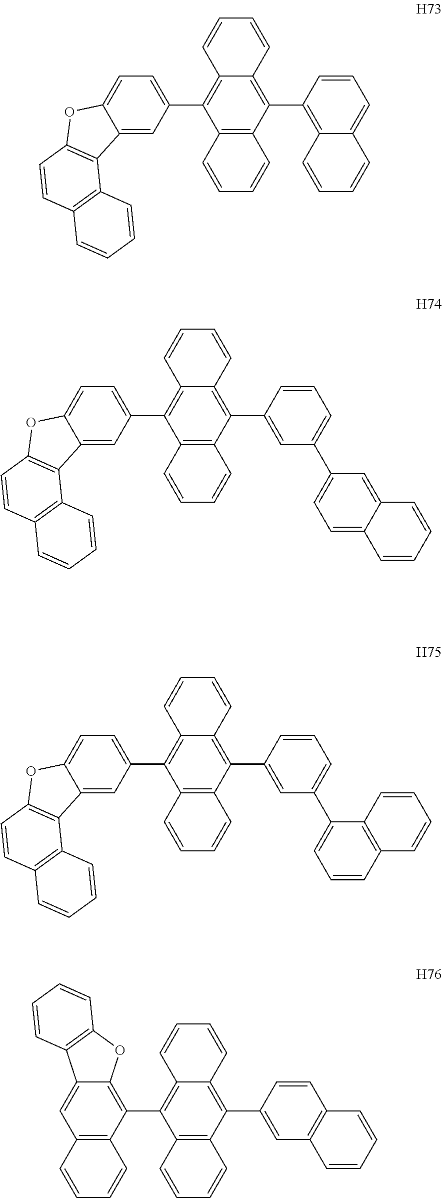 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1]

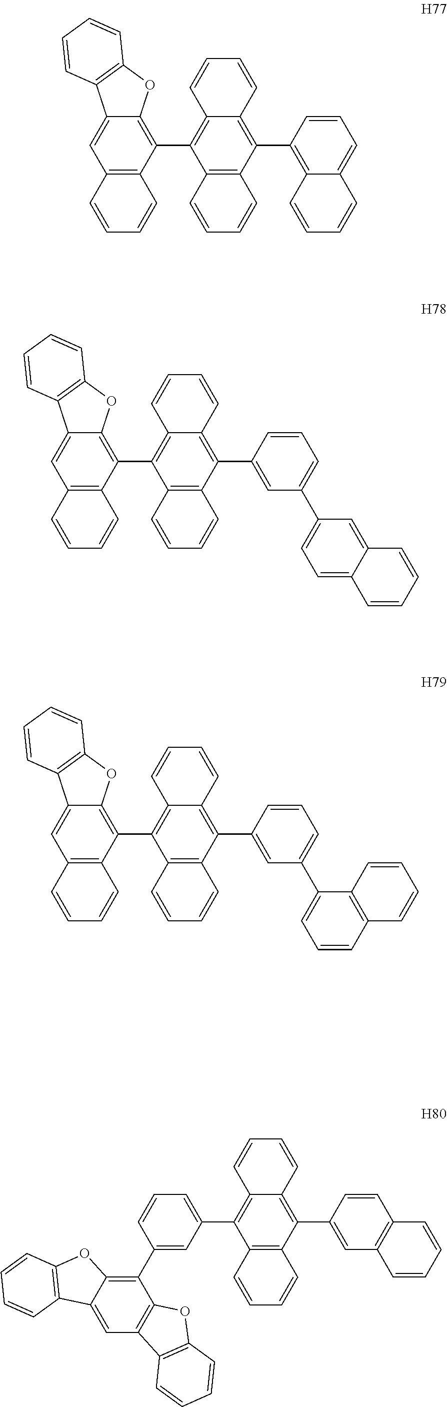 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1]

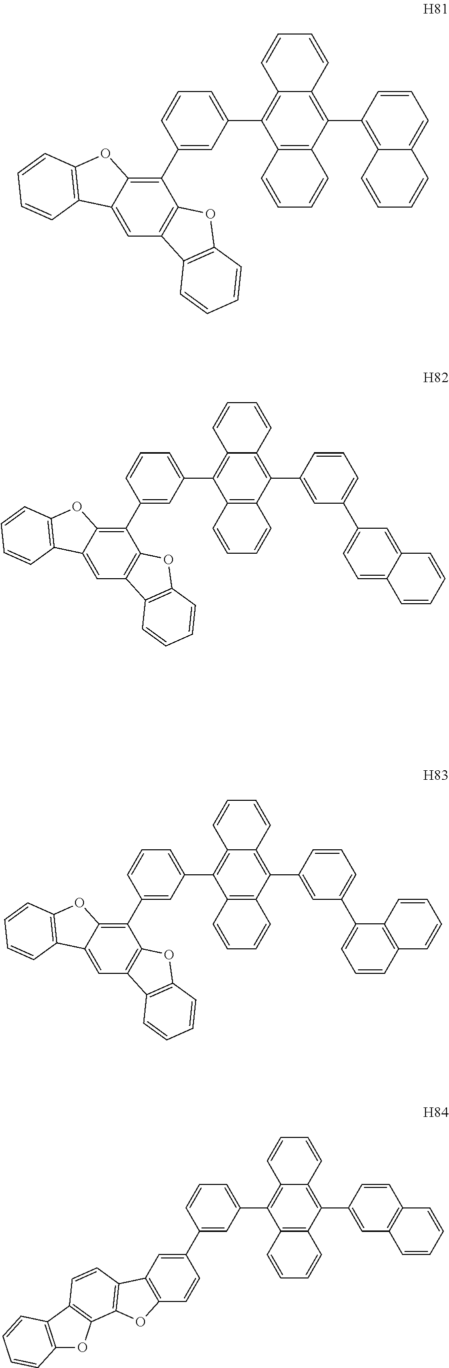 [SMILES: c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

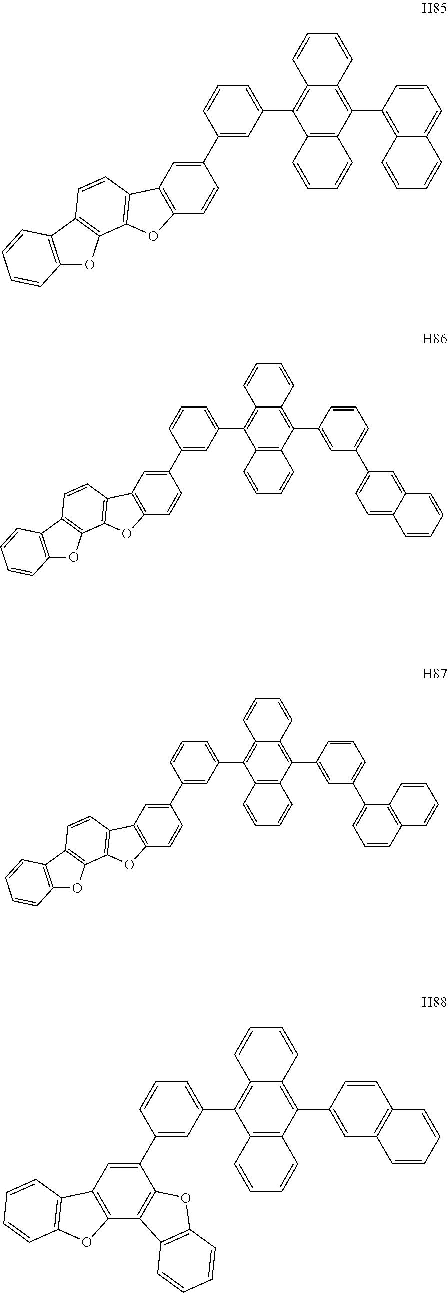 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

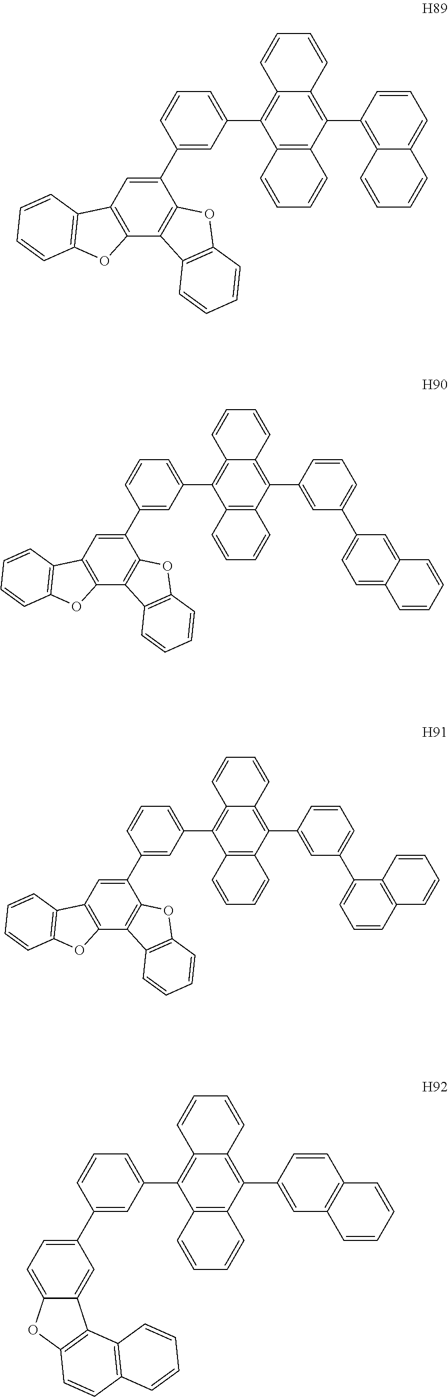 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

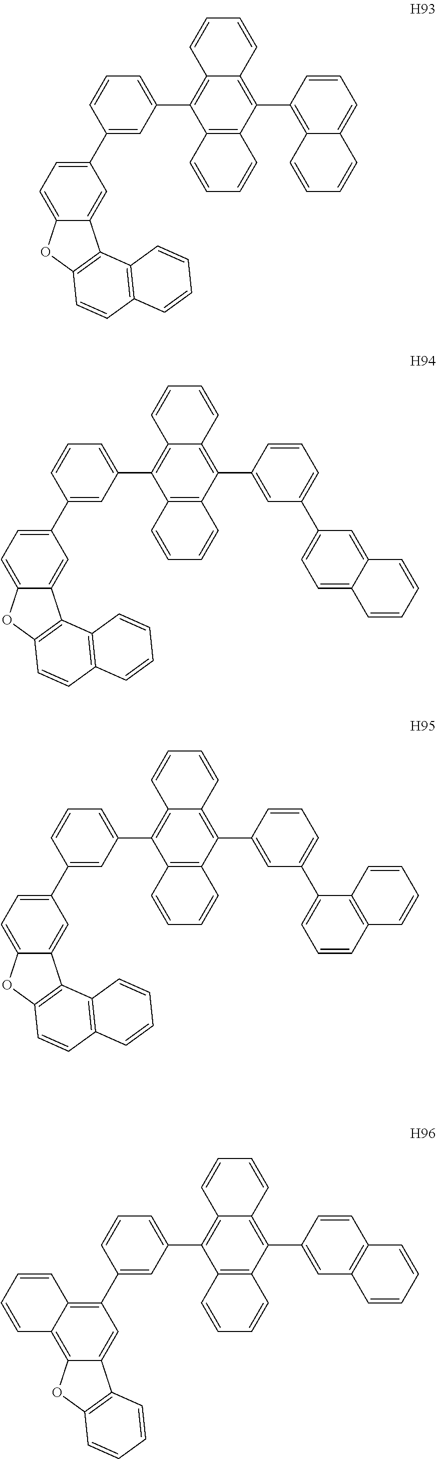 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

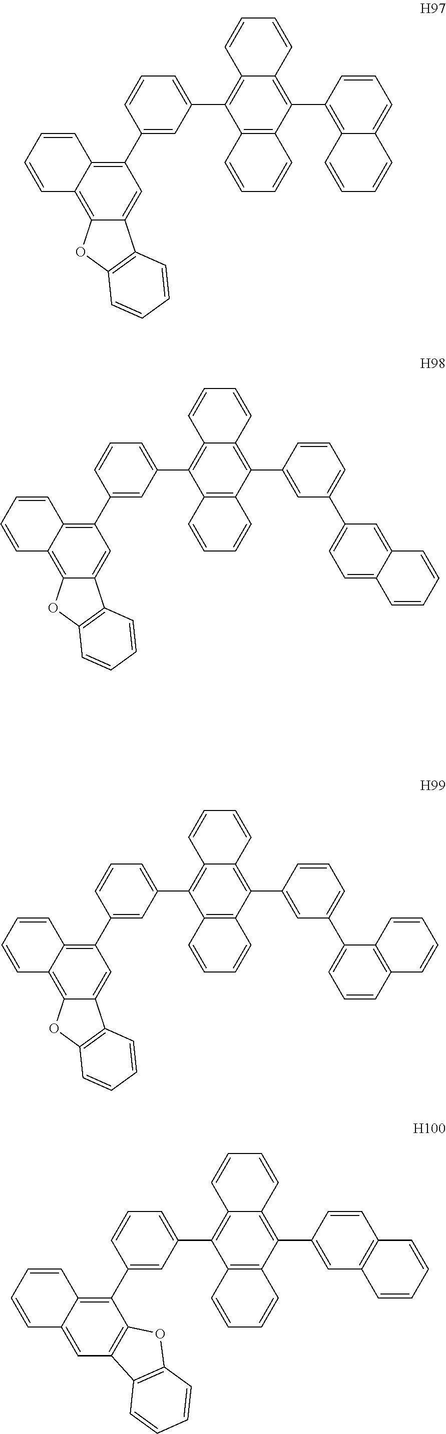 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1]

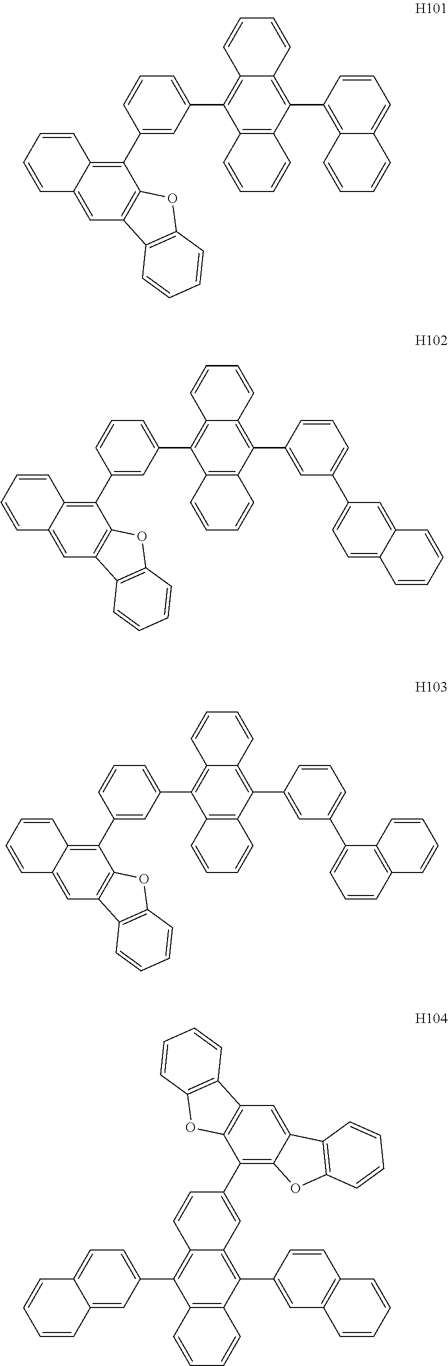 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

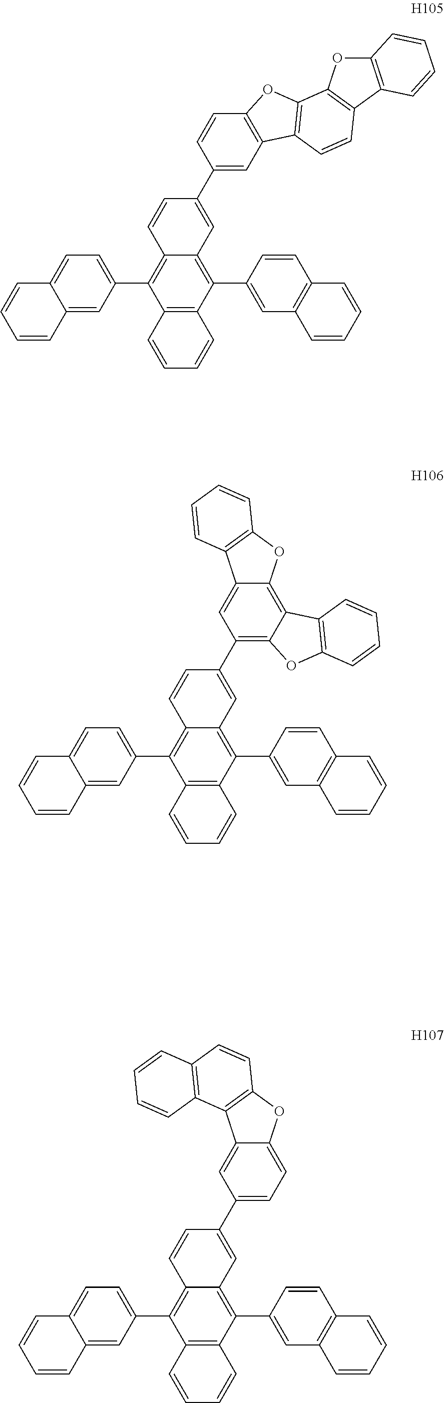 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1]

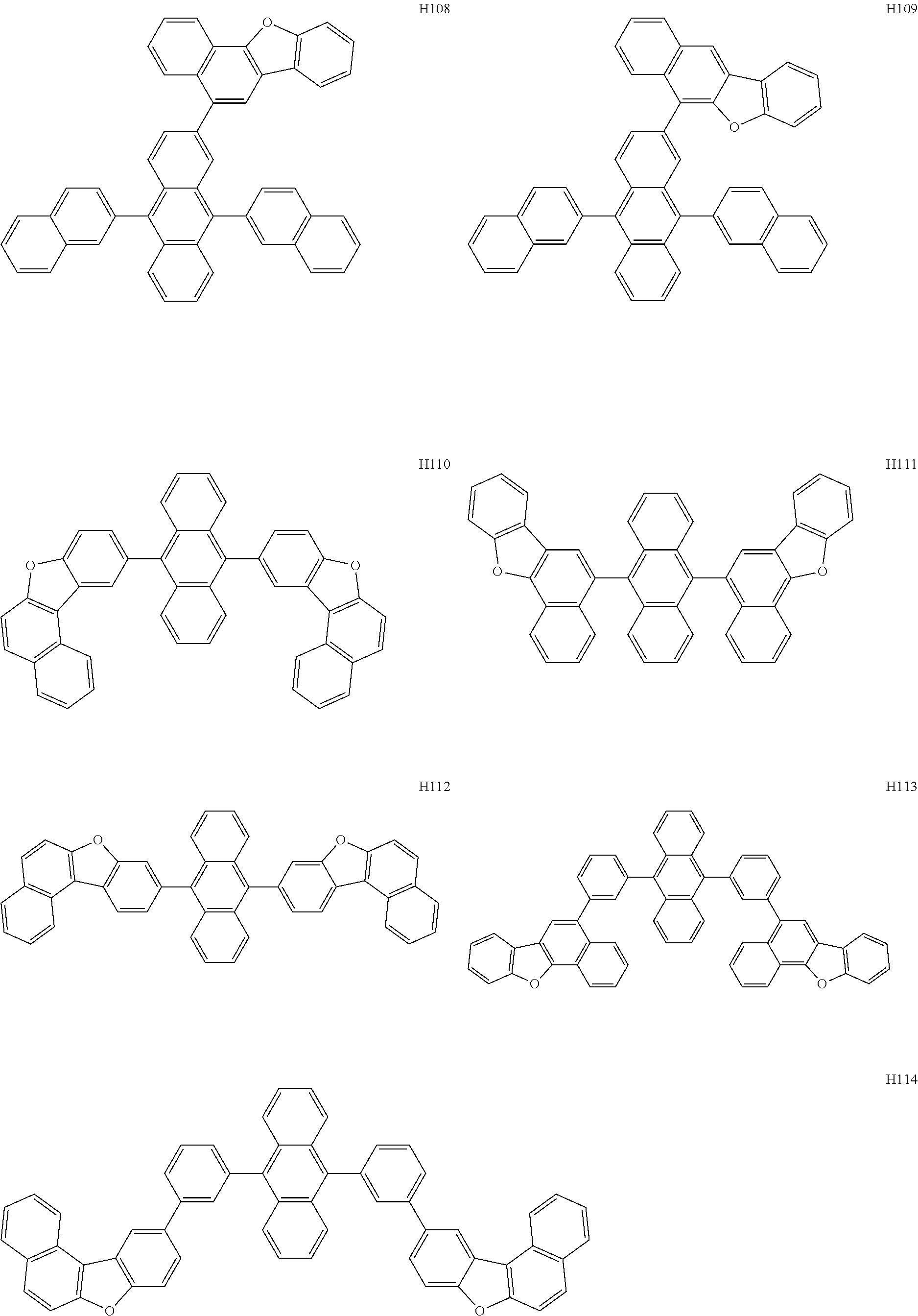

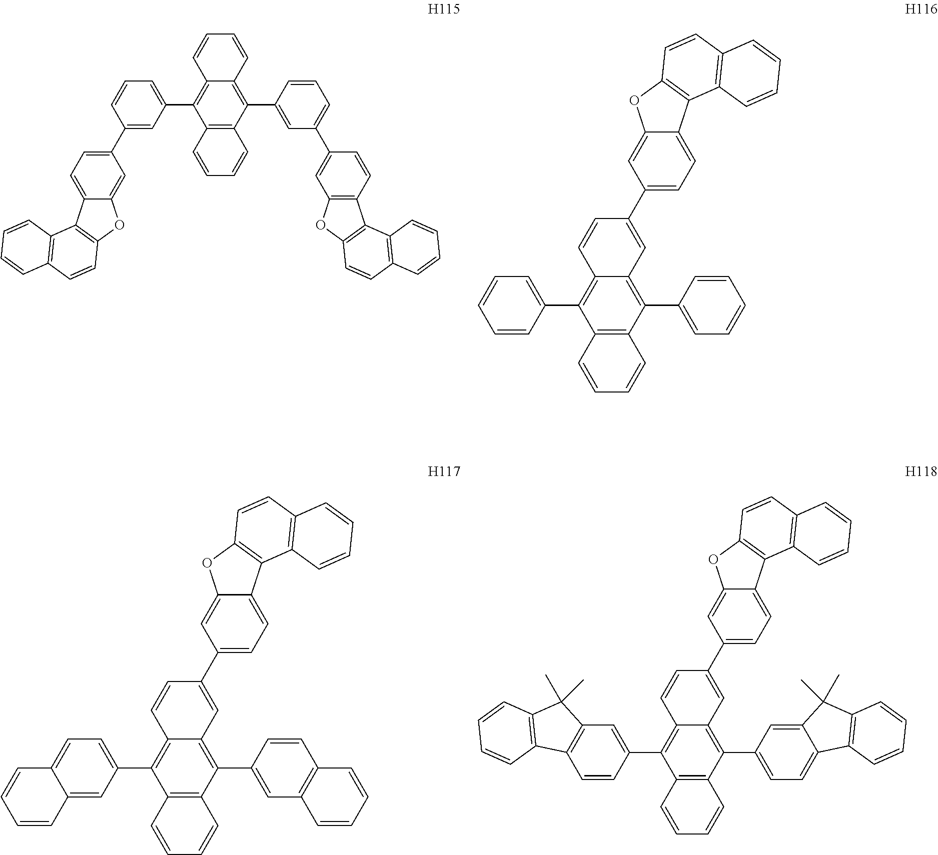 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

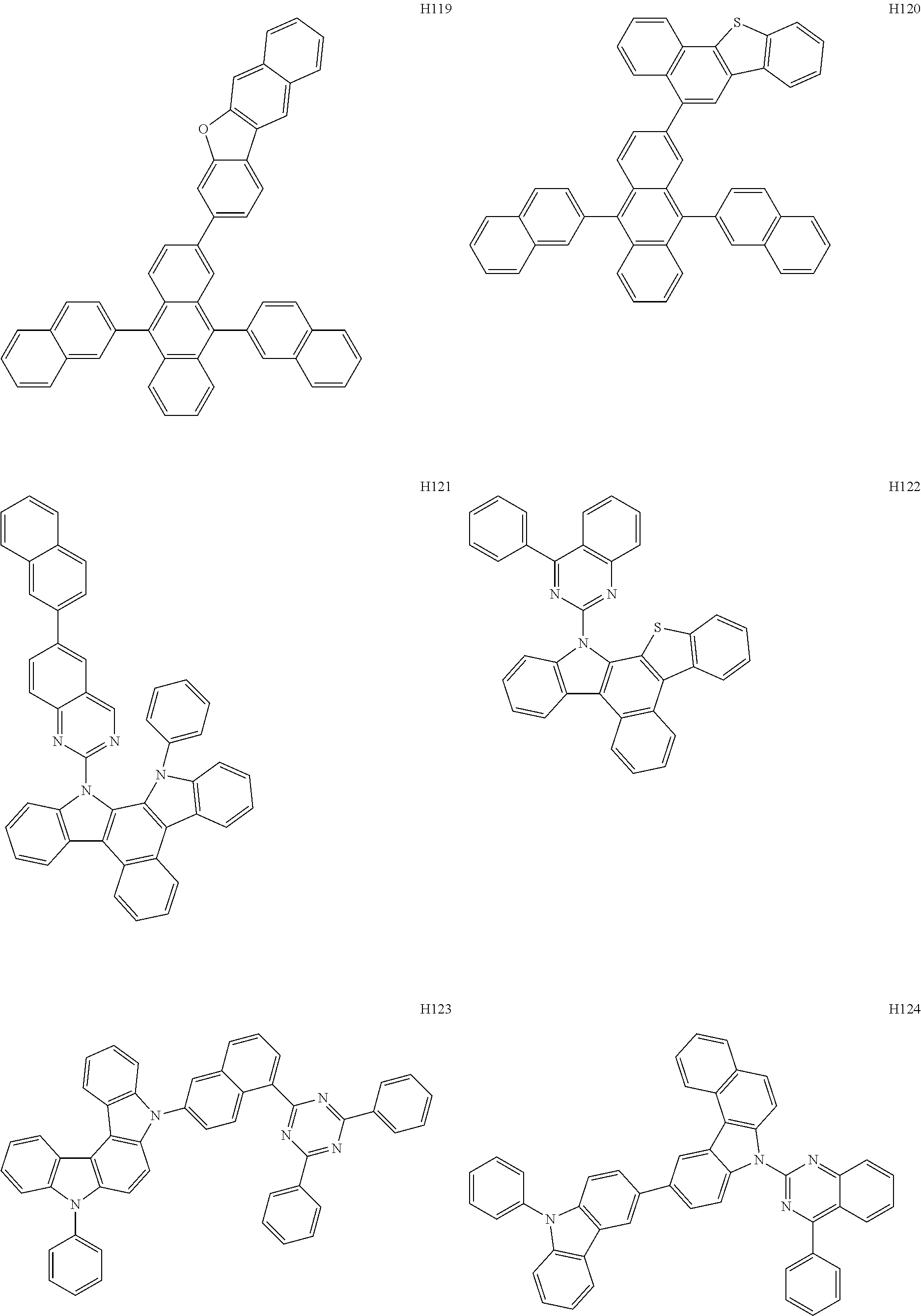

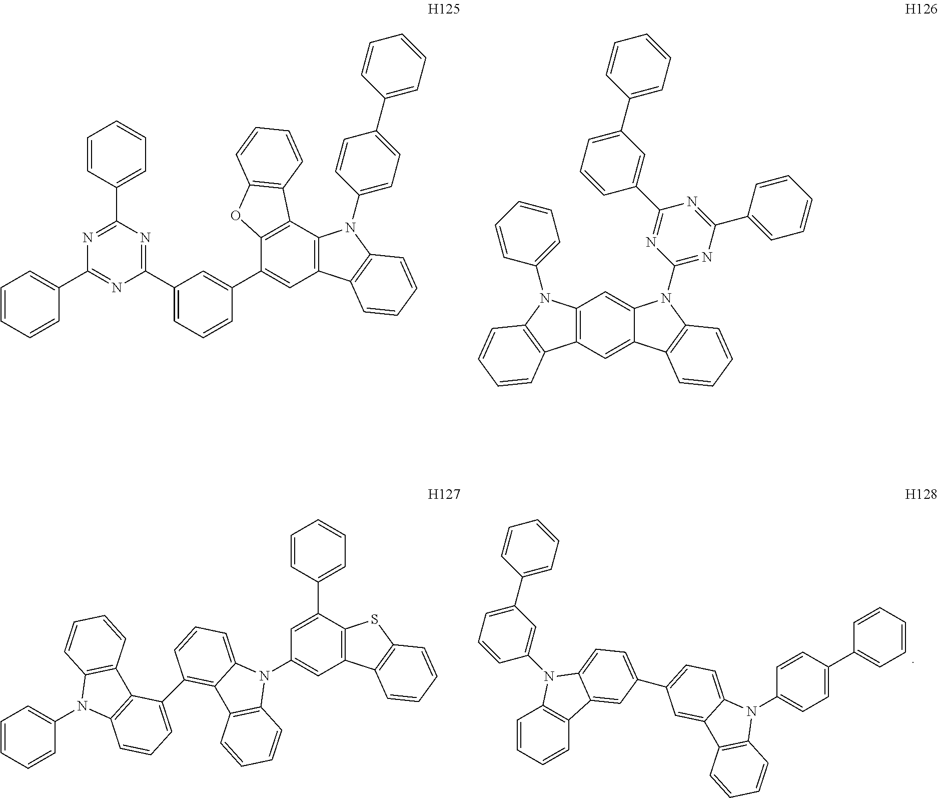 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

In one or more embodiments, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, in one or more embodiments, the phosphorescent dopant may include an organometallic compound represented by Formula 401:

M(L₄₀₁)_{xc1}(L₄₀₂)_{xc2} Formula 401

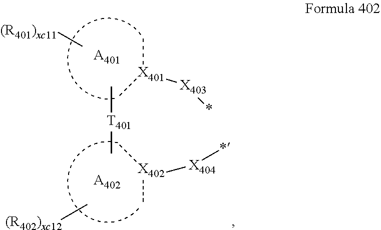

wherein, in Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is two or more, two or more of L₄₀₁(s) may be identical to or different from each other,
L₄₀₂ may be an organic ligand, and xc2 may be 0, 1, 2, 3, or 4, and when xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be the same as described herein with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be the same as described herein with respect to Q₁,
xc11 and xc12 may each independently be an integer from 0 to 10, and
* and *′ in Formula 402 each indicate a binding site to M in Formula 401.

For example, in some embodiments, in Formula 402, i) X₄₀₁ may be nitrogen, and X₄₀₂ may be carbon, or ii) each of X₄₀₁ and X₄₀₂ may be nitrogen.

In one or more embodiments, when xc1 in Formula 401 is 2 or more, two ring A₄₀₁ (s) among two or more of L₄₀₁(s) may optionally be bonded to each other via T₄₀₂, which is a linking group, and/or two ring A₄₀₂(s) among two or more of L₄₀₁(s) may optionally be bonded to each other via T₄₀₃, which is a linking group (see Compounds PD1 to PD4 and PD7). T₄₀₂ and T₄₀₃ may each be the same as described herein with respect to T₄₀₁.

L₄₀₂ in Formula 401 may be an organic ligand. For example, L₄₀₂ may include a halogen, a diketone group (for example, an acetylacetonate group), a carboxylic acid group (for example, a picolinate group), —C(═O), an isonitrile group, —CN group, a phosphorus-containing group (for example, a phosphine group, a phosphite group, etc.), or any combination thereof.

In one or more embodiments, the phosphorescent dopant may include, for example, one selected from among compounds PD1 to PD39, or any combination thereof:

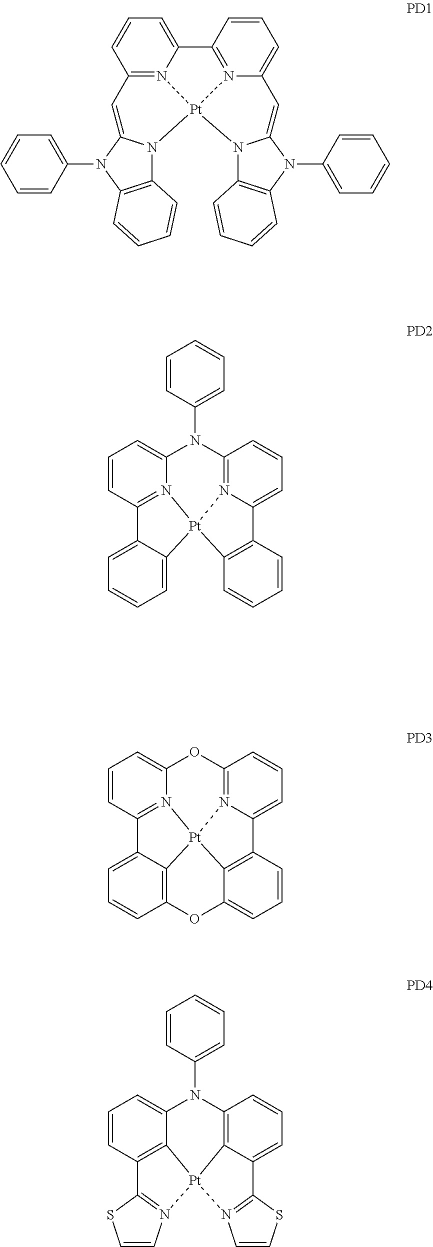

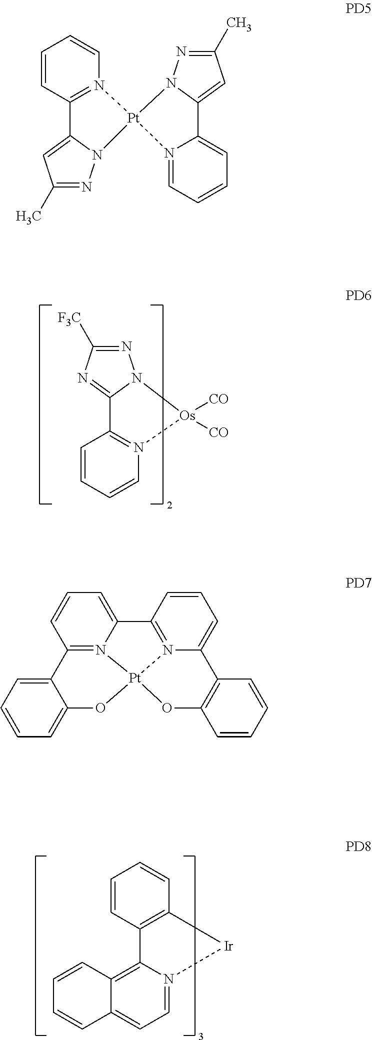

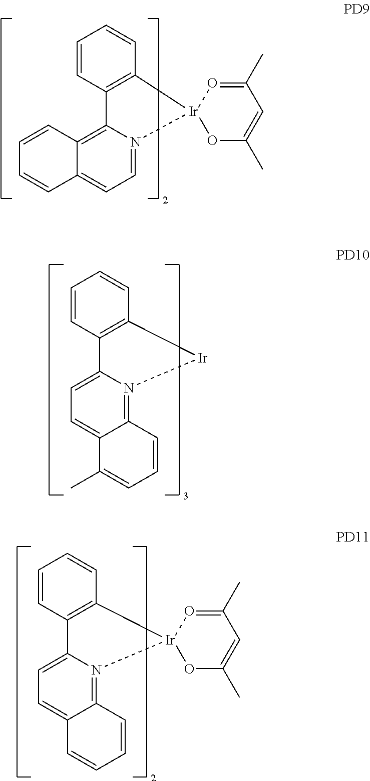

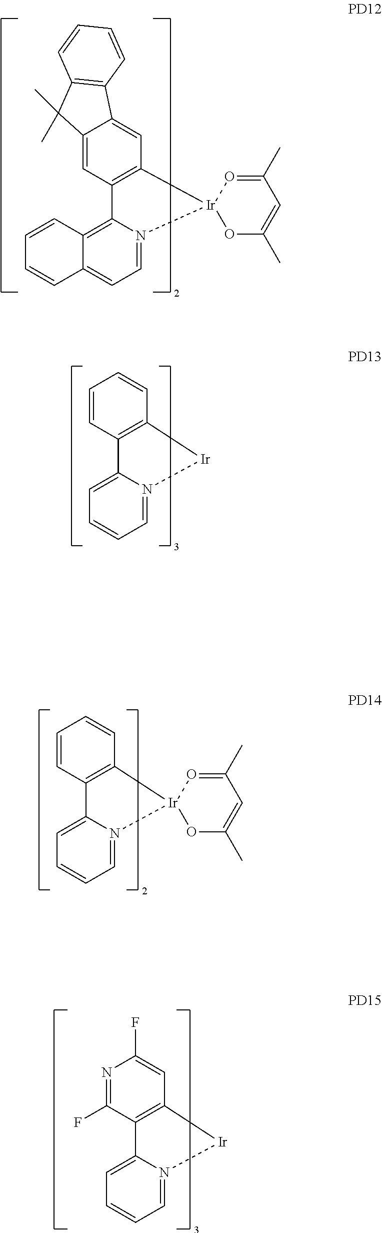

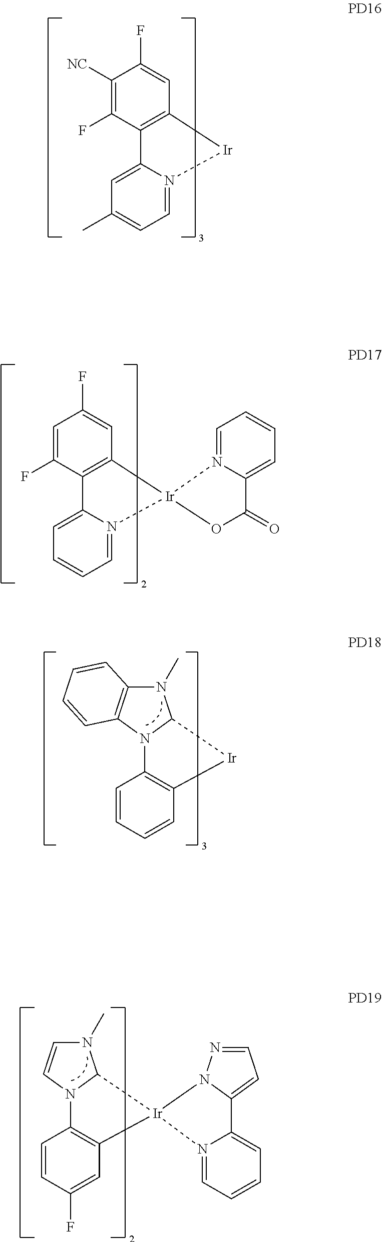

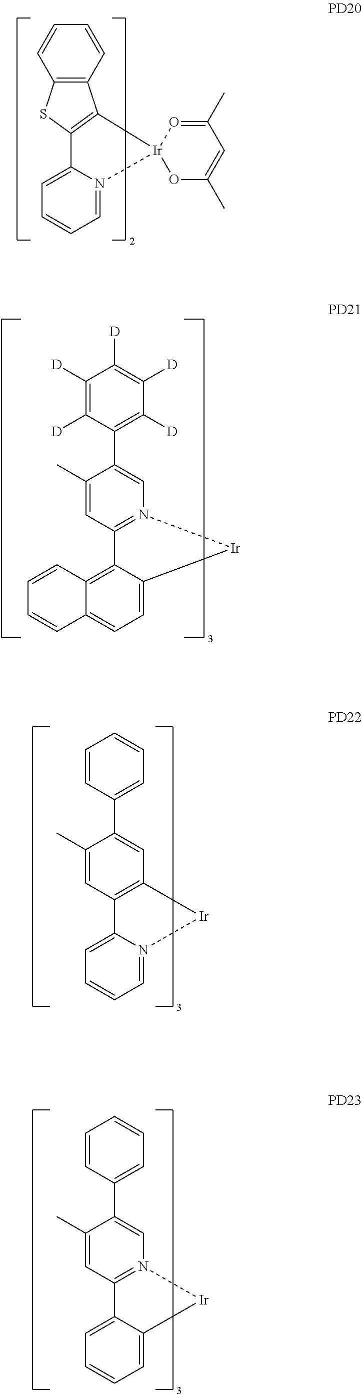

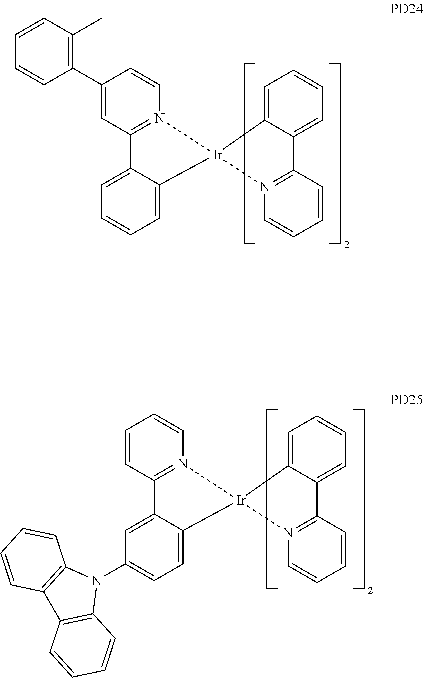

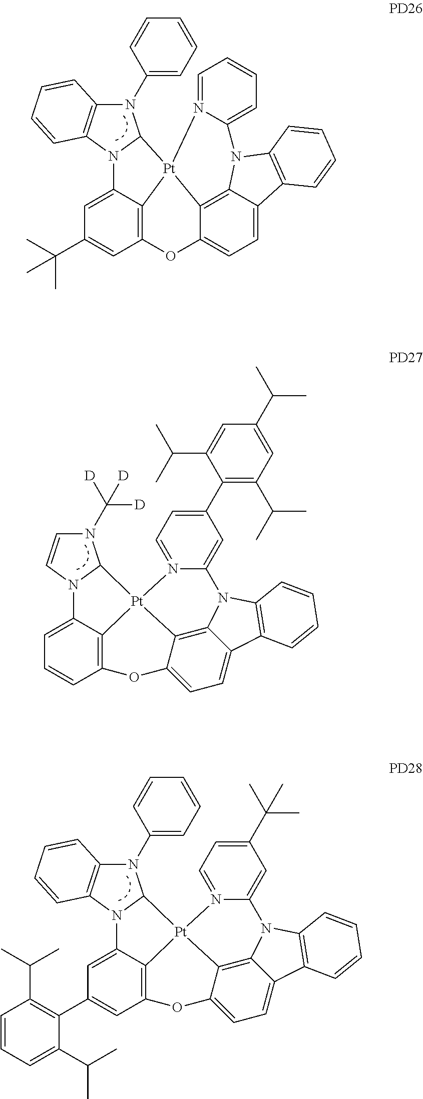

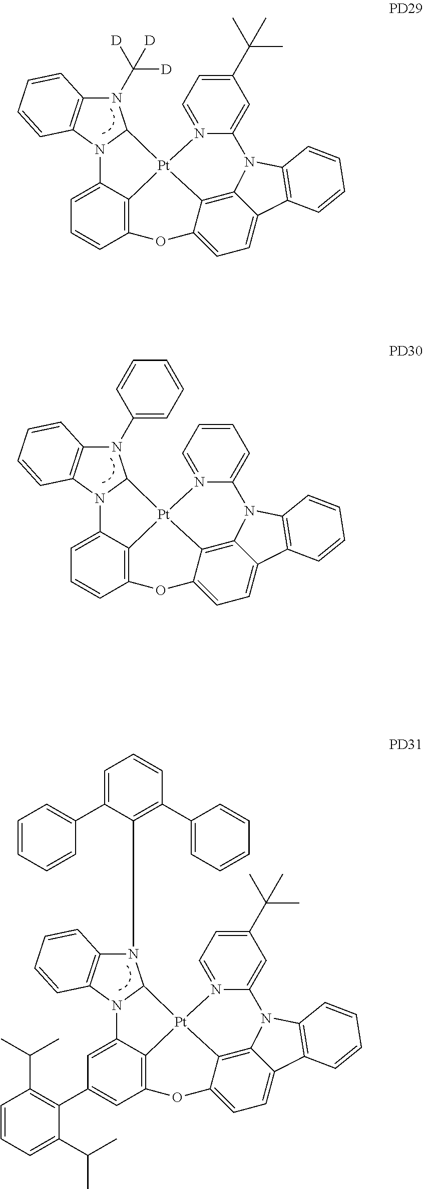

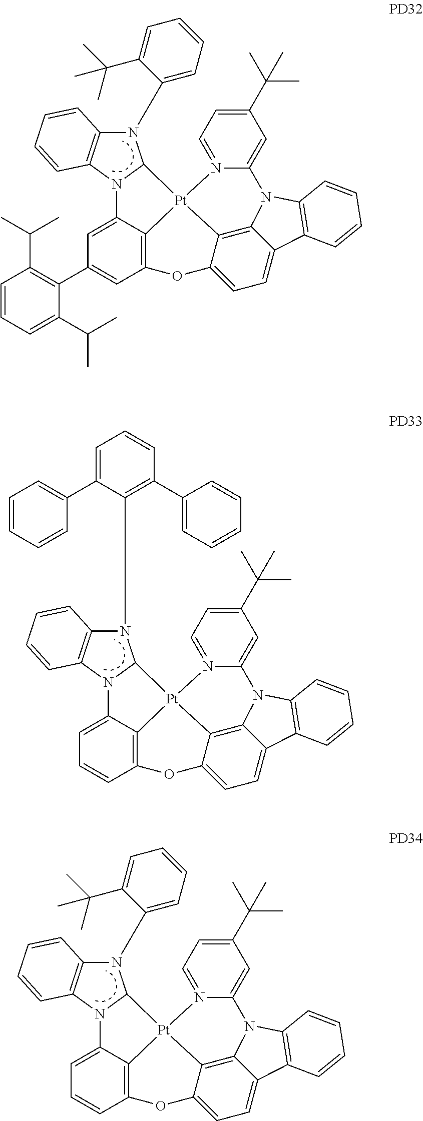

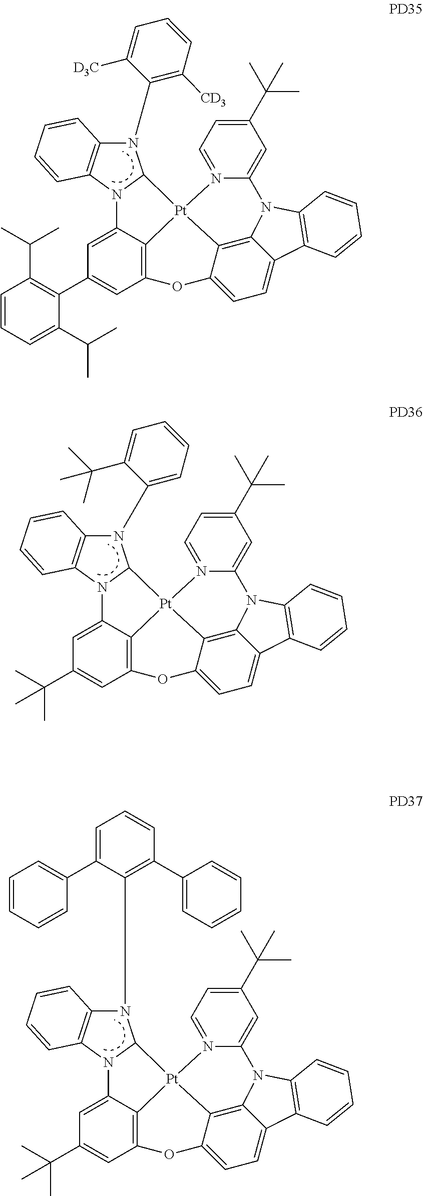

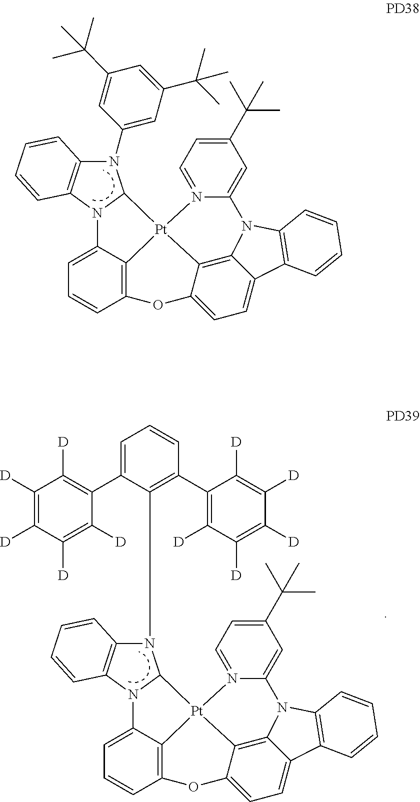

### Fluorescent Dopant

The fluorescent dopant may include an amine group-containing compound, a styryl group-containing compound, or any combination thereof.

For example, in one or more embodiments, the fluorescent dopant may include a compound represented by Formula 501:

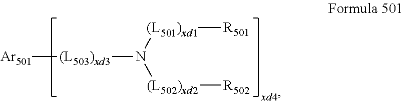

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, in some embodiments, Ar₅₀₁ in Formula 501 may be a condensed cyclic group (for example, an anthracene group, a chrysene group, or a pyrene group) in which three or more monocyclic groups are condensed together.

In one or more embodiments, xd4 in Formula 501 may be 2.

In one or more embodiments, the fluorescent dopant may include: at least one selected from among Compounds FD1 to FD37; 4,4′-bis(2,2-diphenylvinyl)-1,1′-biphenyl (DPVBi); 4,4′-bis[4-(N,N-diphenylamino)styryl]biphenyl (DPAVBi); or any combination thereof:

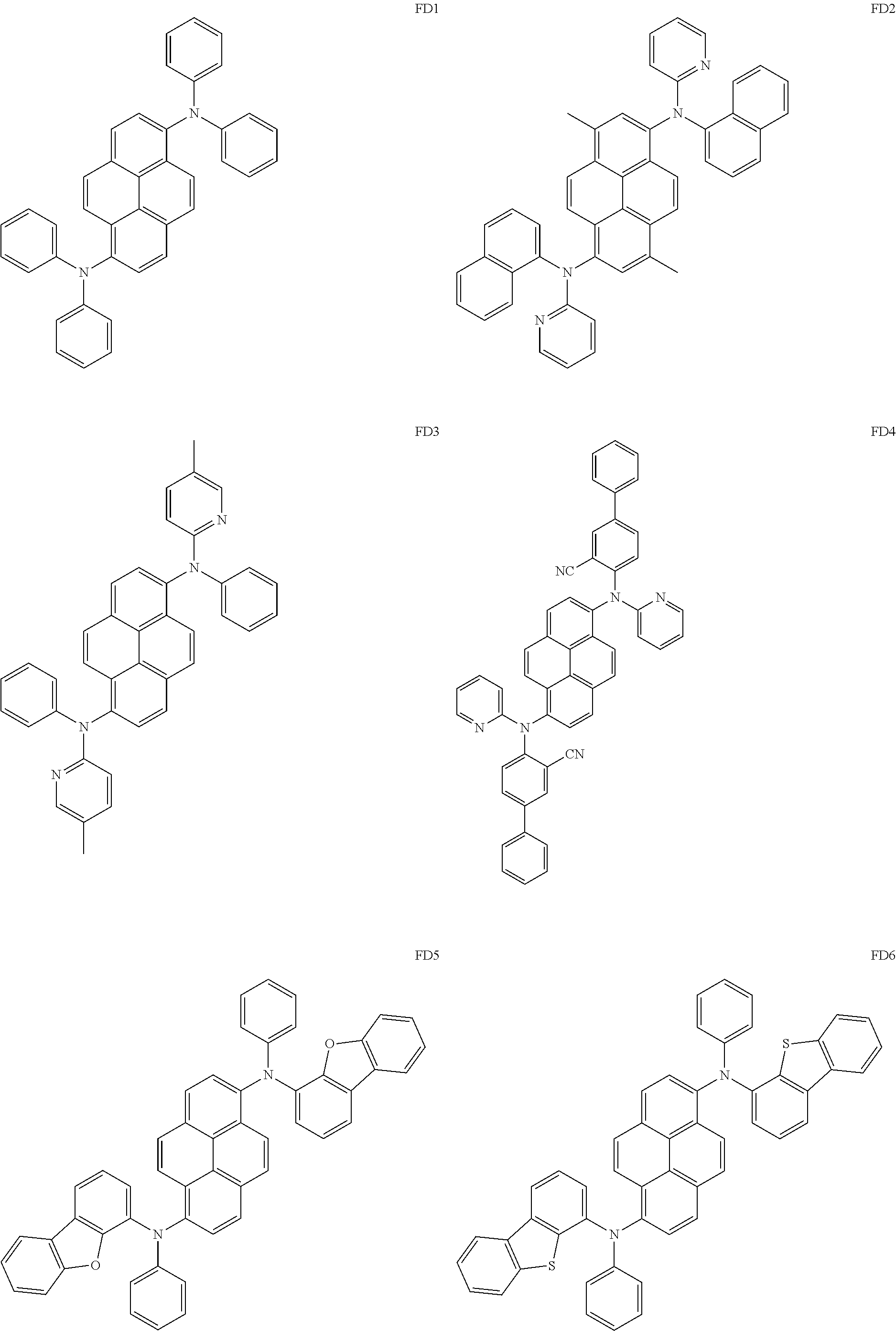

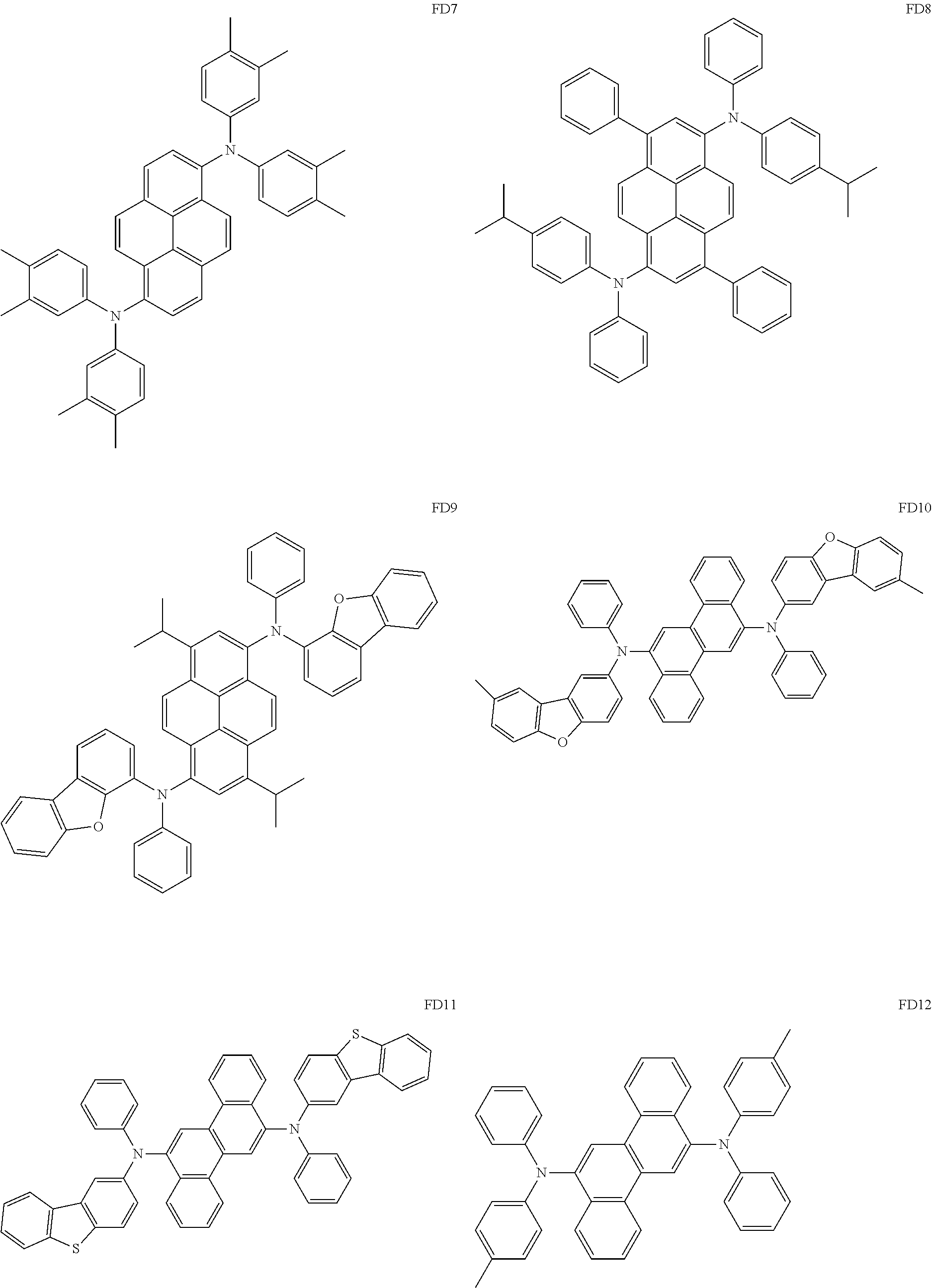

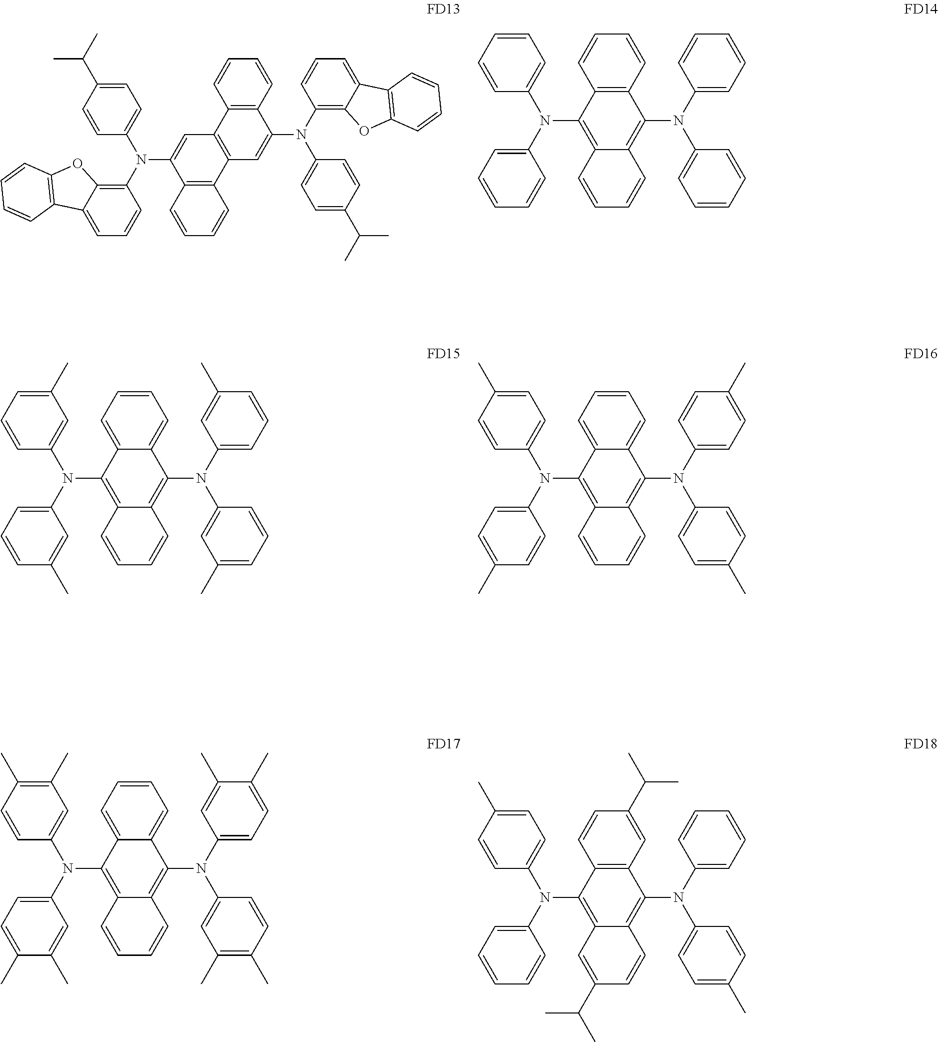

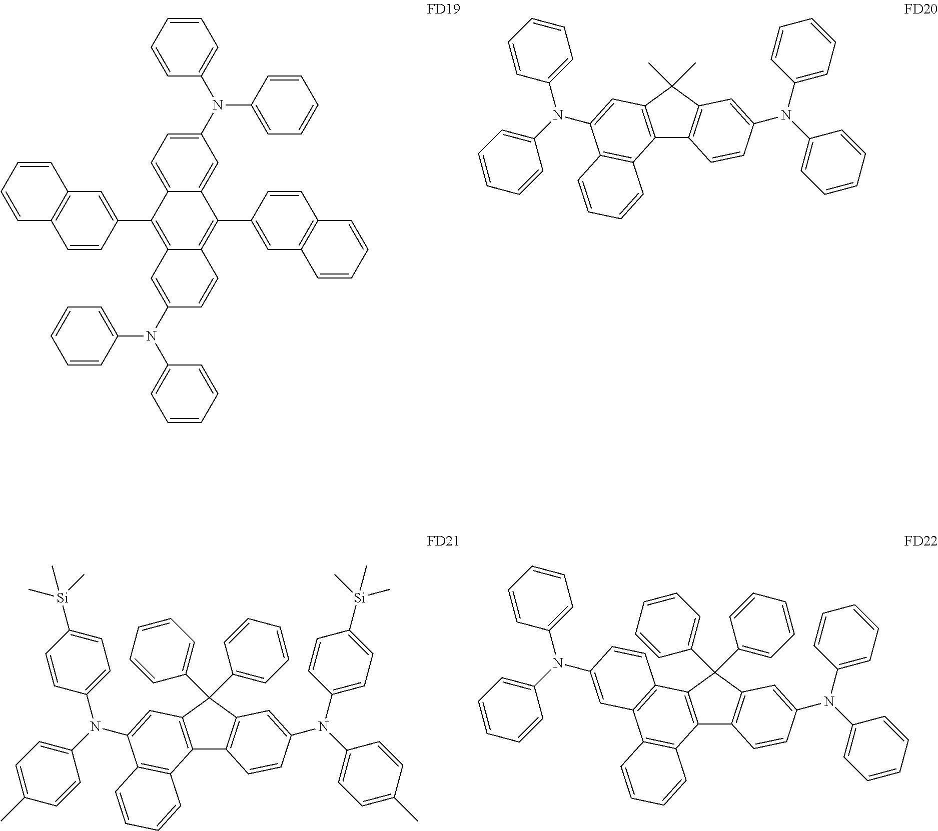

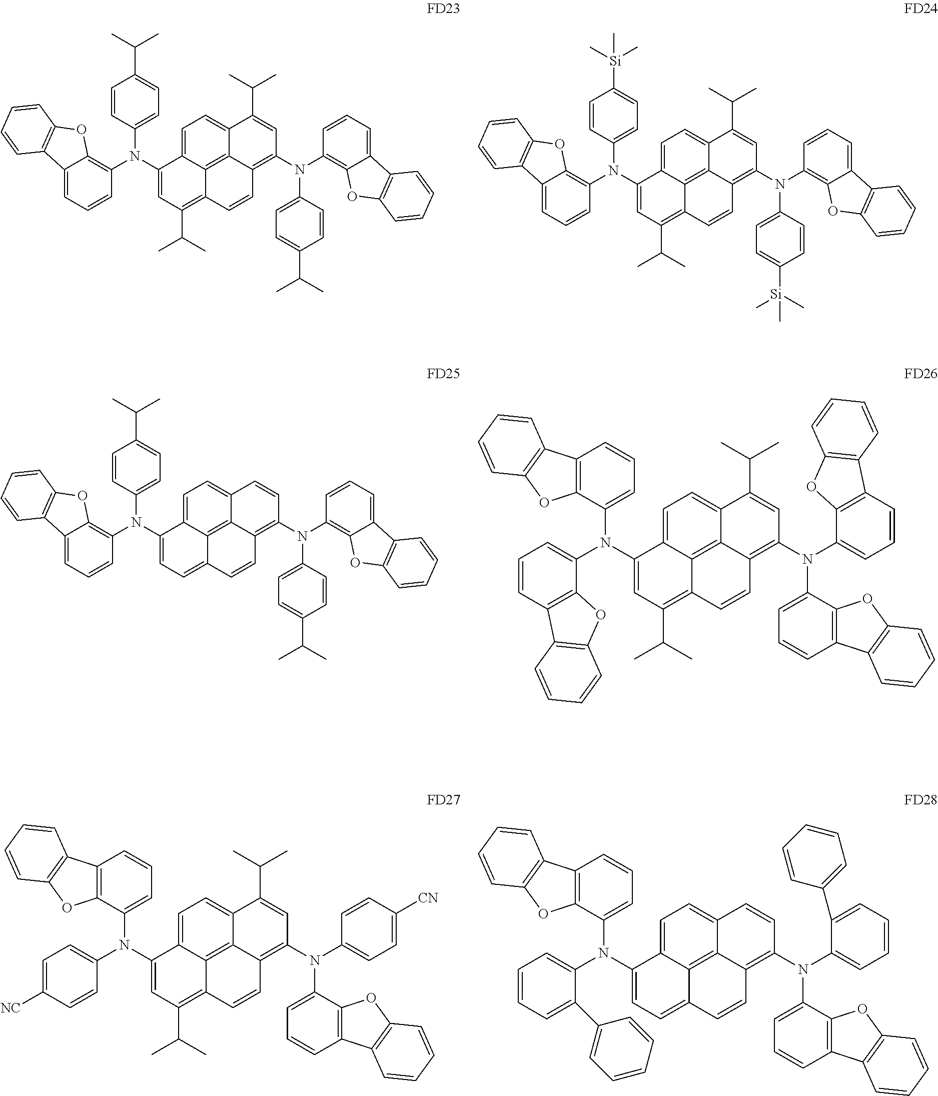

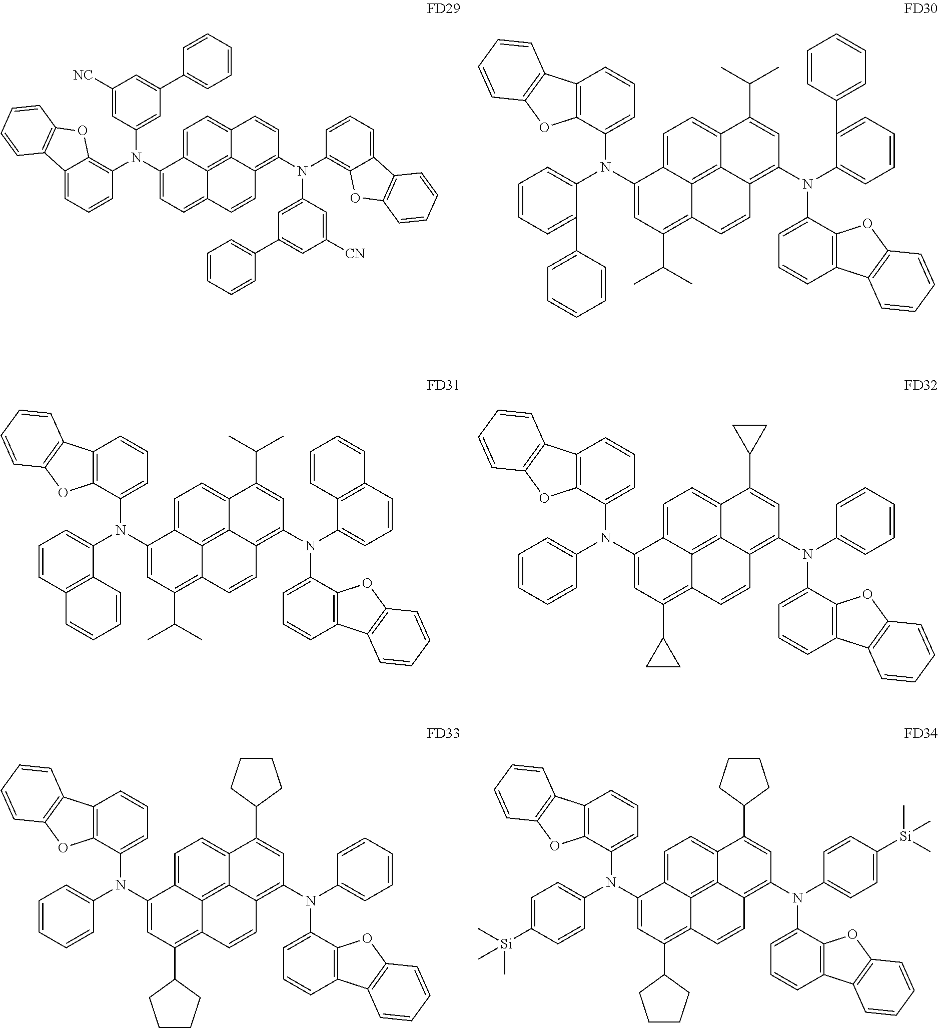

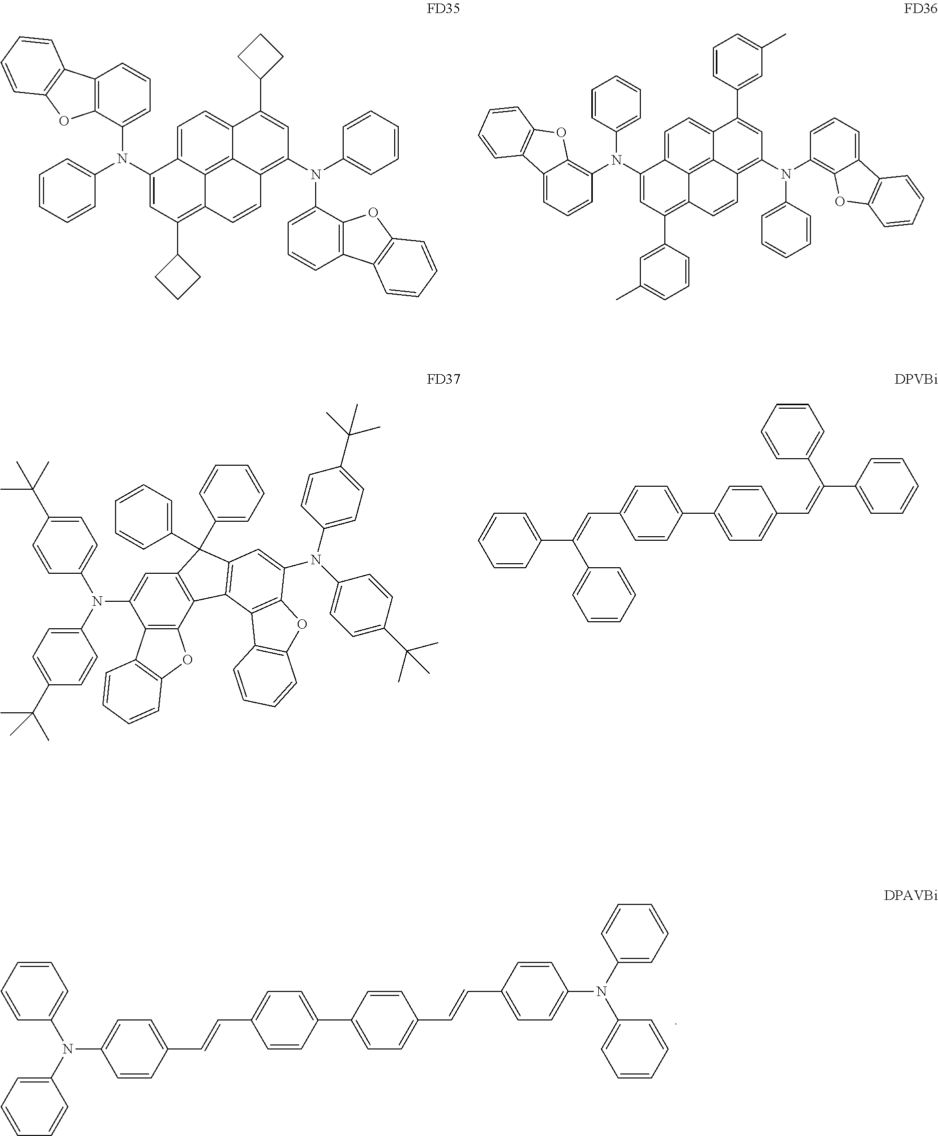

### Delayed Fluorescence Material

In one or more embodiments, the emission layer 130 may include a delayed fluorescence material.

In the present disclosure, the delayed fluorescence material may be selected from compounds capable of emitting delayed fluorescent light based on a delayed fluorescence emission mechanism.

The delayed fluorescence material included in the emission layer 130 may act as a host or a dopant, depending on the type or kind of other materials included in the emission layer 130.

In one or more embodiments, a difference between a triplet energy level (eV) of the delayed fluorescence material and a singlet energy level (eV) of the delayed fluorescence material may be greater than or equal to 0 eV and less than or equal to 0.5 eV. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively occur, and thus, the light-emitting device 10 may have improved luminescence efficiency.

For example, in one or more embodiments, the delayed fluorescence material may include i) a material including at least one electron donor (for example, a π electron-rich C₃-C₆₀ cyclic group, such as a carbazole group) and at least one electron acceptor (for example, a sulfoxide group, a cyano group, or a π electron-deficient nitrogen-containing C₁-C₆₀ cyclic group), and/or ii) a material including a C₈-C₆₀ polycyclic group in which two or more cyclic groups are condensed while sharing boron (B).

Non-limiting examples of the delayed fluorescence material may include at least one selected from among Compounds DF1 to DF14:

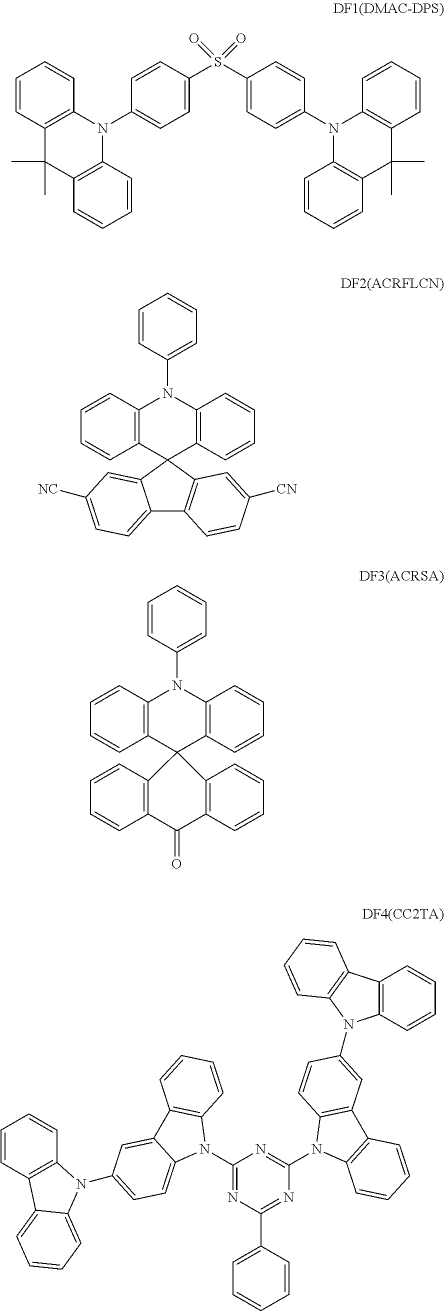

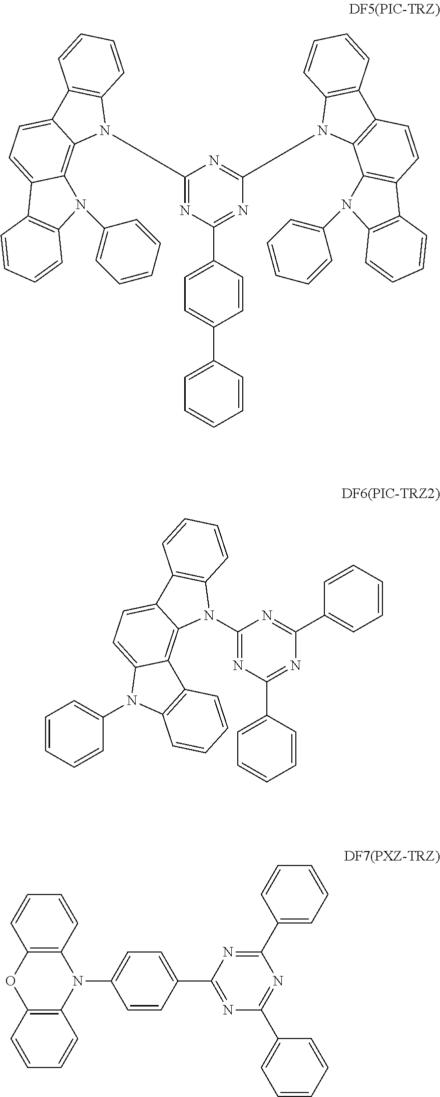 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

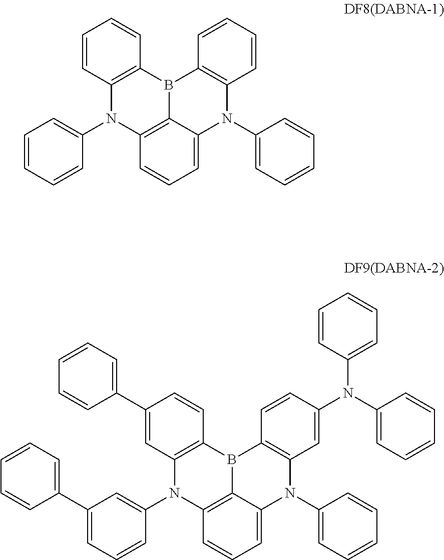 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

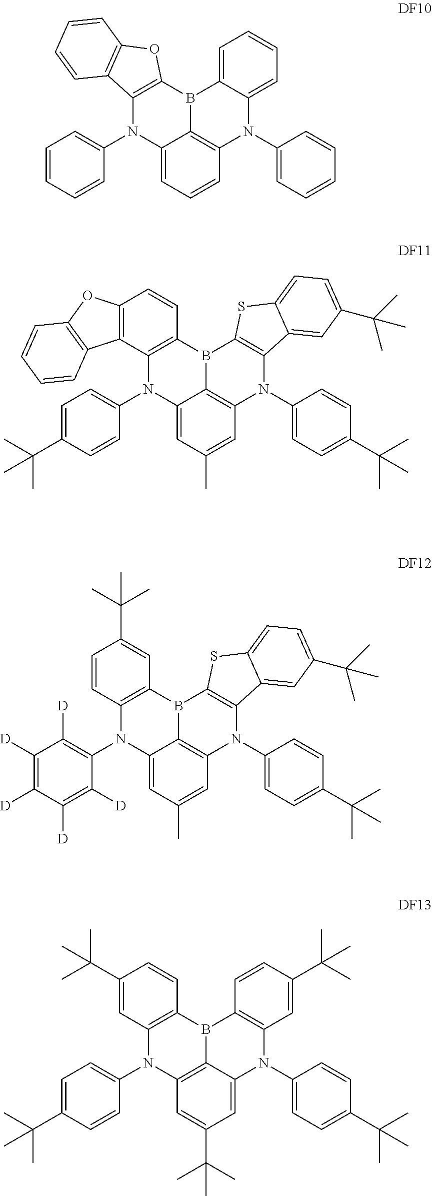

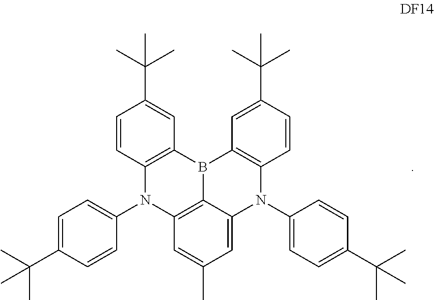 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Quantum Dot

In one or more embodiments, the emission layer 130 may include a quantum dot.

The term “quantum dot” as utilized herein refers to a crystal of a semiconductor compound, and may include any material capable of emitting light of one or more suitable emission wavelengths according to the size of the crystal.

A diameter of the quantum dot may be, for example, in a range of about 1 nm to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or any process similar thereto.

The wet chemical process is a method including mixing a precursor material of a quantum dot with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles may be controlled or selected through a process which costs lower, and is easier than vapor deposition methods, such as metal organic chemical vapor deposition (MOCVD) or molecular beam epitaxy (MBE),

The quantum dot may include Group II-VI semiconductor compounds, Group III-V semiconductor compounds, Group III-VI semiconductor compounds, Group I-III-VI semiconductor compounds, Group IV-VI semiconductor compounds, Group IV elements or compounds, or any combination thereof.

Non-limiting examples of the Group II-VI semiconductor compound may include (e.g., be) a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Non-limiting examples of the Group III-V semiconductor compound may include (e.g., be): a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. In some embodiments, the Group III-V semiconductor compound may further include a Group II element. Non-limiting examples of the Group III-V semiconductor compound further including a Group II element may include (e.g., be) InZnP, InGaZnP, InAlZnP, etc.

Non-limiting examples of the Group III-VI semiconductor compound may include (e.g., be): a binary compound, such as GaS, GaSe, Ga₂Se₃, GaTe, InS, InSe, In₂S₃, In₂Se₃, and/or InTe; a ternary compound, such as InGaS₃, and/or InGaSe₃s; or any combination thereof.

Non-limiting examples of the Group I-III-VI semiconductor compound may include (e.g., be) a ternary compound such as AgInS, AgInS₂, CuInS, CuInS₂, CuGaO₂, AgGaO₂, and/or AgAlO₂, a quaternary compound such as AgInGaS and/or AgInGaS₂, or any combination thereof.

Non-limiting examples of the Group IV-VI semiconductor compound may include (e.g., be): a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

Non-limiting examples of the Group IV element or compound may include (e.g., be): a single element, such as Si, Ge, and/or the like; a binary compound, such as SiC, SiGe, and/or the like; or any combination thereof.

Each element included in a multi-element compound such as the binary compound, the ternary compound, and the quaternary compound may be present at a substantially uniform concentration or non-substantially uniform concentration in a particle.

In some embodiments, the quantum dot may have a single structure in which the concentration of each element in the quantum dot is substantially uniform, or a core-shell dual structure. For example, a material included in the core and a material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases toward the center of the core.

Examples of the shell of the quantum dot may be an oxide of metal, metalloid, or non-metal, a semiconductor compound, and any combination thereof. Non-limiting examples of the oxide of metal, metalloid, or non-metal may include (e.g., be) a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Examples of the semiconductor compound may include (e.g., be), as described herein, a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission spectrum of the quantum dot may be about 45 nm or less, for example, about 40 nm or less, for example, about 30 nm or less, and within these ranges, color purity or color reproducibility of the quantum dot may be increased. In some embodiments, because the light emitted through the quantum dot is emitted in all directions, the wide viewing angle may be improved.

In one or more embodiments, the quantum dot may be in the form of a spherical particle, a pyramidal particle, a multi-arm particle, a cubic nanoparticle, a nanotube particle, a nanowire particle, a nanofiber particle, or a nanoplate particle.

Because the energy band gap of the quantum dot may be adjusted by controlling the size of the quantum dot, light having one or more suitable wavelength bands may be obtained from a quantum dot emission layer. Accordingly, by utilizing quantum dots of different sizes, a light-emitting device that emits light of one or more suitable wavelengths may be implemented. In one or more embodiments, the size of the quantum dots may be selected enable the quantum dots to emit red, green and/or blue light. In some embodiments, the quantum dots with suitable sizes may be configured to emit white light by combination of light of one or more suitable colors.

### Photoactive Layer 135

The photoactive layer 135 may generate excitons by absorbing incident light. The excitons may generate holes and electrons. The holes generated by the photoactive layer 135 may move to the first electrode 110 through the hole transport region 120. The electrons generated by the photoactive layer 135 may move to the second electrode 150 through the electron transport region 140. As such, the photoactive layer 135 may be to absorb light to generate electric signal. Thus, the optoelectronic device 30 including the photoactive layer 135 may serve as an optical sensor. In one or more embodiments, the photoactive layer 135 may include a donor which may be referred to as a p-type or kind compound and an acceptor which may be referred to as an n-type or kind compound. The donor may supply electrons, and the acceptor may receive the electrons.

In one or more embodiments, the photoactive layer 135 may not include (e.g., may exclude) a (e.g., any) subnaphthalocyanine-based compound and a (e.g., any) fullerene-based compound. For example, the photoactive layer 135 may not include (e.g., may exclude) SubNC, Fullerene 60, and Fullerene 70:

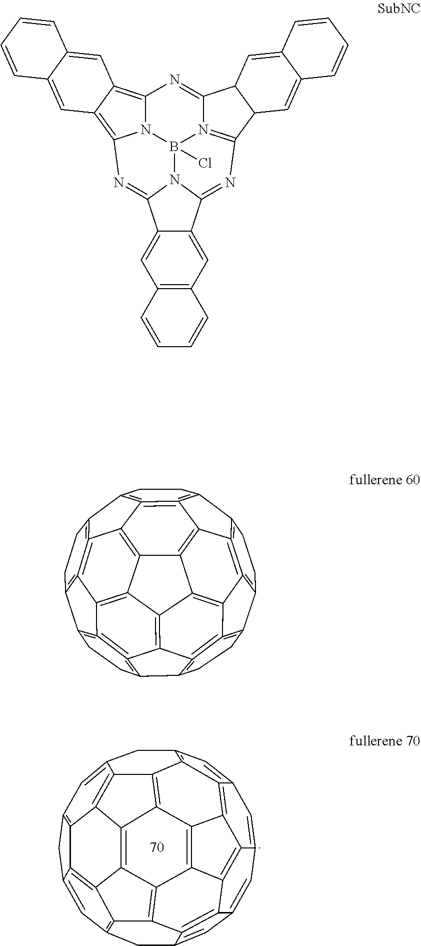

For example, in one or more embodiments, the donor may not be SubNC, and the acceptor may not be Fullerene 60 and Fullerene 70.

As the photoactive layer 135 may have a single-layer structure or a multi-layer structure, detailed description of the optoelectronic device 30 including the photoactive layer 135 is to be provided later.

### Electron Transport Region 140

The electron transport region 140 may have i) a single-layer structure including (e.g., consisting of) a single layer including a single material, ii) a single-layer structure including (e.g., consisting of) a single layer including multiple materials that are different from each other, or iii) a multi-layer structure including (e.g., consisting of) multiple layers including multiple different materials that are different from each other.

The electron transport region 140 may include a buffer layer, a hole-blocking layer, an electron control layer, an electron transport layer, an electron injection layer, or any combination thereof.

In one or more embodiments, the electron transport region 140 may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein, for each structure, constituting layers are sequentially stacked from the emission layer 130 in the stated order.

In one or more embodiments, the electron transport region 140 (for example, the buffer layer, the hole-blocking layer, the electron control layer, or the electron transport layer in the electron transport region) may include a metal-free compound including at least one π electron-deficient nitrogen-containing C₁-C₆₀ cyclic group.

For example, in some embodiments, the electron transport region 140 may include a compound represented by Formula 601:

[Ar₆₀₁]ₓₑ₁₁-[(L₆₀₁)ₓₑ₁-R₆₀₁]ₓₑ₂₁, Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described herein with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

For example, when xe11 in Formula 601 is 2 or more, two or more of Ar₆₀₁(s) may be linked to each other via a single bond.

In some embodiments, Ar₆₀₁ in Formula 601 may be an anthracene group unsubstituted or substituted with at least one R₁₀ₐ.

In one or more embodiments, the electron transport region 140 may include a compound represented by Formula 601-1:

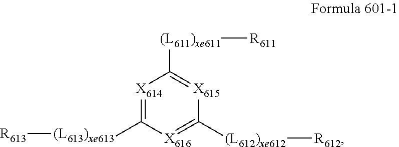

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each be the same as described herein with respect to L₆₀₁,
xe611 to xe613 may each be the same as described herein with respect to xe1,
R₆₁₁ to R₆₁₃ may each be the same as described herein with respect to R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in some embodiments, xe1 and xe611 to xe613 in Formulae 601 and 601-1 may each independently be 0, 1, or 2.

In one or more embodiments, the electron transport region may include at least one selected from among Compounds ET1 to ET45, 2,9-dimethyl-4,7-diphenyl-1,10-phenanthroline (BCP), 4,7-diphenyl-1,10-phenanthroline (Bphen), tris(8-hydroxyquinolinato)aluminum (Alq3), bis(2-methyl-8-quinolinolato-N1,O8)-(1,1′-biphenyl-4-olato)aluminum (BAIq), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), or any combination thereof:

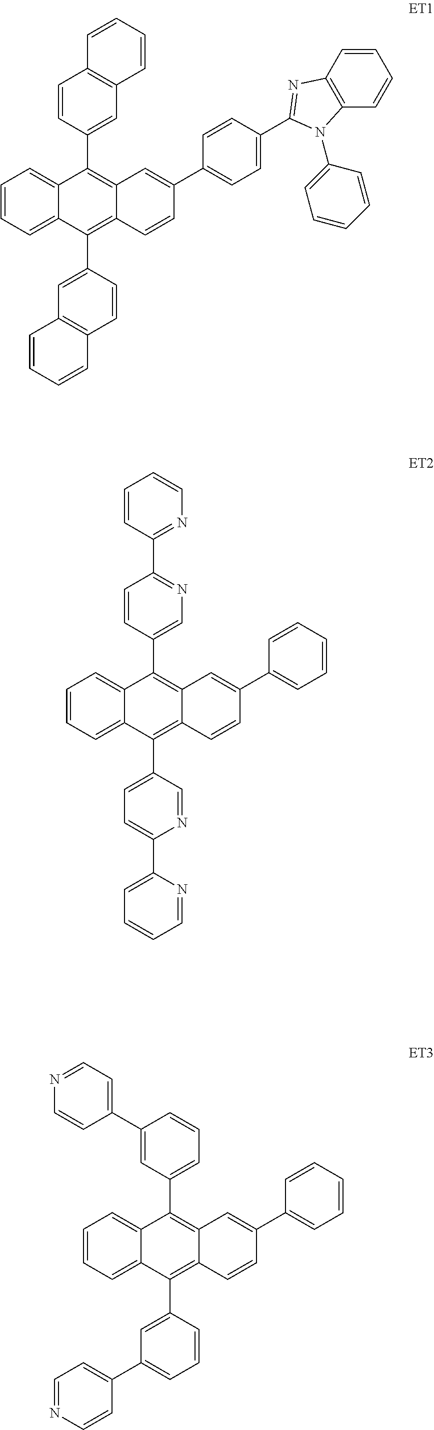 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

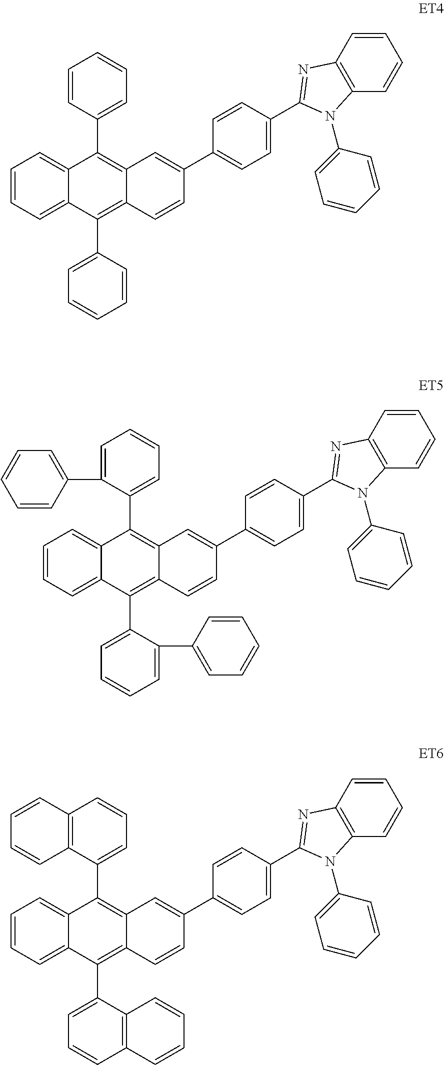 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

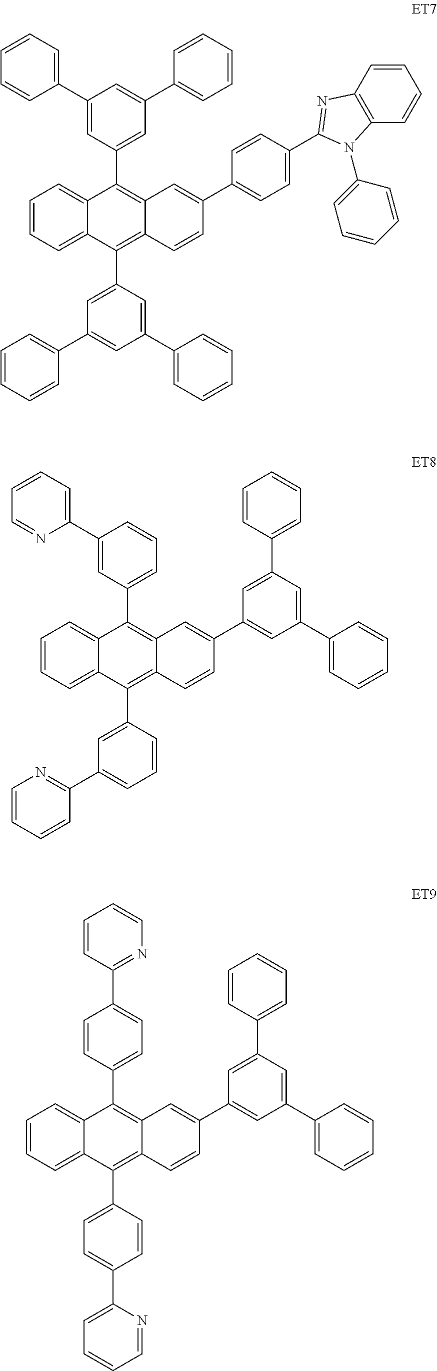 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

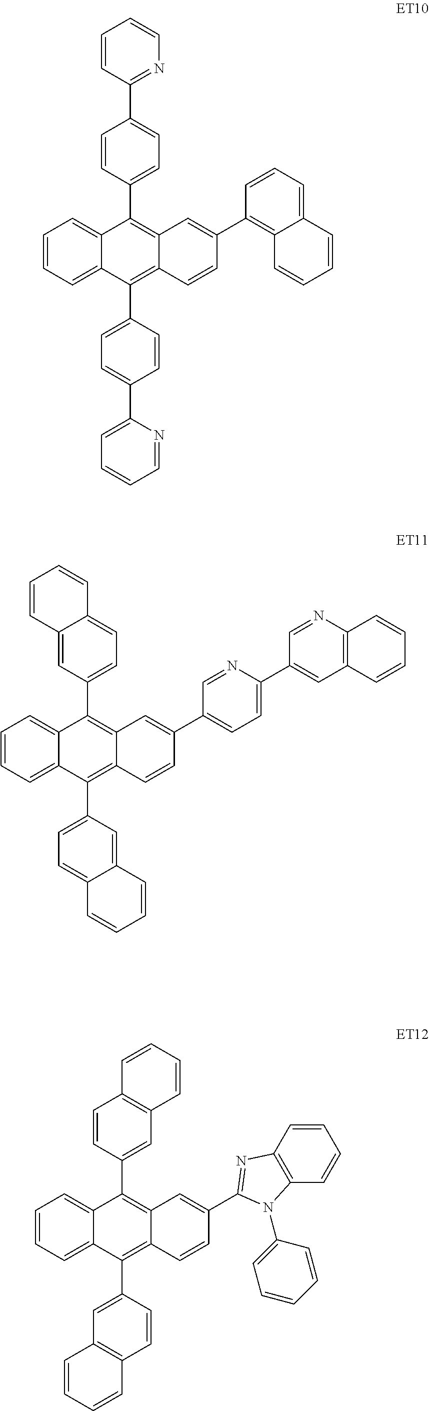 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

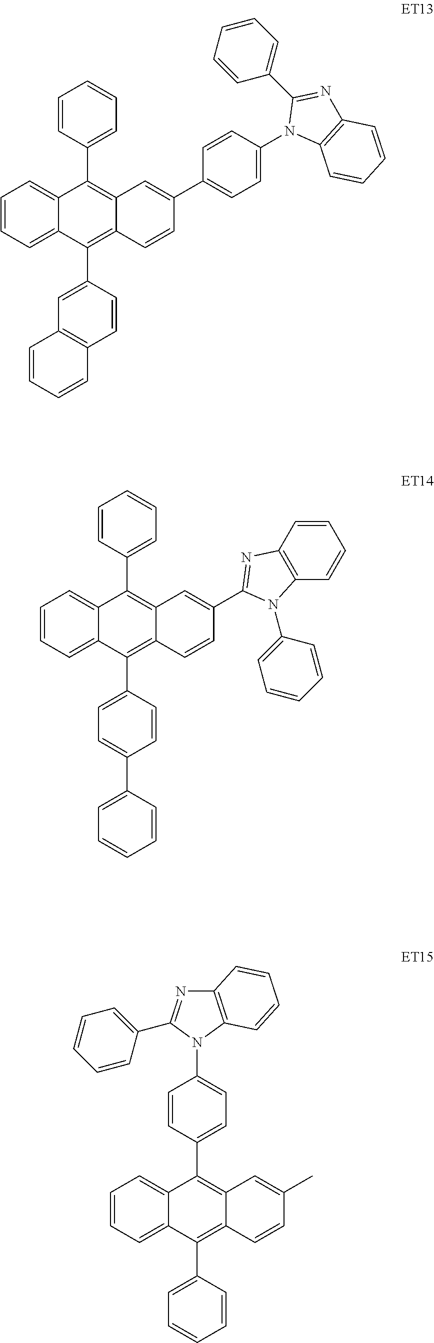 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

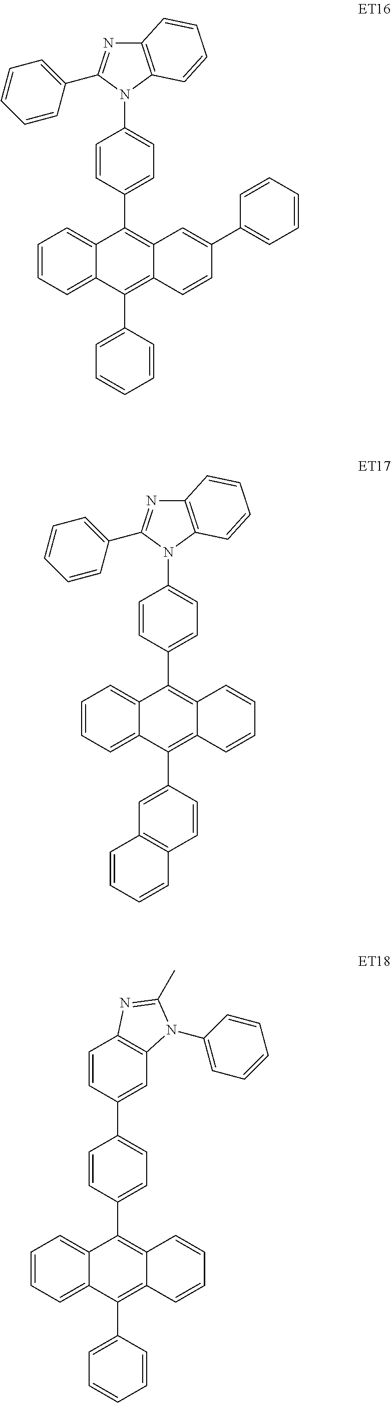 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

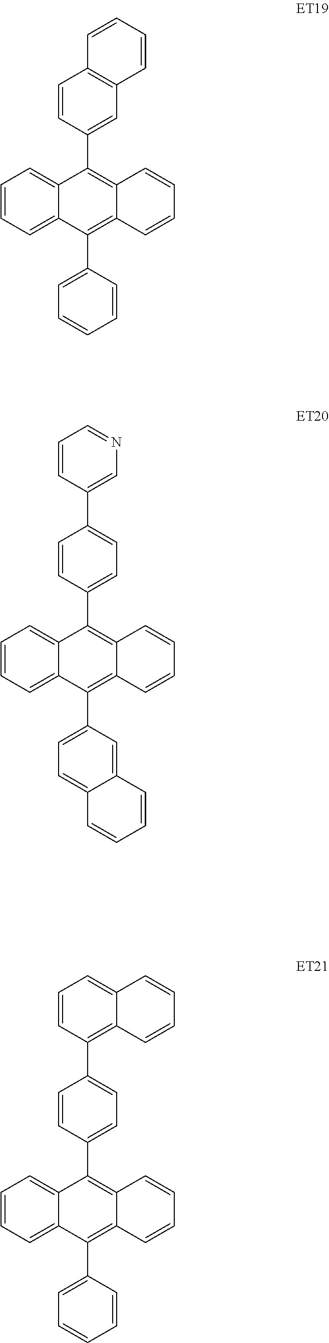

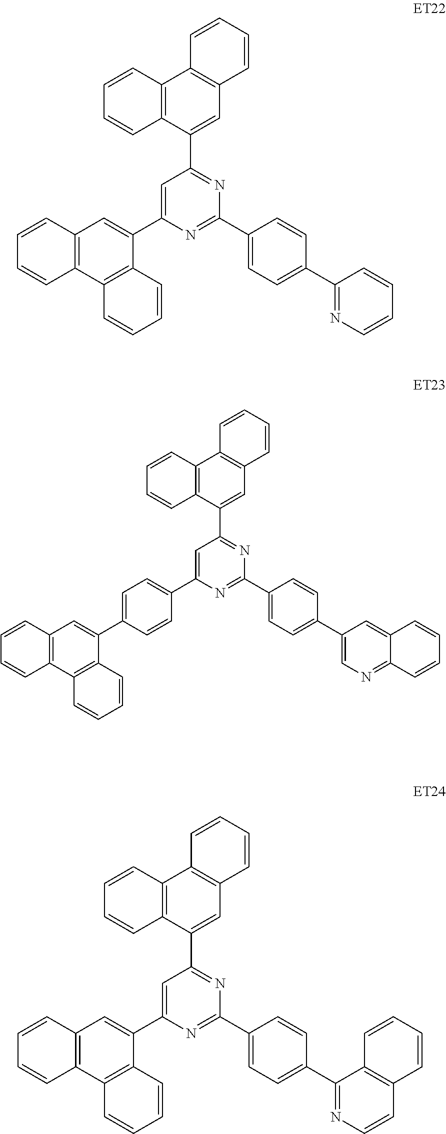 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

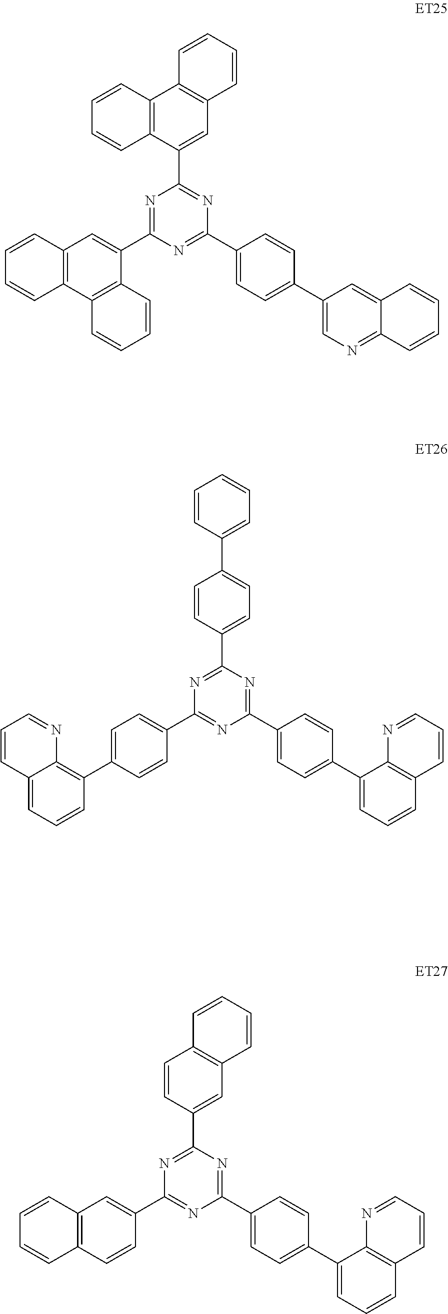 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

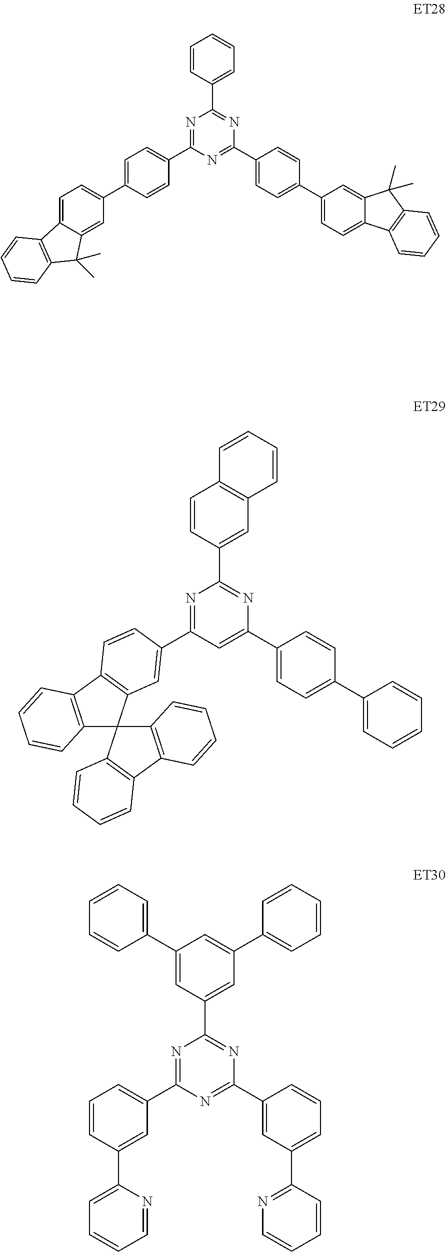 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

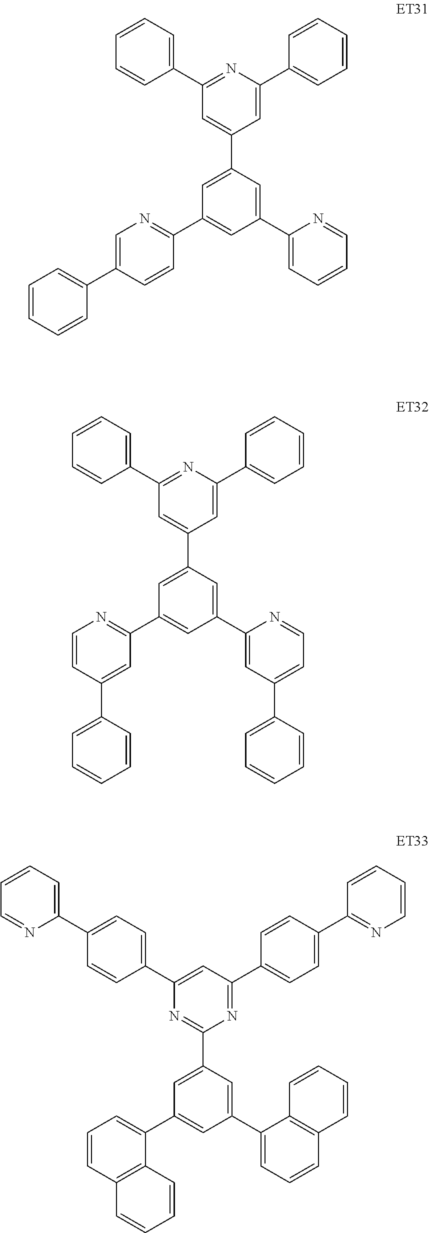 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

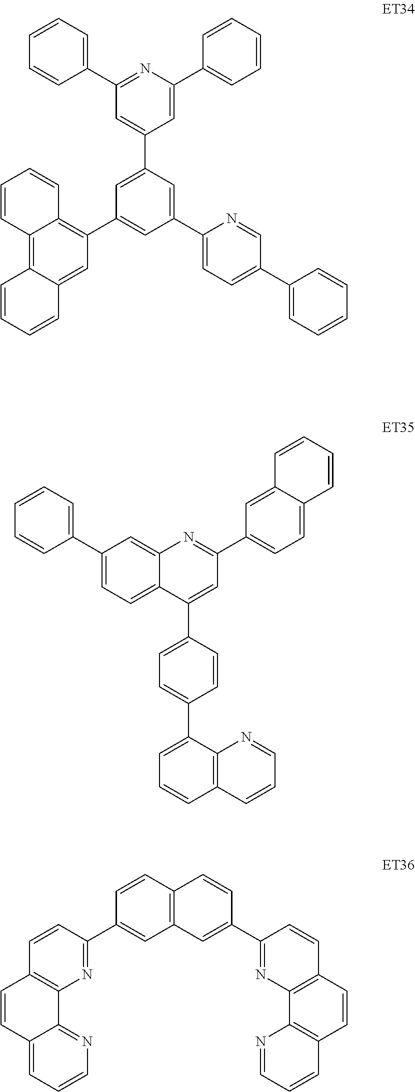 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

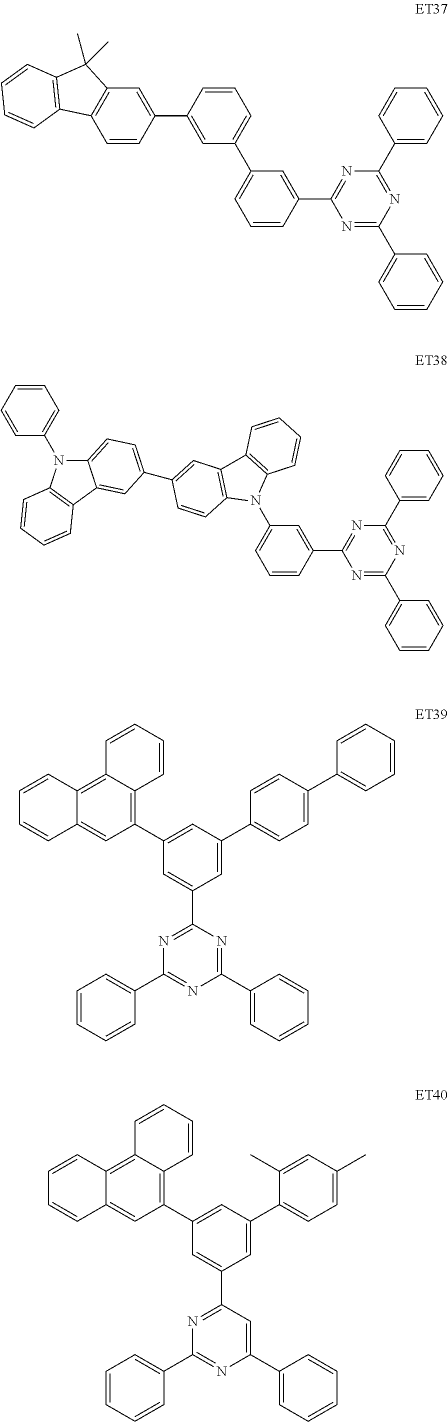 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

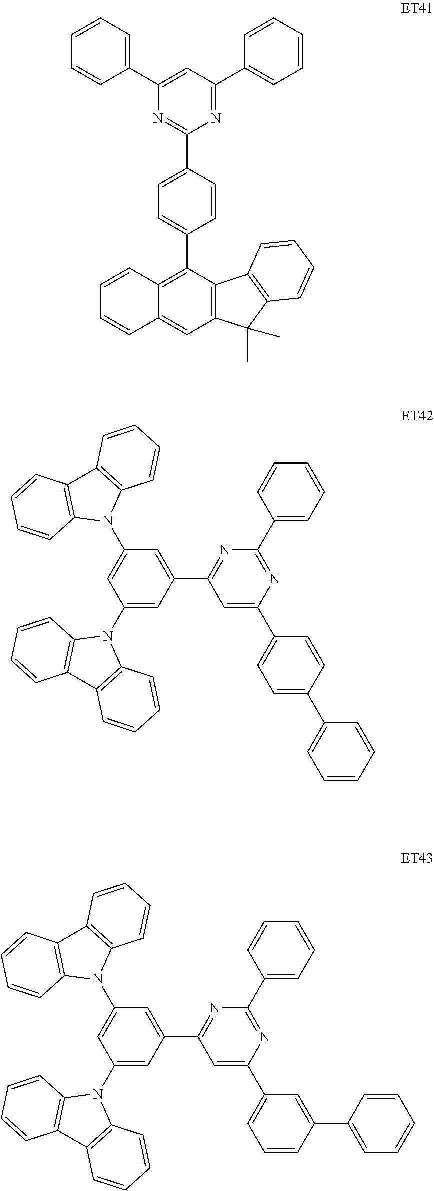 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

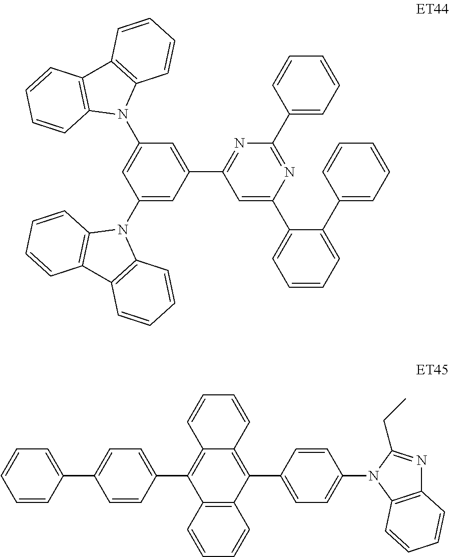 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

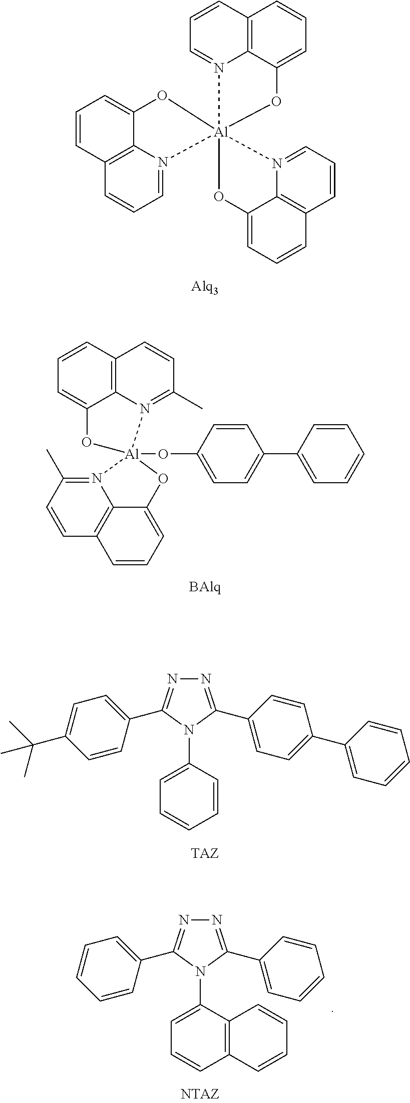

A thickness of the electron transport region 140 may be in a range of about 100 Å to about 5,000 Å, for example, about 160 Å to about 4,000 Å. When the electron transport region 140 includes a buffer layer, a hole-blocking layer, an electron control layer, an electron transport layer, or any combination thereof, a thickness of the buffer layer, the hole-blocking layer, or the electron control layer may each independently be from about 20 Å to about 1,000 Å, for example, about 30 Å to about 300 Å, and a thickness of the electron transport layer may be from about 100 Å to about 1,000 Å, for example, about 150 Å to about 500 Å. When the thicknesses of the buffer layer, the hole-blocking layer, the electron control layer, the electron transport layer, and/or the electron transport region 140 are within these ranges, satisfactory electron-transporting characteristics may be obtained without a substantial increase in driving voltage.

In one or more embodiments, the electron transport region 140 (e.g., an electron transport layer in the electron transport region) may further include, in addition to one or more of the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, in some embodiments, the metal-containing material may include a Li complex. The Li complex may include, for example, Compound ET-D1 (LiQ) and/or Compound ET-D2:

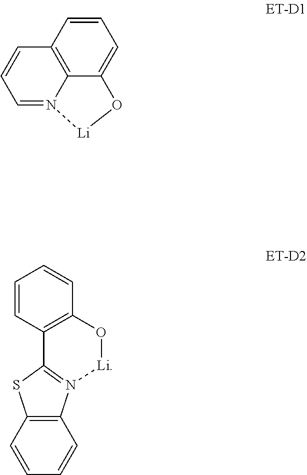

In one or more embodiments, the electron transport region 140 may include an electron injection layer that facilitates the injection of electrons from the second electrode 150. The electron injection layer may be in direct contact with the second electrode 150; however, embodiments of the present disclosure are not limited thereto.

The electron injection layer may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, or iodides), or tellurides of the alkali metal, the alkaline earth metal, and the rare earth metal, respectively, or any combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include lanthanide metal tellurides. Non-limiting examples of the lanthanide metal telluride may include (e.g., be) LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the respective metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may include (e.g., consist of): i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. For example, in some embodiments, the electron injection layer may be a KI:Yb co-deposited layer, an RbI:Yb co-deposited layer, a LiF:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be substantially uniformly or non-uniformly dispersed in a matrix including the organic material.

A thickness of the electron injection layer may be in a range of about 1 Å to about 100 Å, or, for example, about 3 Å to about 90 Å. When the thickness of the electron injection layer is within the ranges described above, satisfactory electron injection characteristics may be obtained without a substantial increase in driving voltage.

### Second Electrode 150

The second electrode 150 may be on the electron transport region 140. The second electrode 150 may be a cathode, which is an electron injection electrode, and as a material for forming the second electrode 150, a metal, an alloy, an electrically conductive compound, or any combination thereof, each having a low-work function, may be utilized.

The second electrode 150 may include Li, Ag, Mg, Al, Al—Li, Ca, Mg—In, Mg—Ag, Yb, Ag—Yb, ITO, IZO, or any combination thereof. The second electrode 150 may be a transmissive electrode, a semi-transmissive electrode, or a reflective electrode.

The second electrode 150 may have a single-layer structure or a multi-layer structure including multiple layers.

### Optoelectronic Device 30, 31, and 32

Referring to FIG. 4, in one or more embodiments, the optoelectronic device 30 may include the photoactive layer 135 which is a single layer. For example, the photoactive layer 135, which is a single layer, may include both (e.g., simultaneously) of the donor and the acceptor. For example, the photoactive layer 135 may be formed by vacuum-depositing a mixture of the donor and the acceptor. For example, the photoactive layer 135 may be easily manufactured by a single chamber process.

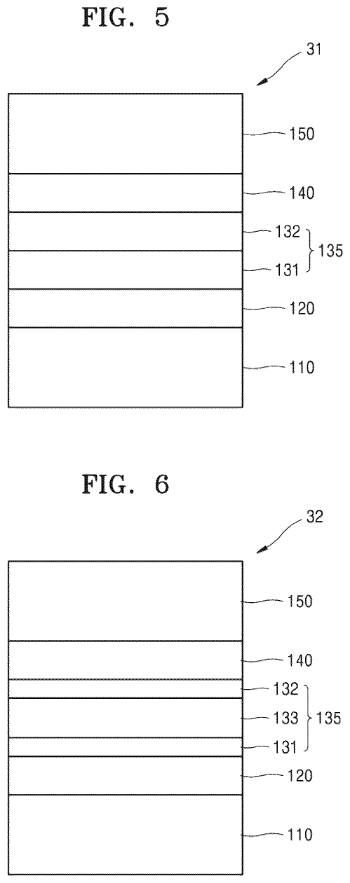

FIG. 5 is a schematic view of an optoelectronic device according to one or more embodiments of present disclosure.

As an optoelectronic device 31 of FIG. 5 is substantially the same as the optoelectronic device 30 of FIG. 4 except for the structure of the photoactive layer 135, any redundant descriptions of other layers are omitted.

Referring to FIG. 5, in one or more embodiments, the photoactive layer 135 may include a first layer 131 adjacent to the hole transport region 120 and a second layer 132 adjacent to the electron transport region 140. For example, the second layer 132 may be arranged between the first layer 131 and the electron transport region 140. For example, in some embodiments, the photoactive layer 135 may have a multi-layer structure which may be divided into the first layer 131 and the second layer 132.

In one or more embodiments, the first layer 131 may include the donor. For example, the first layer 131 may be to absorb red light of about 600 nm to about 750 nm. The first layer 131 may not include (e.g., may exclude) the acceptor and may include the donor; however, embodiments of the present disclosure are not limited thereto.

In one or more embodiments, the second layer 132 may include the acceptor. The second layer 132 may not include (e.g., may exclude) the donor and may include the acceptor; however, embodiments of the present disclosure are not limited thereto.

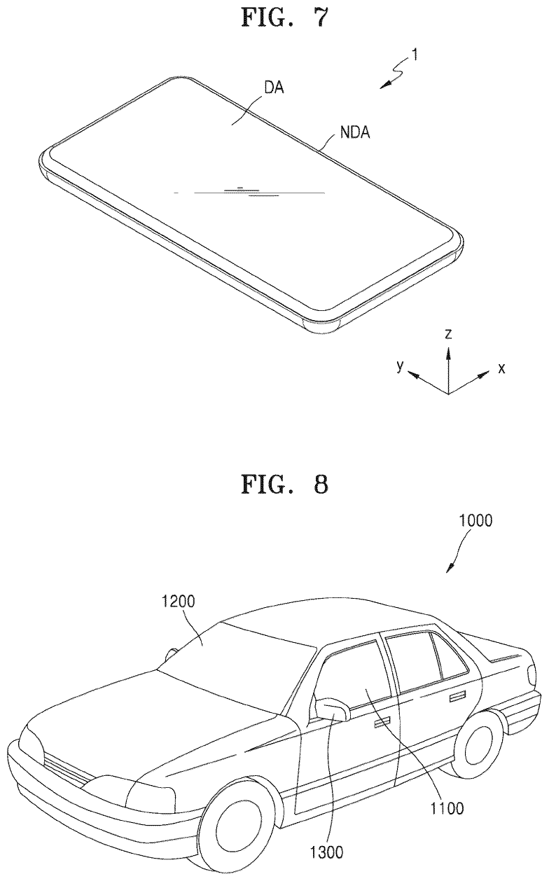

FIG. 6 is a schematic view of an optoelectronic device according to one or more embodiments of the present disclosure.

As an optoelectronic device 32 of FIG. 6 is substantially the same as the optoelectronic device 31 of FIG. 5 except for the structure of the photoactive layer 135, any redundant descriptions of other layers are omitted.

Referring to FIG. 6, in one or more embodiments, the photoactive layer 135 may further include a third layer 133 between the first layer 131 and the second layer 132. For example, in some embodiments, the photoactive layer 135 may have a multi-layer structure which may be divided into the first layer 131, the second layer 132, and the third layer 133.

In one or more embodiments, the third layer 133 may include the donor and the acceptor.

### Electronic Equipment

The optoelectronic device 30, 31, and/or 32 may be included in one or more suitable electronic equipment.

For example, the electronic equipment including the optoelectronic device 30, 31, and/or 32 may be a flat panel display, a curved display, a computer monitor, a medical monitor, a television, a billboard, a light for indoor or outdoor lighting and/or signaling, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual or augmented reality display, a vehicle, a video wall including multiple displays tiled together, a theater or stadium screen, a phototherapy device, a signboard, a sensor for vehicles, a sensor for home, a solar cell, or one or more combinations thereof.

As the optoelectronic device 30, 31, and 32 has excellent or suitable photoelectric characteristics, the electronic equipment may have the function of an optical sensor, such as a fingerprint recognition sensor, a blood pressure recognition sensor, etc.

### Description of FIG. 7

FIG. 7 is a schematic perspective view of electronic equipment 1 including the optoelectronic device 30, 31, and/or 32 according to one or more embodiments. The electronic equipment 1 may be, as a device apparatus that displays a moving image or still image, a portable electronic equipment, such as a mobile phone, a smart phone, a tablet personal computer (PC), a mobile communication terminal, an electronic notebook, an electronic book, a portable multimedia player (PMP), a navigation, or a ultra-mobile PC (UMPC), as well as one or more suitable products, such as a television, a laptop, a monitor, a billboard, or an Internet of things (IOT). The electronic equipment 1 may be such a product above or a part thereof. In some embodiments, the electronic equipment 1 may be a wearable device, such as a smart watch, a watch phone, a glasses-type or kind display, or a head mounted display (HMD), or a part of the wearable device. However, embodiments of the disclosure are not limited thereto. For example, the electronic equipment 1 may be a center information display (CID) on an instrument panel and a center fascia or dashboard of a vehicle, a room mirror display instead of a side mirror of a vehicle, an entertainment display for the rear seat of a car or a display placed on the back of the front seat thereof, head up display (HUD) installed in the front of a vehicle or projected on a front window glass, or a computer generated hologram augmented reality head up display (CGH AR HUD). FIG. 7 illustrates an embodiment in which the electronic equipment 1 is a smart phone for convenience of explanation.

The electronic equipment 1 may include a display area DA and a non-display area NDA outside the display area DA. A display device of the electronic equipment 1 may implement an image through an array of a plurality of pixels that are two-dimensionally arranged in the display area DA.

The non-display area NDA is an area that does not display an image, and may entirely surround the display area DA. On the non-display area NDA, a driver for providing electrical signals or power to display devices arranged on the display area DA may be arranged. On the non-display area NDA, a pad, which is an area to which an electronic element or a printing circuit board may be electrically connected, may be arranged.

In the electronic equipment 1, a length in the x-axis direction and a length (e.g., a width) in the y-axis direction may be different from each other. In some embodiments, as shown in FIG. 7, the length in the x-axis direction may be shorter than the length (e.g., the width) in the y-axis direction. In one or more embodiments, the length in the x-axis direction may be substantially the same as the length (e.g., the width) in the y-axis direction. In one or more embodiments, the length in the x-axis direction may be longer than the length (e.g., the width) in the y-axis direction.

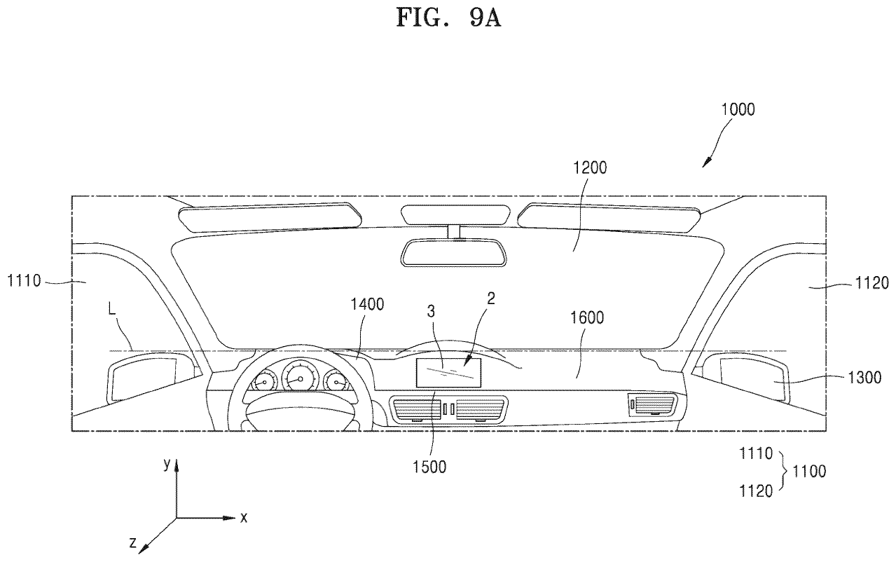

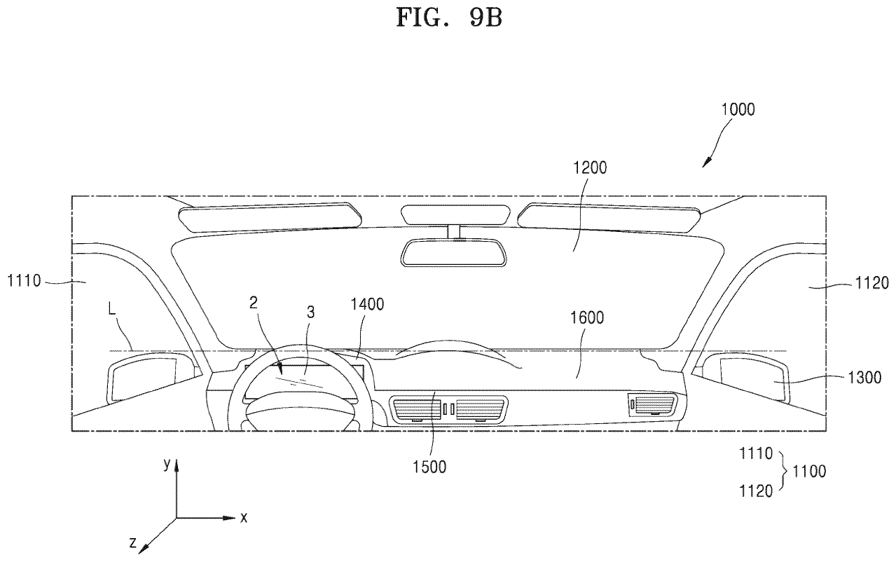

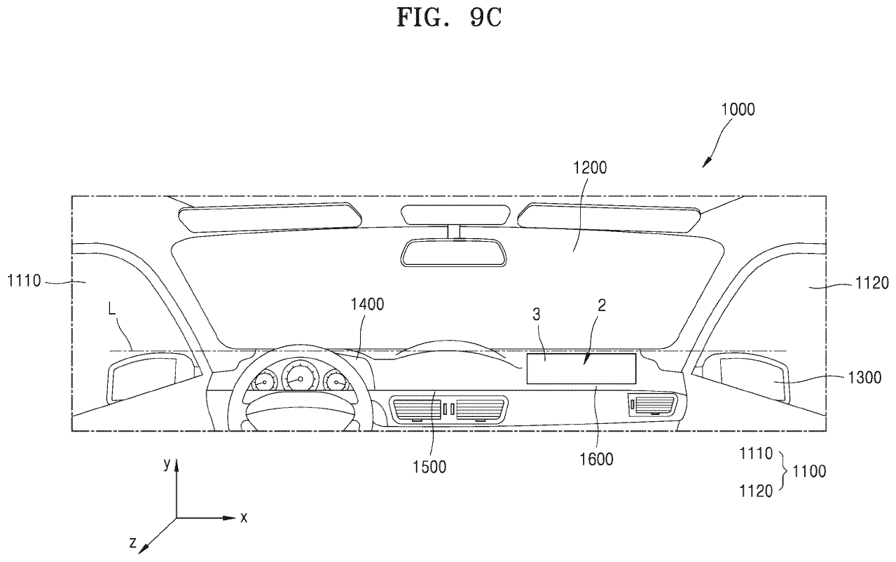

### Descriptions of FIGS. 8 and 9A to 9C

FIG. 8 is a diagram illustrating an exterior of a vehicle 1000 as electronic equipment including the optoelectronic device 30, 31, and/or 32 according to one or more embodiments. FIGS. 9A to 9C are each a schematic view of an interior of the vehicle 1000 according to one or more embodiments.

Referring to FIGS. 8, 9A, 9B, and 9C, the vehicle 1000 may refer to one or more suitable apparatuses for moving an object to be transported, such as a human, an object, or an animal, from a departure point to a destination point. The vehicle 1000 may include a vehicle traveling on a road or a track, a vessel moving over a sea or a river, an airplane flying in the sky utilizing the action of air, and/or the like.

In one or more embodiments, the vehicle 1000 may travel on a road or a track. The vehicle 1000 may move in a set or predetermined direction according to the rotation of at least one wheel thereof. For example, the vehicle 1000 may include a three-wheeled or four-wheeled vehicle, a construction machine, a two-wheeled vehicle, a prime mover device, a bicycle, or a train running on a track.

The vehicle 1000 may include a body having an interior and an exterior, and a chassis in which mechanical apparatuses necessary for driving are installed as other parts except for the body. The exterior of the vehicle body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on a side of the vehicle 1000. In some embodiments, the side window glass 1100 may be installed on a door of the vehicle 1000. A plurality of side window glasses 1100 may be provided and may face each other. In some embodiments, the side window glass 1100 may include a first side window glass 1110 and a second side window glass 1120. In some embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced apart from each other in the x-direction or the −x-direction (the direction opposite the x-direction). For example, in some embodiments, the first side window glass 1110 and the second side window glass 1120 may be spaced apart from each other in the x direction or the −x direction. In other words, an imaginary straight line L connecting the side window glasses 1100 may extend in the x-direction or the −x-direction. For example, an imaginary straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In one embodiment, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and/or a heater of a seat are disposed. The center fascia 1500 may be arranged on one side of the cluster 1400.

The passenger seat dashboard 1600 may be spaced apart from the cluster 1400 with the center fascia 1500 arranged therebetween. In some embodiments, the cluster 1400 may be arranged to correspond to a driver seat, and the passenger seat dashboard 1600 may be disposed to correspond to a passenger seat. In some embodiments, the cluster 1400 may be adjacent to the first side window glass 1110, and the passenger seat dashboard 1600 may be adjacent to the second side window glass 1120.

In one or more embodiments, the display device 2 may include a display panel 3, and the display panel 3 may display an image. The display device 2 may be arranged inside the vehicle 1000. In some embodiments, the display device 2 may be arranged between the side window glasses 1100 facing each other. The display device 2 may be arranged on at least one of the cluster 1400, the center fascia 1500, or the passenger seat dashboard 1600.

The display device 2 may include an organic light-emitting display device, an inorganic electroluminescent (EL) display device, a quantum dot display device, and/or the like. Hereinafter, as the display device 2 according to one or more embodiments of the disclosure, an organic light-emitting display device including the light-emitting device according to the disclosure will be described as an example, but one or more suitable types (kinds) of display devices as described above may be utilized in embodiments of the disclosure.

Referring to FIG. 9A, in one or more embodiments, the display device 2 may be arranged on the center fascia 1500. In some embodiments, the display device 2 may display navigation information. In some embodiments, the display device 2 may display audio, video, or information regarding vehicle settings.

Referring to FIG. 9B, in one or more embodiments, the display device 2 may be arranged on the cluster 1400. When the display device 2 is arranged on the cluster 1400, the cluster 1400 may display driving information and/or the like through the display device 2. For example, the cluster 1400 may be implemented digitally. The digital cluster 1400 may display vehicle information and driving information as images. For example, a needle and a gauge of a tachometer and one or more suitable warning light icons may be displayed by a digital signal.

Referring to FIG. 9C, in one or more embodiments, the display device 2 may be arranged on the passenger seat dashboard 1600. The display device 2 may be embedded in the passenger seat dashboard 1600 or arranged on the passenger seat dashboard 1600. In some embodiments, the display device 2 arranged on the passenger seat dashboard 1600 may display an image related to information displayed on the cluster 1400 and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

The layers constituting the hole transport region, the emission layer, the layers constituting the photoactive layer, and/or the layers constituting the electron transport region may each be formed in a certain region by utilizing one or more suitable methods such as vacuum deposition, spin coating, casting, Langmuir-Blodgett (LB) deposition, ink-jet printing, laser-printing, laser-induced thermal imaging, and/or the like.

When the layers constituting the hole transport region, the emission layer, the layers constituting the photoactive layer, and/or the layers constituting the electron transport region are each formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/see to about 100 Å/see, depending on a material to be included in a layer to be formed and the structure of a layer to be formed.

### DEFINITION OF TERMS

The term “C₃-C₆₀ carbocyclic group” as utilized herein refers to a cyclic group including (e.g., consisting of) carbon only as a ring-forming atom and having 3 to 60 carbon atoms. The term “C₁-C₆₀ heterocyclic group” as utilized herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be a monocyclic group including (e.g., consisting of) one (e.g., only one) ring or a polycyclic group in which two or more rings are condensed with each other. For example, the C₁-C₆₀ heterocyclic group has 3 to 61 ring-forming atoms.

The term “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has 3 to 60 carbon atoms and does not include *—N═*′ as a ring-forming moiety.

The term “π electron-deficient nitrogen-containing C₁-C₆₀ cyclic group” as utilized herein refers to a heterocyclic group that has 1 to 60 carbon atoms and includes *—N═*′ as a ring-forming moiety.

For example, the C₃-C₆₀ carbocyclic group may be i) Group T1 (e.g., one or more of the groups in Group T1) or ii) a condensed cyclic group in which two or more Group T1 (e.g., two or more of the groups in Group T1) are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more Group T2 are condensed with each other, or iii) a condensed cyclic group in which at least one Group T2 (e.g., at least one of the groups in Group T2) and at least one Group T1 (e.g., at least one of the groups in Group T1) are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) Group T1, ii) a condensed cyclic group in which two or more Group T1 are condensed with each other, iii) Group T3, iv) a condensed cyclic group in which two or more Group T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
the π electron-deficient nitrogen-containing C₁-C₆₀ cyclic group may be i) Group T4, ii) a condensed cyclic group in which two or more Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T3 may be a furan group, a thiophene group, a 1H-pyrrole group, a silole group, or a borole group.

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group,” “C₃-C₆₀ carbocyclic group,” “C₁-C₆₀ heterocyclic group,” “π electron-rich C₃-C₆₀ cyclic group,” or “π electron-deficient nitrogen-containing C₁-C₆₀ cyclic group” as utilized herein refer to a group condensed to any cyclic group, a monovalent group, or a polyvalent group (for example, a divalent group, a trivalent group, a tetravalent group, etc.) according to the structure of a formula for which the corresponding term is utilized.

For example, the “benzene group” may be a benzo group, a phenyl group, a phenylene group, and/or the like, which may be easily understood by one of ordinary skill in the art according to the structure of a formula including the “benzene group.”

Non-limiting examples of the monovalent C₃-C₆₀ carbocyclic group and monovalent C₁-C₆₀ heterocyclic group may be a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Non-limiting examples of the divalent C₃-C₆₀ carbocyclic group and the divalent C₁-C₆₀ heterocyclic group may be a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as utilized herein refers to a linear or branched aliphatic hydrocarbon monovalent group that has one to sixty carbon atoms, and non-limiting examples thereof may be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group.

The term “C₁-C₆₀ alkylene group” as utilized herein refers to a divalent group having substantially the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of a C₂-C₆₀ alkyl group, and non-limiting examples thereof may be an ethenyl group, a propenyl group, and a butenyl group.

The term “C₂-C₆₀ alkenylene group” as utilized herein refers to a divalent group having substantially the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of a C₂-C₆₀ alkyl group, and non-limiting examples thereof may include an ethynyl group, a propynyl group, and/or the like.

The term “C₂-C₆₀ alkynylene group” as utilized herein refers to a divalent group having substantially the same structure as the C₂-C₆₀ alkynyl group.

The term “C₁-C₆₀ alkoxy group” as utilized herein refers to a monovalent group represented by —OA₁₀₁ (wherein A₁₀₁ is a C₁-C₆₀ alkyl group), and non-limiting examples thereof may include a methoxy group, an ethoxy group, and an isopropyloxy group.

The term “C₃-C₁₀ cycloalkyl group” as utilized herein refers to a monovalent saturated hydrocarbon cyclic group having 3 to 10 carbon atoms, and non-limiting examples thereof may be a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group.

The term “C₃-C₁₀ cycloalkylene group” as utilized herein refers to a divalent group having substantially the same structure as the C₃-C₁₀ cycloalkyl group.

The term “C₁-Cia heterocycloalkyl group” as utilized herein refers to a monovalent cyclic group of 1 to 10 carbon atoms, further including, in addition to carbon atoms, at least one heteroatom, as ring-forming atoms, and non-limiting examples may be a 1,2,3,4-oxatriazolidinyl group, a tetrahydrofuranyl group, and a tetrahydrothiophenyl group.

The term “C₁-C₁₀ heterocycloalkylene group” as utilized herein refers to a divalent group having substantially the same structure as the C₁-C₁₀ heterocycloalkyl group.

The term “C₃-Cia cycloalkenyl group” utilized herein refers to a monovalent cyclic group that has three to ten carbon atoms and at least one carbon-carbon double bond in the ring thereof and no aromaticity, and non-limiting examples thereof may be a cyclopentenyl group, a cyclohexenyl group, and a cycloheptenyl group.

The term “C₃-Cia cycloalkenylene group” as utilized herein refers to a divalent group having substantially the same structure as the C₃-Cia cycloalkenyl group.

The term “C₁-C₁₀ heterocycloalkenyl group” as utilized herein refers to a monovalent cyclic group of 1 to 10 carbon atoms, further including, in addition to carbon atoms, at least one heteroatom, as ring-forming atoms, and having at least one double bond in the cyclic structure thereof. Non-limiting examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group.

The term “C₁-Cia heterocycloalkenylene group” as utilized herein refers to a divalent group having substantially the same structure as the C₁-Cia heterocycloalkenyl group.

The term “C₆-C₆₀ aryl group” as utilized herein refers to a monovalent group having a carbocyclic aromatic system of 6 to 60 carbon atoms.

The term “C₆-C₆₀ arylene group” as utilized herein refers to a divalent group having a carbocyclic aromatic system of 6 to 60 carbon atoms.

Non-limiting examples of the C₆-C₆₀ aryl group may be a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group.

When the C₆-C₆₀ aryl group and the C₆-C₆₀ arylene group each include two or more rings, the rings may be condensed with each other.

The term “C₁-C₆₀ heteroaryl group” as utilized herein refers to a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as utilized herein refers to a divalent group having a heterocyclic aromatic system of 1 to 60 carbon atoms, further including, in addition to carbon atoms, at least one heteroatom, as ring-forming atoms.

Non-limiting examples of the C₁-C₆₀ heteroaryl group may be a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group.

When the C₁-C₆₀ heteroaryl group and the C₁-C₆₀ heteroarylene group each include two or more rings, the rings may be condensed with each other.

The term “monovalent non-aromatic condensed polycyclic group” as utilized herein refers to a monovalent group (for example, having 8 to 60 carbon atoms) having two or more rings condensed to each other, only carbon atoms as ring-forming atoms, and no aromaticity in its entire molecular structure when considered as a whole. Non-limiting examples of the monovalent non-aromatic condensed polycyclic group may be an indenyl group, a fluorenyl group, a spiro-bifluorenyl group, a benzofluorenyl group, an indenophenanthrenyl group, and an indeno anthracenyl group.

The term “divalent non-aromatic condensed polycyclic group” as utilized herein refers to a divalent group having substantially the same structure as the monovalent non-aromatic condensed polycyclic group described above.

The term “monovalent non-aromatic condensed heteropolycyclic group” as utilized herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure when considered as a whole. Non-limiting examples of the monovalent non-aromatic condensed heteropolycyclic group may be a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group.

The term “divalent non-aromatic condensed heteropolycyclic group” as utilized herein refers to a divalent group having substantially the same structure as the monovalent non-aromatic condensed heteropolycyclic group described above.

The term “C₆-C₆₀ aryloxy group” as utilized herein indicates —OA₁₀₂ (wherein A₁₀₂ is a C₆-C₆₀ aryl group).

The term “C₆-C₆₀ arylthio group” as utilized herein indicates —SA₁₀₃ (wherein A₁₀₃ is a C₆-C₆₀ aryl group).

The term “C₇-C₆₀ arylalkyl group” as utilized herein refers to -A₁₀₄A₁₀₅ (wherein A₁₀₄ is a C₁-C₅₄ alkylene group, and A₁₀₅ is a C₆-C₅₉ aryl group).

The term “C₂-C₆₀ heteroarylalkyl group” as utilized herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as utilized herein refers to:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃ and Q₃₁ to Q₃₃ utilized herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as utilized herein refers to any atom other than a carbon atom. Non-limiting examples of the heteroatom are O, S, N, P, Si, B, Ge, Se, and any combinations thereof.

The term “transition metal” utilized herein includes hafnium (Hf), tantalum (Ta), tungsten (W), rhenium (Re), osmium (Os), iridium (Ir), platinum (Pt), gold (Au), and/or the like.

In the present disclosure, “D” refers to deuterium, “Ph” refers to a phenyl group, “Me” refers to a methyl group, “Et” refers to an ethyl group, “tert-Bu” or “Bu^{t}” refers to a tert-butyl group, and “OMe” refers to a methoxy group.

The term “CF₃” as utilized herein refers to “a methyl group substituted with F.” In other words, “CF₃” is a substituted alkyl group having F as a substituent.

The term “biphenyl group” as utilized herein refers to “a phenyl group substituted with a phenyl group.” In other words, the “biphenyl group” is a substituted phenyl group having a C₆-C₆₀ aryl group as a substituent.

The term “terphenyl group” as utilized herein refers to “a phenyl group substituted with a biphenyl group”. In other words, the “terphenyl group” is a substituted phenyl group having, as a substituent, a C₆-C₆₀ aryl group substituted with a C₆-C₆₀ aryl group.

*, *′, and *″ as utilized herein, unless defined otherwise, each refer to a binding site to a neighboring atom in a corresponding formula or moiety.

In the present disclosure, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

Hereinafter, embodiments of the optoelectronic device of the disclosure will be described in more detail with reference to the following Examples and Comparative Examples.

### Evaluation Example 1

To evaluate characteristics of each of Compounds A₄, A₉, A₁₆, B1, B22, and B41 as a donor and Compounds C₁, C₃, C₄, C₅, and C₇, Fullerene 60, and Fullerene 70 as an acceptor, the HOMO energy level, LUMO energy level, and maximum absorption wavelength (λ_{abs}) of each of the compounds were measure, and the results thereof are shown in Tables 1 and 2. In addition, the difference between the LUMO energy level and the HOMO energy level of each compound was calculated, and the results thereof are also provided in Tables 1 and 2.

The energy levels in a structurally enhanced or optimized state and in an excited state were evaluated by performing quantum simulation/computation at a level of B3LYP/6-311 G** based on the time-dependent density functional theory by utilizing a Gaussian program.

TABLE 1

| | | | E^{D}_{LUMO}- | |
|---|---|---|---|---|
| | LUMO | HOMO | E^{D}_{HOMO} | λ_{abs} |
| Donor | (eV) | (eV) | (eV) | (nm) |
| A4 | −3.4 | −5.3 | 1.9 | 630 |
| A9 | −3.4 | −5.3 | 1.9 | 636 |
| A16 | −3.4 | −5.3 | 1.9 | 633 |
| B1 | −3.3 | −5.3 | 2.0 | 631 |
| B22 | −3.2 | −5.2 | 2.0 | 627 |
| B41 | −3.2 | −5.4 | 2.2 | 625 |

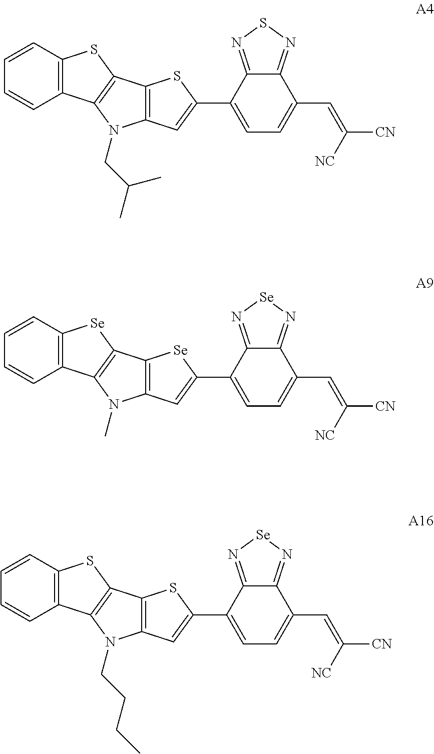 [SMILES: CC(C)Cn1c2cc(-c3ccc(C=C(C#N)C#N)c4nsnc34)sc2c2sc3ccccc3c21 ; Cn1c2cc(-c3ccc(C=C(C#N)C#N)c4n[se]nc34)[se]c2c2[se]c3ccccc3c21 ; CCCCn1c2cc(-c3ccc(C=C(C#N)C#N)c4n[se]nc34)sc2c2sc3ccccc3c21]

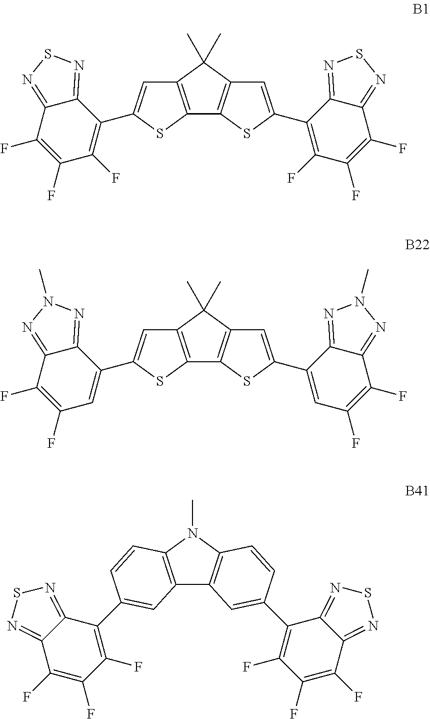 [SMILES: CC1(C)c2cc(-c3c(F)c(F)c(F)c4nsnc34)sc2-c2sc(-c3c(F)c(F)c(F)c4nsnc34)cc21 ; Cn1nc2c(-c3cc4c(s3)-c3sc(-c5cc(F)c(F)c6nn(C)nc56)cc3C4(C)C)cc(F)c(F)c2n1 ; Cn1c2ccc(-c3c(F)c(F)c(F)c4nsnc34)cc2c2cc(-c3c(F)c(F)c(F)c4nsnc34)ccc21]

TABLE 2

| | LUMO | HOMO | E^{A}_{LUMO}-E^{A}_{HOMO} |
|---|---|---|---|
| | (eV) | (eV) | (eV) |
| C1 | −4.2 | −7.9 | 3.7 |
| C3 | −3.6 | −7.3 | 3.7 |
| C4 | −3.6 | −7.2 | 3.6 |
| C5 | −3.5 | −6.9 | 3.4 |
| C7 | −3.8 | −7.2 | 3.4 |
| Fullerene 60 | −3.7 | −6.4 | 2.7 |
| Fullerene 70 | −3.7 | −6.4 | 2.7 |

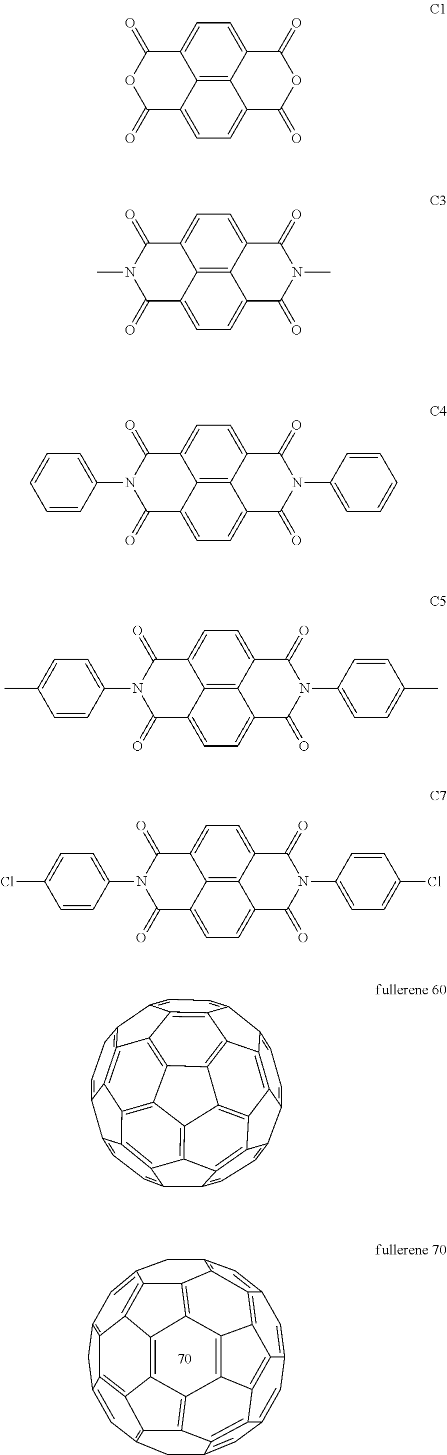

### Example 1

As an anode, a glass substrate (product of Corning Inc.) with a 15 Ω/cm² (1,200 Å) ITO formed thereon was cut to a size of 50 mm×50 mm×0.7 mm, sonicated with isopropyl alcohol and then pure water each for 5 minutes, cleaned by irradiation of ultraviolet rays and exposure of ozone thereto for 30 minutes, and then mounted on a vacuum deposition apparatus.

2-TNATA was vacuum-deposited on the anode to form a hole injection layer having a thickness of 100 Å. 4,4′-bis[N-(1-naphthyl)-N-phenylamino]biphenyl (NPB) was vacuum-deposited on the hole injection layer to form a hole transport layer having a thickness of 1,250 Å.

Compound A4 was vacuum-deposited on the hole transport layer to form a first layer having a thickness of 200 Å and included in a photoactive layer. Compound C1 was vacuum-deposited on the first layer to form a second layer having a thickness of 250 Å.

Subsequently, BAIq was vacuum-deposited on the second layer to form a hole-blocking layer having a thickness of 50 Å, and ET1 was vacuum-deposited on the hole-blocking layer to form an electron transport layer having a thickness of 300 Å. LiQ was vacuum-deposited on the electron transport layer to form an electron injection layer having a thickness of 10 Å.

AgMg was deposited on the electron injection layer to form a cathode having a thickness of a 100 Å, thereby completing the manufacture of an optoelectronic device.

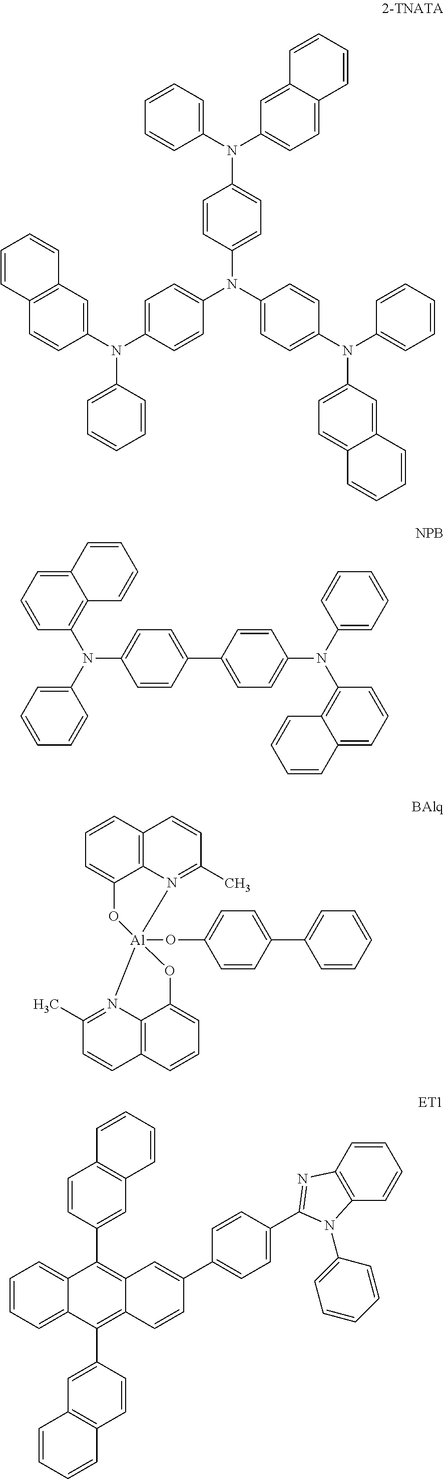

### Examples 2 to 30 and Comparative Examples 1 to 12

Optoelectronic devices were each manufactured in substantially the same manner as in Example 1, except that the donors indicated in Tables 3 to 8 were each respectively utilized when forming a first layer included in a photoactive layer, and the acceptors indicated in Tables 3 to 8 were each respectively utilized when forming a second layer included in the photoactive layer.

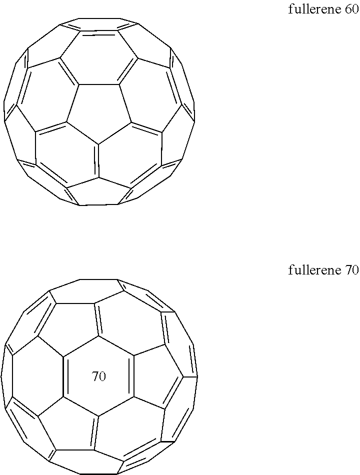

### Evaluation Example 2

To evaluate characteristics of each of the optoelectronic devices manufactured in Examples 1 to 30 and Comparative Examples 1 to 12, external quantum efficiency (EQE) and dark current density (J_{dark}) were measured, and results thereof are shown in Tables 3 to 8.

N As for the external quantum efficiency (FOE), current values generated by irradiating red light having a wavelength of about 600 nm to about 750 nm to the optoelectronic devices manufactured in Examples 1 to 30 and Comparative Examples 1 to 12 were each measured by utilizing an external quantum efficiency measuring device (K3100, McScience, Korea) and a current meter (Keithley, Tektronix, USA), and the EQE values were calculated from the current values.

As for the dark current density (J_{dark}), the dark current density at −3 V reverse bias was measured by utilizing electro-optics characteristics evaluating equipment (K3100, McScience, Korean) and a current meter (Keithley, Tektronix, USA) while applying a voltage to an anode.

TABLE 3

| | | | | | (E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 1 | A4 | C1 | 0.8 | 1.9 | 0.42 | 47 | 6.2 × 10⁻⁶ |
| Example 2 | A4 | C3 | 0.2 | 1.9 | 0.11 | 49 | 4.5 × 10⁻⁶ |
| Example 3 | A4 | C4 | 0.2 | 1.9 | 0.11 | 45 | 4.4 × 10⁻⁶ |
| Example 4 | A4 | C5 | 0.1 | 1.9 | 0.05 | 62 | 2.2 × 10⁻⁶ |
| Example 5 | A4 | C7 | 0.4 | 1.9 | 0.21 | 68 | 5.2 × 10⁻⁶ |
| Comparative | A4 | Fullerene | 0.3 | 1.9 | 0.16 | 34 | 3.3 × 10⁻⁶ |
| Example 1 | | 60 | | | | | |
| Comparative | A4 | Fullerene | 0.3 | 1.9 | 0.16 | 39 | 4.8 × 10⁻⁶ |
| Example 2 | | 70 | | | | | |

TABLE 4

| | | | | | (E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 6 | A9 | C1 | 0.8 | 1.9 | 0.42 | 45 | 6.3 × 10⁻⁶ |
| Example 7 | A9 | C3 | 0.2 | 1.9 | 0.11 | 46 | 4.5 × 10⁻⁶ |
| Example 8 | A9 | C4 | 0.2 | 1.9 | 0.11 | 43 | 4.5 × 10⁻⁶ |
| Example 9 | A9 | C5 | 0.1 | 1.9 | 0.05 | 60 | 2.5 × 10⁻⁶ |
| Example 10 | A9 | C7 | 0.4 | 1.9 | 0.21 | 66 | 5.3 × 10⁻⁶ |
| Comparative | A9 | Fullerene | 0.3 | 1.9 | 0.16 | 33 | 3.4 × 10⁻⁶ |
| Example 3 | | 60 | | | | | |
| Comparative | A9 | Fullerene | 0.3 | 1.9 | 0.16 | 38 | 4.9 × 10⁻⁶ |
| Example 4 | | 70 | | | | | |

TABLE 5

| | | | | | (E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 11 | A16 | C1 | 0.8 | 1.9 | 0.42 | 46 | 6.2 × 10⁻⁶ |
| Example 12 | A16 | C3 | 0.2 | 1.9 | 0.11 | 47 | 4.5 × 10⁻⁶ |
| Example 13 | A16 | C4 | 0.2 | 1.9 | 0.11 | 44 | 4.4 × 10⁻⁶ |
| Example 14 | A16 | C5 | 0.1 | 1.9 | 0.05 | 61 | 2.3 × 10⁻⁶ |
| Example 15 | A16 | C7 | 0.4 | 1.9 | 0.21 | 67 | 5.3 × 10⁻⁶ |
| Comparative | A16 | Fullerene | 0.3 | 1.9 | 0.16 | 34 | 3.5 × 10⁻⁶ |
| Example 5 | | 60 | | | | | |
| Comparative | A16 | Fullerene | 0.3 | 1.9 | 0.16 | 39 | 4.8 × 10⁻⁶ |
| Example 6 | | 70 | | | | | |

TABLE 6

| | | | | | (E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 16 | B1 | C1 | 0.9 | 2.0 | 0.45 | 46 | 6.3 × 10⁻⁶ |
| Example 17 | B1 | C3 | 0.3 | 2.0 | 0.15 | 49 | 4.6 × 10⁻⁶ |
| Example 18 | B1 | C4 | 0.3 | 2.0 | 0.15 | 45 | 4.4 × 10⁻⁶ |
| Example 19 | B1 | C5 | 0.2 | 2.0 | 0.1 | 62 | 2.2 × 10⁻⁶ |
| Example 20 | B1 | C7 | 0.5 | 2.0 | 0.25 | 65 | 5.2 × 10⁻⁶ |
| Comparative | B1 | Fullerene | 0.4 | 2.0 | 0.2 | 33 | 3.3 × 10⁻⁶ |
| Example 7 | | 60 | | | | | |
| Comparative | B1 | Fullerene | 0.4 | 2.0 | 0.2 | 38 | 4.8 × 10⁻⁶ |
| Example 8 | | 70 | | | | | |

TABLE 7

| | | | | | (E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 21 | B22 | C1 | 1.0 | 2.0 | 0.5 | 45 | 6.4 × 10⁻⁶ |
| Example 22 | B22 | C3 | 0.4 | 2.0 | 0.2 | 46 | 4.4 × 10⁻⁶ |
| Example 23 | B22 | C4 | 0.4 | 2.0 | 0.2 | 44 | 4.4 × 10⁻⁶ |
| Example 24 | B22 | C5 | 0.3 | 2.0 | 0.15 | 62 | 2.3 × 10⁻⁶ |
| Example 25 | B22 | C7 | 0.6 | 2.0 | 0.3 | 66 | 5.5 × 10⁻⁶ |
| Comparative | B22 | Fullerene | 0.5 | 2.0 | 0.25 | 34 | 3.7 × 10⁻⁶ |
| Example 9 | | 60 | | | | | |
| Comparative | B22 | Fullerene | 0.5 | 2.0 | 0.25 | 39 | 4.7 × 10⁻⁶ |
| Example 10 | | 70 | | | | | |

TABLE 8

| | | | | | E^{D}_{LUMO} − | | |
|---|---|---|---|---|---|---|---|
| | | | E^{D}_{LUMO} − | E^{D}_{LUMO} − | E^{A}_{LUMO})/ | | |
| | | | E^{A}_{LUMO} | E^{D}_{HOMO} | (E^{D}_{LUMO} − | EQE | J_{dark} |
| No. | Donor | Acceptor | (eV) | (eV) | E^{D}_{HOMO}) | (%) | (mA/cm²) |
| Example 26 | B41 | C1 | 1.0 | 2.2 | 0.45 | 43 | 6.2 × 10⁻⁶ |
| Example 27 | B41 | C3 | 0.4 | 2.2 | 0.18 | 44 | 4.6 × 10⁻⁶ |
| Example 28 | B41 | C4 | 0.4 | 2.2 | 0.18 | 41 | 4.5 × 10⁻⁶ |
| Example 29 | B41 | C5 | 0.3 | 2.2 | 0.14 | 59 | 2.7 × 10⁻⁶ |
| Example 30 | B41 | C7 | 0.6 | 2.2 | 0.27 | 64 | 5.4 × 10⁻⁶ |
| Comparative | B41 | Fullerene | 0.5 | 2.2 | 0.23 | 32 | 3.6 × 10⁻⁶ |
| Example 11 | | 60 | | | | | |
| Comparative | B41 | Fullerene | 0.5 | 2.2 | 0.23 | 37 | 5.0 × 10⁻⁶ |
| Example 12 | | 70 | | | | | |

Referring to Tables 3 to 8, the optoelectronic devices according to Examples 1 to 30 which satisfy Expression 1 each have better external quantum efficiency than that of the optoelectronic devices according to Comparative Examples 1 to 12 which do not satisfy Expression 1.

When a value of (E^{D}_{LUMO}−E^{A}_{LUMO})/(E^{D}_{LUMO}−E^{D}_{HOMO}) is less than 0.05, the excitons generated from the donor may not be substantially transported to the acceptor.

When the value of (E^{D}_{LUMO}−E^{A}_{LUMO})/(E^{D}_{LUMO}−E^{D}_{HOMO}) is greater than 0.5, the holes of the donor and the electrons of the acceptor may combine, and excitons may not be substantially generated.

When an acceptor having a value of E^{A}_{LUMO}−E^{A}_{HOMO} outside a range from 3 eV to 4 eV is utilized, the charge balance may be degraded, and the charge-transporting characteristics and the exciton-generating characteristics may be diminished even when the value of (E^{D}_{LUMO}−E^{A}_{LUMO})/(E^{D}_{LUMO}−E^{D}_{HOMO}) is within the range of 0.05 to 0.5.

Accordingly, when both (e.g., simultaneously) of the donor absorbing red light and the acceptor satisfying Expression 1 are employed, and Expression 2 is satisfied, the external quantum efficiency of the optoelectronic device may be improved.

In the present disclosure, it will be understood that the term “comprise(s),” “include(s),” or “have/has” specifies the presence of stated features, integers, steps, operations, elements, and/or components, but do not preclude the presence or addition of one or more other features, integers, steps, operations, elements, components, and/or groups thereof.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The optoelectronic device, the light-emitting device, the display device, the electronic apparatus, the electronic device/electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the appended claims and equivalents thereof.

What is claimed is:

1. An optoelectronic device comprising:
a first electrode;
a second electrode facing the first electrode; and
a photoactive layer between the first electrode and the second electrode,
wherein the photoactive layer comprises an acceptor satisfying Expression 1 and a donor having a maximum absorption wavelength of about 600 nm to about 750 nm, and
Expression 2 is satisfied:
$$3 eV \leq {E}_{LUMO}^{A} - {E}_{HOMO}^{A} \leq 4 eV \qquad Expression 1$$
$$0.05 \leq ( {E}_{LUMO}^{D} - {E}_{LUMO}^{A} ) / ( {E}_{LUMO}^{D} - {E}_{HOMO}^{D} ) \leq 0.5 \qquad Expression 2$$
in Expressions 1 and 2,
E^{D}_{LUMO} representing a lowest unoccupied molecular orbital (LUMO) energy level of the donor,
E^{D}_{HOMO} representing a highest occupied molecular orbital (HOMO) energy level of the donor,
E^{A}_{LUMO} representing a LUMO energy level of the acceptor, and
E^{A}_{HOMO} representing a HOMO energy level of the acceptor.

2. The optoelectronic device of claim 1, wherein the donor satisfies Expression 3:
$$1. eV \leq {E}_{LUMO}^{D} - {E}_{HOMO}^{D} \leq 2.5 eV \qquad Expression 3$$
in Expression 3,
E^{D}_{LUMO} and E^{D}_{HOMO} each being the same as described in Expression 2.

3. The optoelectronic device of claim 1, wherein Expression 4 is further satisfied:
$${E}_{LUMO}^{A} \leq {E}_{LUMO}^{D} \qquad Expression 4$$
in Expression 4,
E^{D}_{LUMO} and E^{A}_{LUMO} each being the same as described in Expressions 1 and 2.

4. The optoelectronic device of claim 1, wherein Expression 5 is further satisfied:
$${E}_{HOMO}^{A} \leq {E}_{HOMO}^{D} \qquad Expression 5$$
in Expression 5,
E^{D}_{HOMO} and E^{A}_{HOMO} each being the same as described in Expressions 1 and 2.

5. The optoelectronic device of claim 1, wherein the acceptor does not comprise a fullerene-based compound.

6. The optoelectronic device of claim 1, wherein the acceptor does not comprise a 5-membered ring.

7. The optoelectronic device of claim 1, wherein the acceptor is transparent in a visible light region.

8. The optoelectronic device of claim 1, wherein the acceptor is represented by Formula 1: 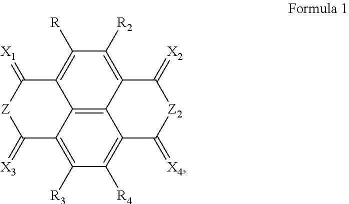
wherein, in Formula 1,
X₁ to X₄ are each independently O, S, or Se,
Z₁ is O or N(R₅),
Z₂ is O or N(R₆),
R₁ to R₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ being:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ each being independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

9. The optoelectronic device of claim 1, wherein the acceptor is at least one selected from among Compounds C1 to C17:

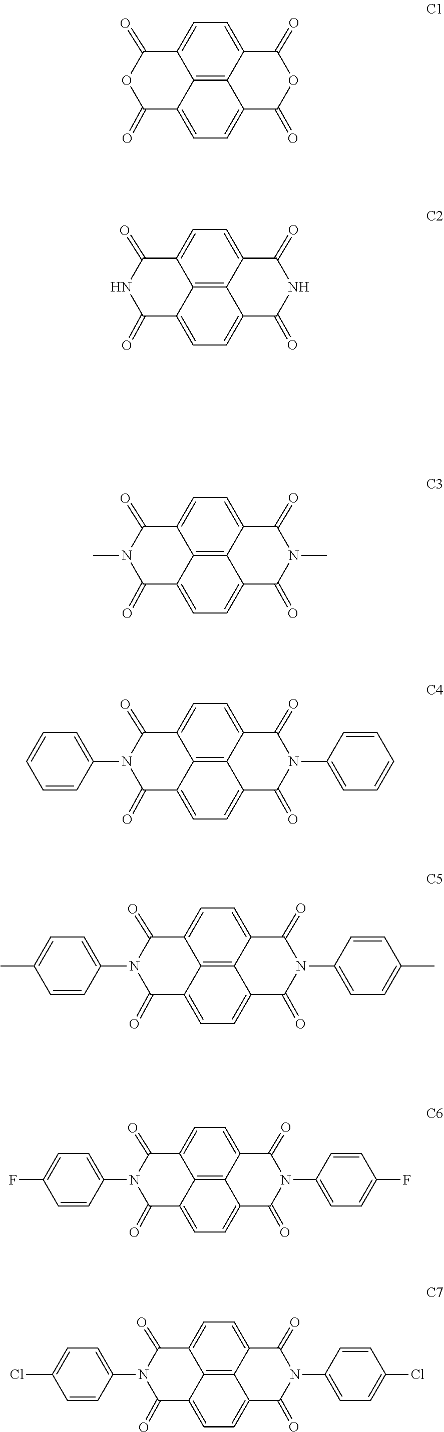

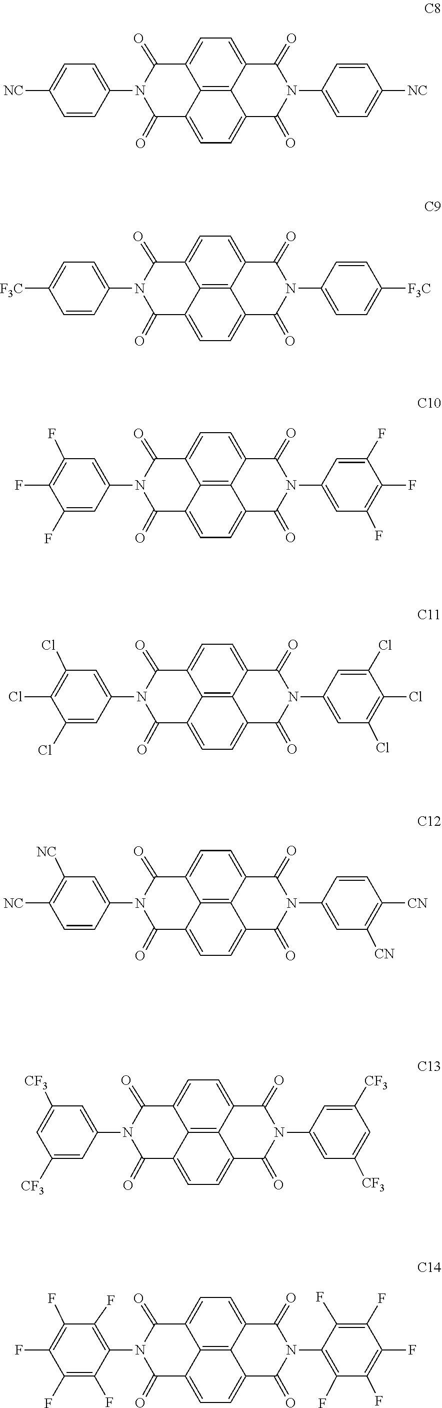

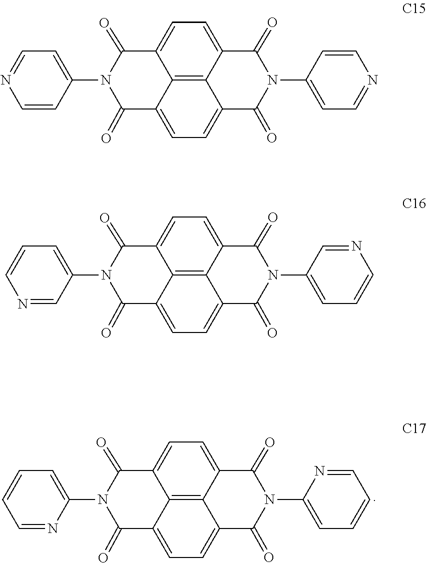 [SMILES: O=C1c2ccc3c4c(ccc(c24)C(=O)N1c1ccncc1)C(=O)N(c1ccncc1)C3=O ; O=C1c2ccc3c4c(ccc(c24)C(=O)N1c1cccnc1)C(=O)N(c1cccnc1)C3=O ; O=C1c2ccc3c4c(ccc(c24)C(=O)N1c1ccccn1)C(=O)N(c1ccccn1)C3=O]

10. The optoelectronic device of claim 1, wherein the donor has a maximum absorption wavelength of about 630 nm to about 700 nm.

11. The optoelectronic device of claim 1, wherein the donor does not include boron.

12. The optoelectronic device of claim 1, wherein the donor is represented by any one selected from among Formulae 2 and 3: 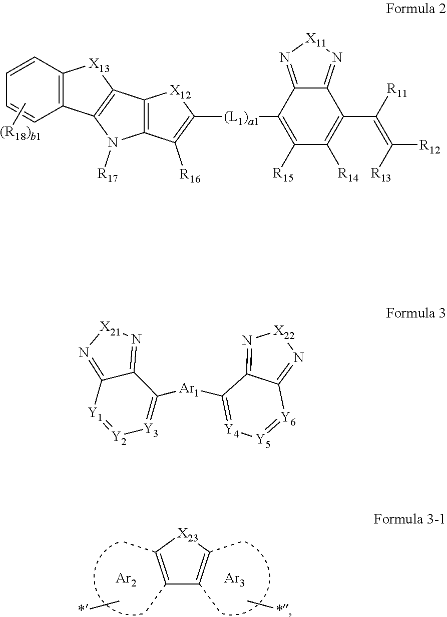
in Formulae 2, 3, and 3-1,
L₁ being a single bond, a C₁-C₂₀ alkylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
a1 being an integer from 1 to 3,
Ar₁ being a group represented by Formula 3-1,
Ar₂ and Ar₃ being each independently a C₃-C₆₀ carbocyclic group unsubstituted or substituted with at least one R₁₀ₐ or a C₁-C₆₀ heterocyclic group unsubstituted or substituted with at least one R₁₀ₐ,
X₁₁ to X₁₃ being each independently O, S, or Se,
X₂₁ being N(R₂₁), O, S, or Se,
X₂₂ being N(R₂₂), O, S, or Se,
X₂₃ is C(R₂₃ₐ)(R_{23b}), N(R₂₃), O, S, or Se,
Y₁ being N or C(R₂₄),
Y₂ being N or C(R₂₅),
Y₃ being N or C(R₂₆),
Y₄ being N or C(R₂₇),
Y₅ being N or C(R₂₈),
Y₆ being N or C(R₂₉),
R₁₁ to R₁₈, R₂₁ to R₂₉, R₂₃ₐ, and R_{23b} being each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ being:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ each being independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
b1 being an integer from 0 to 4, and
*′ and *″ each indicating a binding site to a neighboring atom.

13. The optoelectronic device of claim 1, wherein the donor is at least one selected from among Compounds A1 to A32, B1 to B50, and combinations thereof:

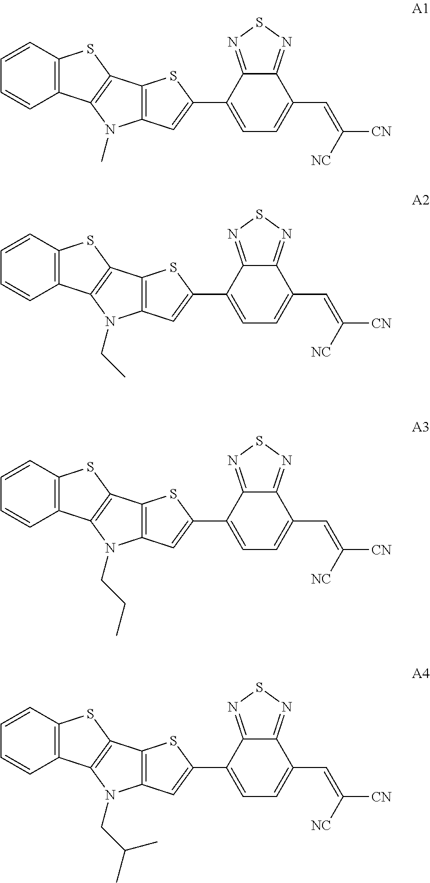 [SMILES: Cn1c2cc(-c3ccc(C=C(C#N)C#N)c4nsnc34)sc2c2sc3ccccc3c21 ; CCn1c2cc(-c3ccc(C=C(C#N)C#N)c4nsnc34)sc2c2sc3ccccc3c21 ; CCCn1c2cc(-c3ccc(C=C(C#N)C#N)c4nsnc34)sc2c2sc3ccccc3c21 ; CC(C)Cn1c2cc(-c3ccc(C=C(C#N)C#N)c4nsnc34)sc2c2sc3ccccc3c21]

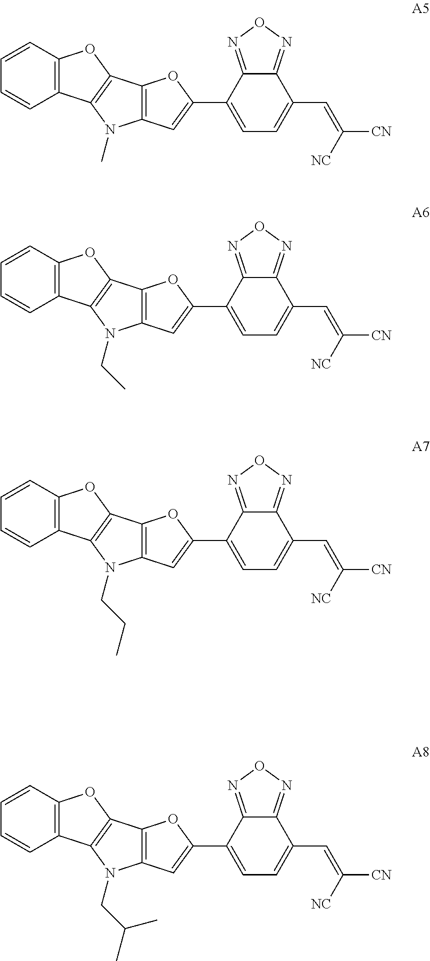 [SMILES: Cn1c2cc(-c3ccc(C=C(C#N)C#N)c4nonc34)oc2c2oc3ccccc3c21 ; CCn1c2cc(-c3ccc(C=C(C#N)C#N)c4nonc34)oc2c2oc3ccccc3c21 ; CCCn1c2cc(-c3ccc(C=C(C#N)C#N)c4nonc34)oc2c2oc3ccccc3c21 ; CC(C)Cn1c2cc(-c3ccc(C=C(C#N)C#N)c4nonc34)oc2c2oc3ccccc3c21]

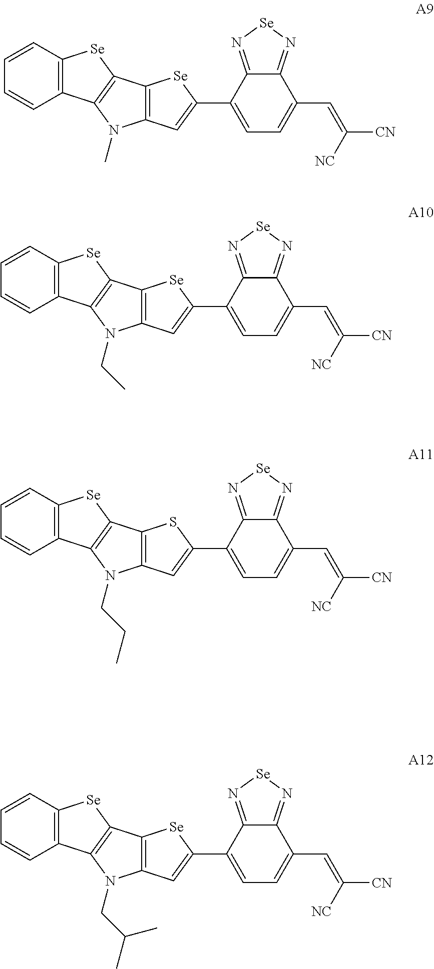 [SMILES: Cn1c2cc(-c3ccc(C=C(C#N)C#N)c4n[se]nc34)[se]c2c2[se]c3ccccc3c21 ; CCn1c2cc(-c3ccc(C=C(C#N)C#N)c4n[se]nc34)[se]c2c2[se]c3ccccc3c21 ; CCCn1c2cc(-c3ccc(C=C(C#N)C#N)c4n[se]nc34)sc2c2[se]c3ccccc3c21 ; CC(C)Cn1c2cc(-c3ccc(C=C(C#N)C#N)c4n[se]nc34)[se]c2c2[se]c3ccccc3c21]

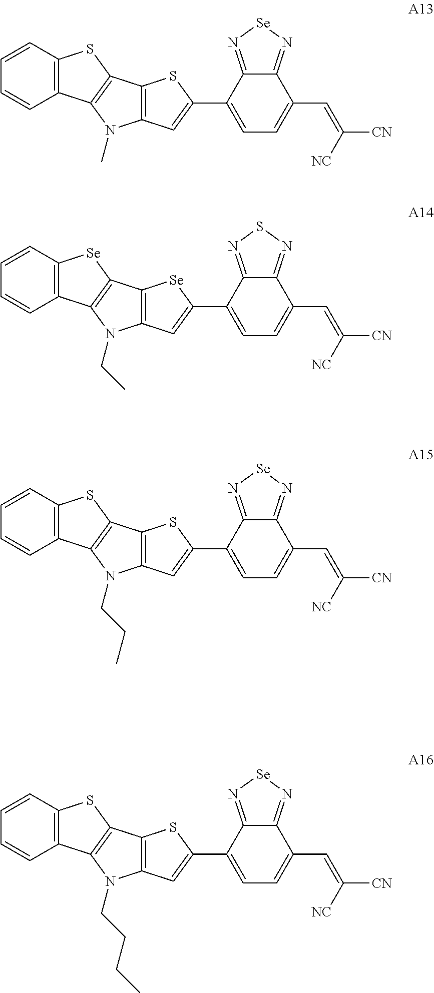 [SMILES: Cn1c2cc(-c3ccc(C=C(C#N)C#N)c4n[se]nc34)sc2c2sc3ccccc3c21 ; CCn1c2cc(-c3ccc(C=C(C#N)C#N)c4nsnc34)[se]c2c2[se]c3ccccc3c21 ; CCCn1c2cc(-c3ccc(C=C(C#N)C#N)c4n[se]nc34)sc2c2sc3ccccc3c21 ; CCCCn1c2cc(-c3ccc(C=C(C#N)C#N)c4n[se]nc34)sc2c2sc3ccccc3c21]

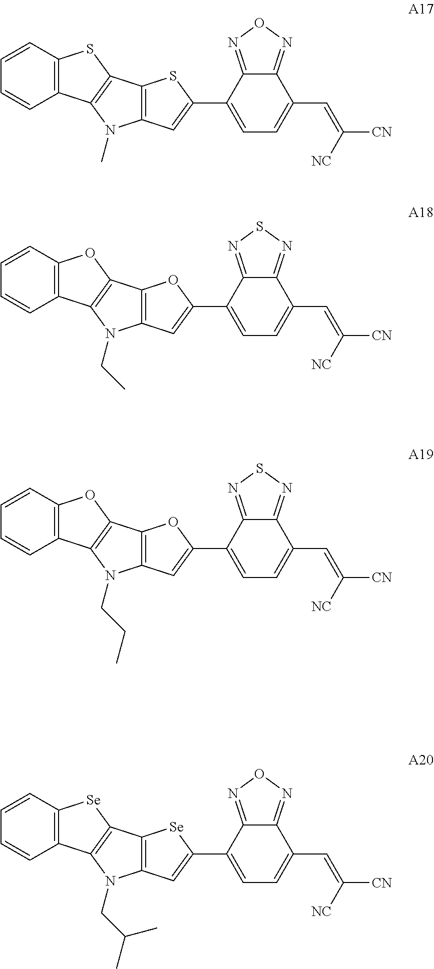 [SMILES: Cn1c2cc(-c3ccc(C=C(C#N)C#N)c4nonc34)sc2c2sc3ccccc3c21 ; CCn1c2cc(-c3ccc(C=C(C#N)C#N)c4nsnc34)oc2c2oc3ccccc3c21 ; CCCn1c2cc(-c3ccc(C=C(C#N)C#N)c4nsnc34)oc2c2oc3ccccc3c21 ; CC(C)Cn1c2cc(-c3ccc(C=C(C#N)C#N)c4nonc34)[se]c2c2[se]c3ccccc3c21]

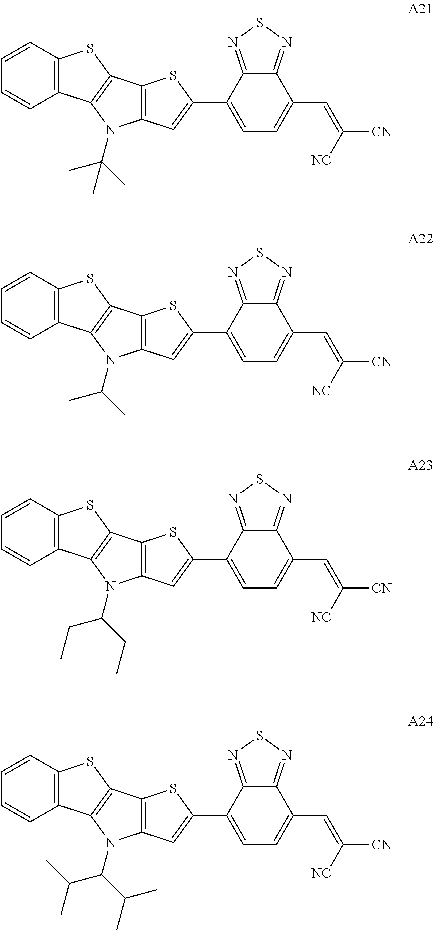 [SMILES: CC(C)(C)n1c2cc(-c3ccc(C=C(C#N)C#N)c4nsnc34)sc2c2sc3ccccc3c21 ; CC(C)n1c2cc(-c3ccc(C=C(C#N)C#N)c4nsnc34)sc2c2sc3ccccc3c21 ; CCC(CC)n1c2cc(-c3ccc(C=C(C#N)C#N)c4nsnc34)sc2c2sc3ccccc3c21 ; CC(C)C(C(C)C)n1c2cc(-c3ccc(C=C(C#N)C#N)c4nsnc34)sc2c2sc3ccccc3c21]

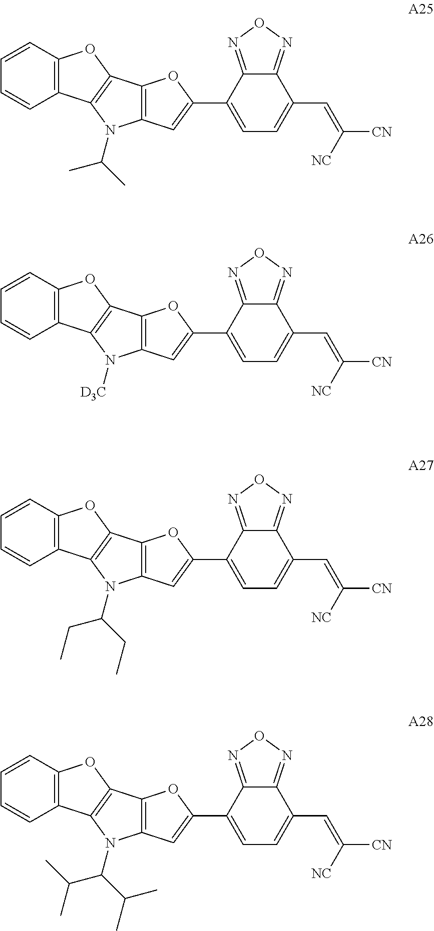 [SMILES: CC(C)n1c2cc(-c3ccc(C=C(C#N)C#N)c4nonc34)oc2c2oc3ccccc3c21 ; [2H]C([2H])([2H])n1c2cc(-c3ccc(C=C(C#N)C#N)c4nonc34)oc2c2oc3ccccc3c21 ; CCC(CC)n1c2cc(-c3ccc(C=C(C#N)C#N)c4nonc34)oc2c2oc3ccccc3c21 ; CC(C)C(C(C)C)n1c2cc(-c3ccc(C=C(C#N)C#N)c4nonc34)oc2c2oc3ccccc3c21]

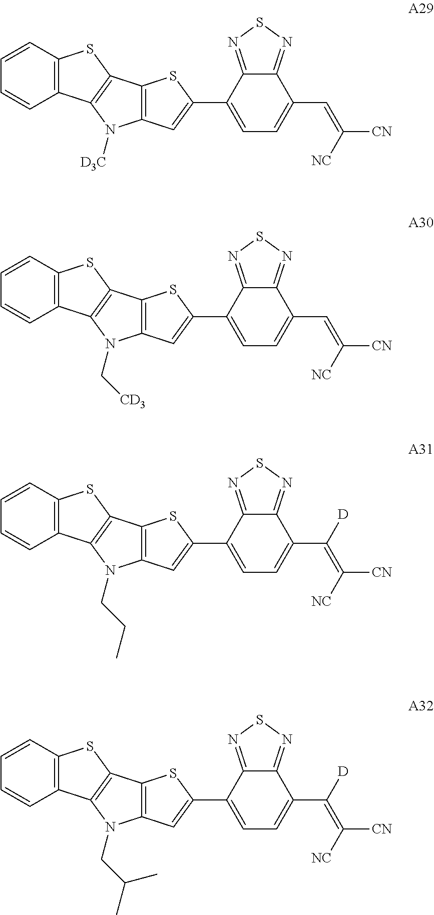 [SMILES: [2H]C([2H])([2H])n1c2cc(-c3ccc(C=C(C#N)C#N)c4nsnc34)sc2c2sc3ccccc3c21 ; [2H]C([2H])([2H])Cn1c2cc(-c3ccc(C=C(C#N)C#N)c4nsnc34)sc2c2sc3ccccc3c21 ; [2H]C(=C(C#N)C#N)c1ccc(-c2cc3c(s2)c2sc4ccccc4c2n3CCC)c2nsnc12 ; [2H]C(=C(C#N)C#N)c1ccc(-c2cc3c(s2)c2sc4ccccc4c2n3CC(C)C)c2nsnc12]

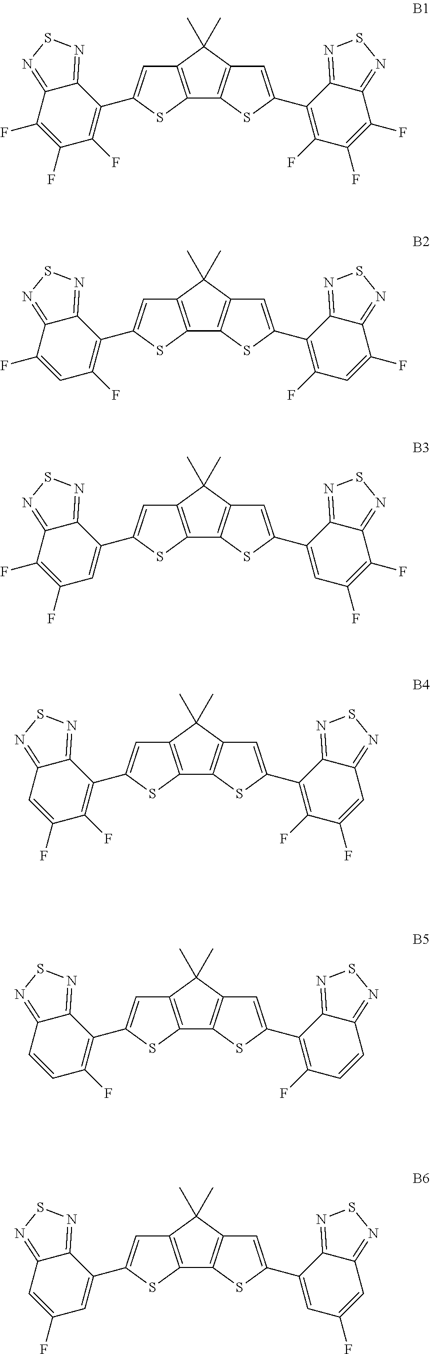 [SMILES: CC1(C)c2cc(-c3c(F)c(F)c(F)c4nsnc34)sc2-c2sc(-c3c(F)c(F)c(F)c4nsnc34)cc21 ; CC1(C)c2cc(-c3c(F)cc(F)c4nsnc34)sc2-c2sc(-c3c(F)cc(F)c4nsnc34)cc21 ; CC1(C)c2cc(-c3cc(F)c(F)c4nsnc34)sc2-c2sc(-c3cc(F)c(F)c4nsnc34)cc21 ; CC1(C)c2cc(-c3c(F)c(F)cc4nsnc34)sc2-c2sc(-c3c(F)c(F)cc4nsnc34)cc21 ; CC1(C)c2cc(-c3c(F)ccc4nsnc34)sc2-c2sc(-c3c(F)ccc4nsnc34)cc21 ; CC1(C)c2cc(-c3cc(F)cc4nsnc34)sc2-c2sc(-c3cc(F)cc4nsnc34)cc21]

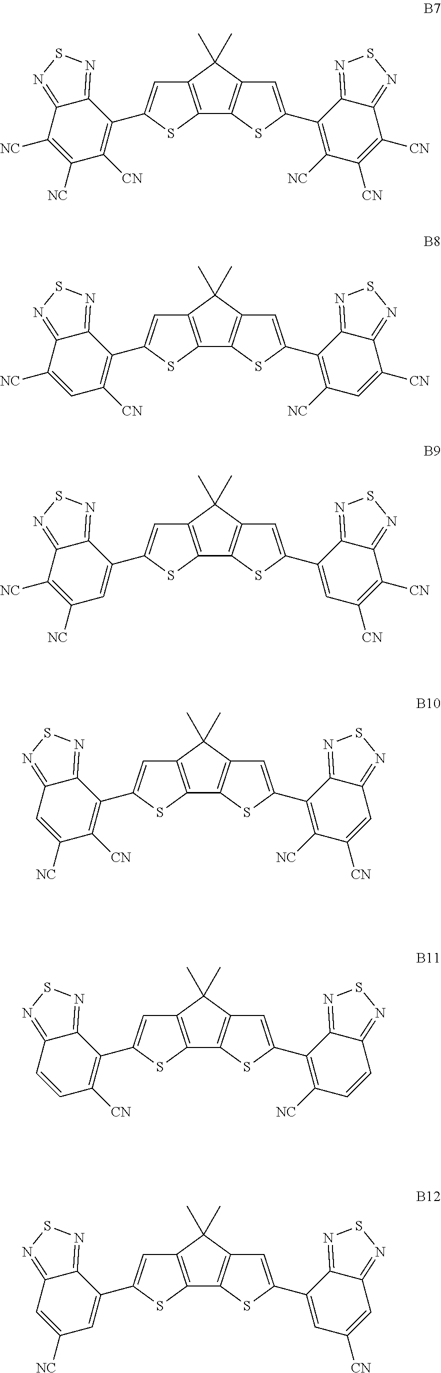 [SMILES: CC1(C)c2cc(-c3c(C#N)c(C#N)c(C#N)c4nsnc34)sc2-c2sc(-c3c(C#N)c(C#N)c(C#N)c4nsnc34)cc21 ; CC1(C)c2cc(-c3c(C#N)cc(C#N)c4nsnc34)sc2-c2sc(-c3c(C#N)cc(C#N)c4nsnc34)cc21 ; CC1(C)c2cc(-c3cc(C#N)c(C#N)c4nsnc34)sc2-c2sc(-c3cc(C#N)c(C#N)c4nsnc34)cc21 ; CC1(C)c2cc(-c3c(C#N)c(C#N)cc4nsnc34)sc2-c2sc(-c3c(C#N)c(C#N)cc4nsnc34)cc21 ; CC1(C)c2cc(-c3c(C#N)ccc4nsnc34)sc2-c2sc(-c3c(C#N)ccc4nsnc34)cc21 ; CC1(C)c2cc(-c3cc(C#N)cc4nsnc34)sc2-c2sc(-c3cc(C#N)cc4nsnc34)cc21]

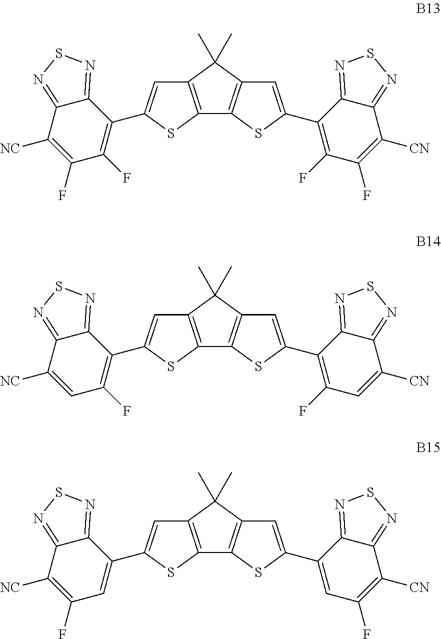 [SMILES: CC1(C)c2cc(-c3c(F)c(F)c(C#N)c4nsnc34)sc2-c2sc(-c3c(F)c(F)c(C#N)c4nsnc34)cc21 ; CC1(C)c2cc(-c3c(F)cc(C#N)c4nsnc34)sc2-c2sc(-c3c(F)cc(C#N)c4nsnc34)cc21 ; CC1(C)c2cc(-c3cc(F)c(C#N)c4nsnc34)sc2-c2sc(-c3cc(F)c(C#N)c4nsnc34)cc21]

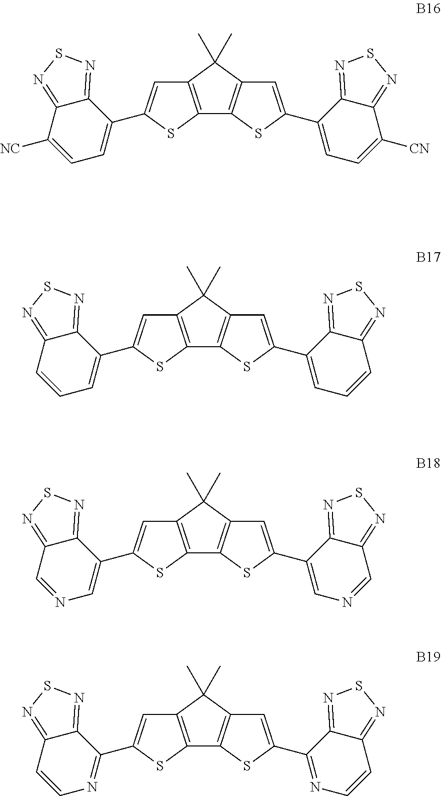 [SMILES: CC1(C)c2cc(-c3ccc(C#N)c4nsnc34)sc2-c2sc(-c3ccc(C#N)c4nsnc34)cc21 ; CC1(C)c2cc(-c3cccc4nsnc34)sc2-c2sc(-c3cccc4nsnc34)cc21 ; CC1(C)c2cc(-c3cncc4nsnc34)sc2-c2sc(-c3cncc4nsnc34)cc21 ; CC1(C)c2cc(-c3nccc4nsnc34)sc2-c2sc(-c3nccc4nsnc34)cc21]

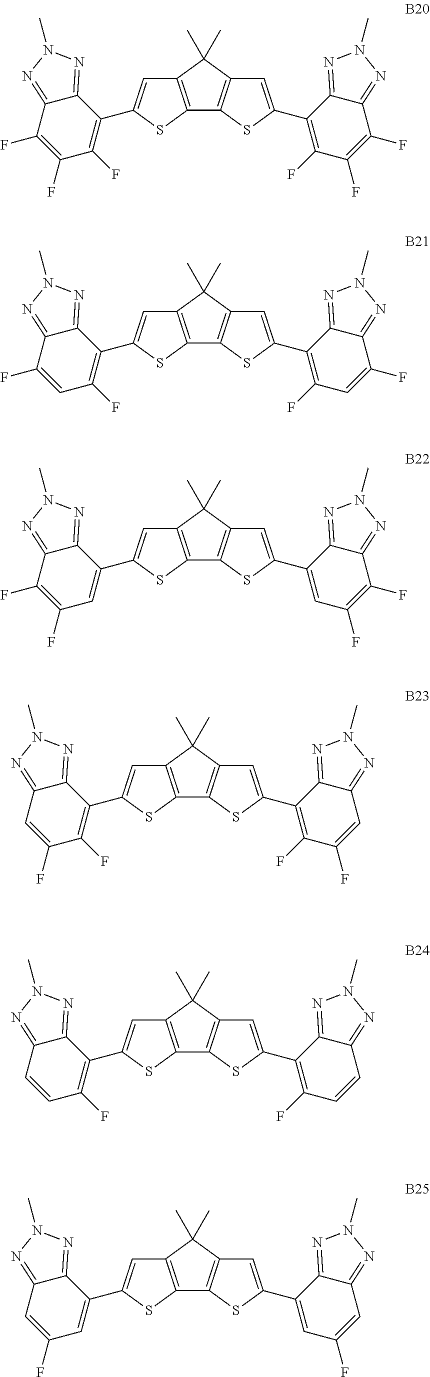 [SMILES: Cn1nc2c(F)c(F)c(F)c(-c3cc4c(s3)-c3sc(-c5c(F)c(F)c(F)c6nn(C)nc56)cc3C4(C)C)c2n1 ; Cn1nc2c(F)cc(F)c(-c3cc4c(s3)-c3sc(-c5c(F)cc(F)c6nn(C)nc56)cc3C4(C)C)c2n1 ; Cn1nc2c(-c3cc4c(s3)-c3sc(-c5cc(F)c(F)c6nn(C)nc56)cc3C4(C)C)cc(F)c(F)c2n1 ; Cn1nc2cc(F)c(F)c(-c3cc4c(s3)-c3sc(-c5c(F)c(F)cc6nn(C)nc56)cc3C4(C)C)c2n1 ; Cn1nc2ccc(F)c(-c3cc4c(s3)-c3sc(-c5c(F)ccc6nn(C)nc56)cc3C4(C)C)c2n1 ; Cn1nc2cc(F)cc(-c3cc4c(s3)-c3sc(-c5cc(F)cc6nn(C)nc56)cc3C4(C)C)c2n1]

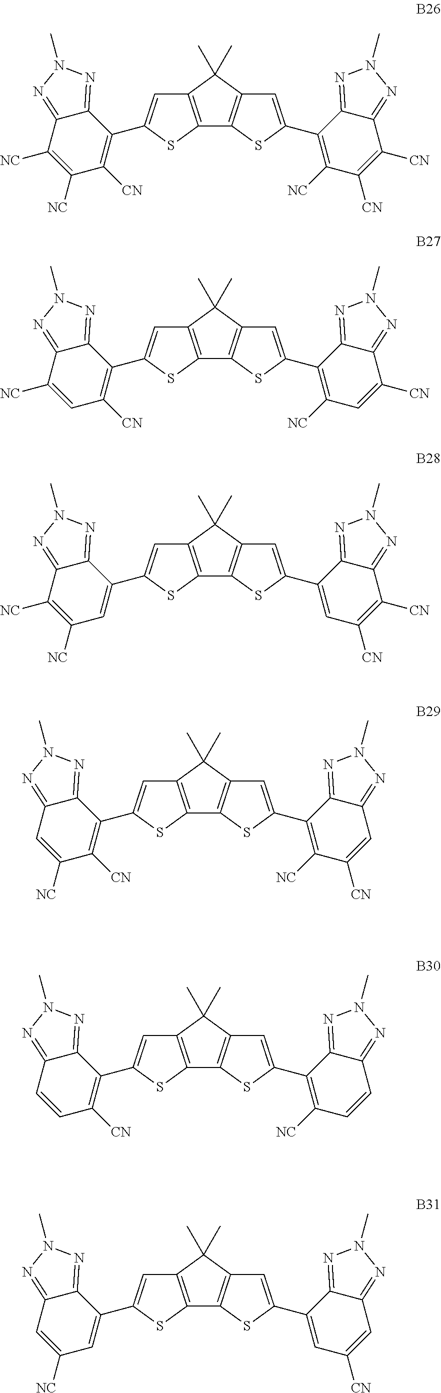 [SMILES: Cn1nc2c(C#N)c(C#N)c(C#N)c(-c3cc4c(s3)-c3sc(-c5c(C#N)c(C#N)c(C#N)c6nn(C)nc56)cc3C4(C)C)c2n1 ; Cn1nc2c(C#N)cc(C#N)c(-c3cc4c(s3)-c3sc(-c5c(C#N)cc(C#N)c6nn(C)nc56)cc3C4(C)C)c2n1 ; Cn1nc2c(-c3cc4c(s3)-c3sc(-c5cc(C#N)c(C#N)c6nn(C)nc56)cc3C4(C)C)cc(C#N)c(C#N)c2n1 ; Cn1nc2cc(C#N)c(C#N)c(-c3cc4c(s3)-c3sc(-c5c(C#N)c(C#N)cc6nn(C)nc56)cc3C4(C)C)c2n1 ; Cn1nc2ccc(C#N)c(-c3cc4c(s3)-c3sc(-c5c(C#N)ccc6nn(C)nc56)cc3C4(C)C)c2n1 ; Cn1nc2cc(C#N)cc(-c3cc4c(s3)-c3sc(-c5cc(C#N)cc6nn(C)nc56)cc3C4(C)C)c2n1]

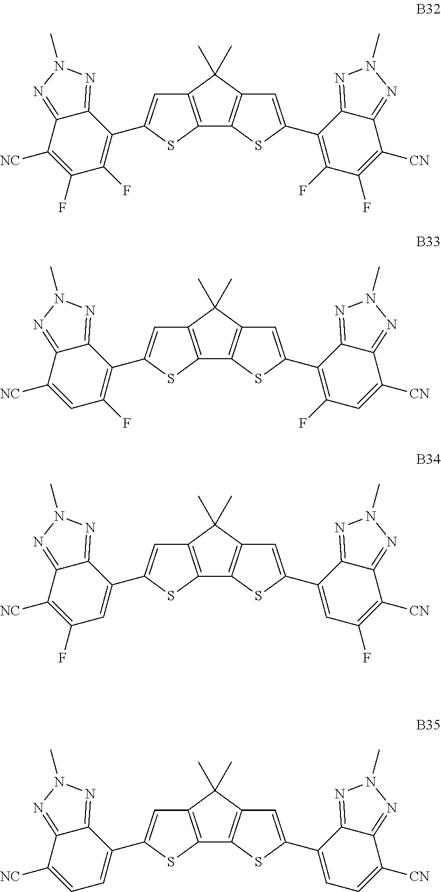 [SMILES: Cn1nc2c(C#N)c(F)c(F)c(-c3cc4c(s3)-c3sc(-c5c(F)c(F)c(C#N)c6nn(C)nc56)cc3C4(C)C)c2n1 ; Cn1nc2c(C#N)cc(F)c(-c3cc4c(s3)-c3sc(-c5c(F)cc(C#N)c6nn(C)nc56)cc3C4(C)C)c2n1 ; Cn1nc2c(-c3cc4c(s3)-c3sc(-c5cc(F)c(C#N)c6nn(C)nc56)cc3C4(C)C)cc(F)c(C#N)c2n1 ; Cn1nc2c(C#N)ccc(-c3cc4c(s3)-c3sc(-c5ccc(C#N)c6nn(C)nc56)cc3C4(C)C)c2n1]

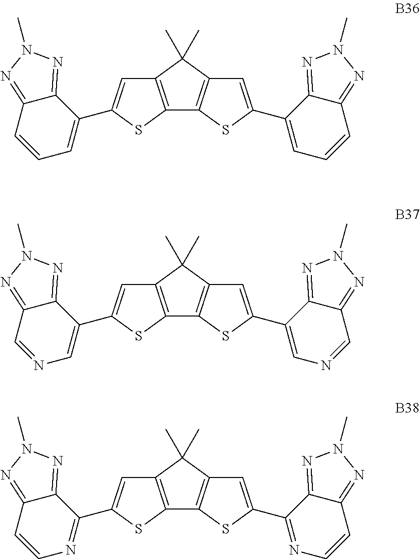 [SMILES: Cn1nc2cccc(-c3cc4c(s3)-c3sc(-c5cccc6nn(C)nc56)cc3C4(C)C)c2n1 ; Cn1nc2cncc(-c3cc4c(s3)-c3sc(-c5cncc6nn(C)nc56)cc3C4(C)C)c2n1 ; Cn1nc2ccnc(-c3cc4c(s3)-c3sc(-c5nccc6nn(C)nc56)cc3C4(C)C)c2n1]

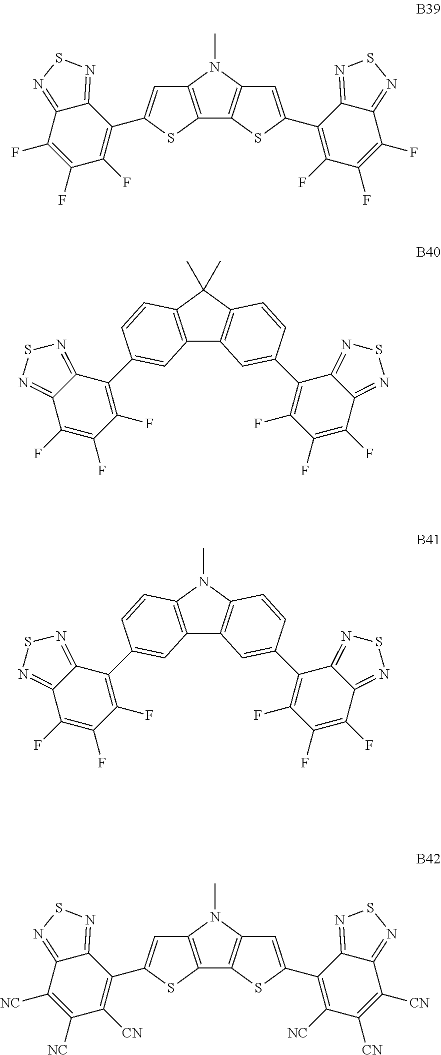 [SMILES: Cn1c2cc(-c3c(F)c(F)c(F)c4nsnc34)sc2c2sc(-c3c(F)c(F)c(F)c4nsnc34)cc21 ; CC1(C)c2ccc(-c3c(F)c(F)c(F)c4nsnc34)cc2-c2cc(-c3c(F)c(F)c(F)c4nsnc34)ccc21 ; Cn1c2ccc(-c3c(F)c(F)c(F)c4nsnc34)cc2c2cc(-c3c(F)c(F)c(F)c4nsnc34)ccc21 ; Cn1c2cc(-c3c(C#N)c(C#N)c(C#N)c4nsnc34)sc2c2sc(-c3c(C#N)c(C#N)c(C#N)c4nsnc34)cc21]

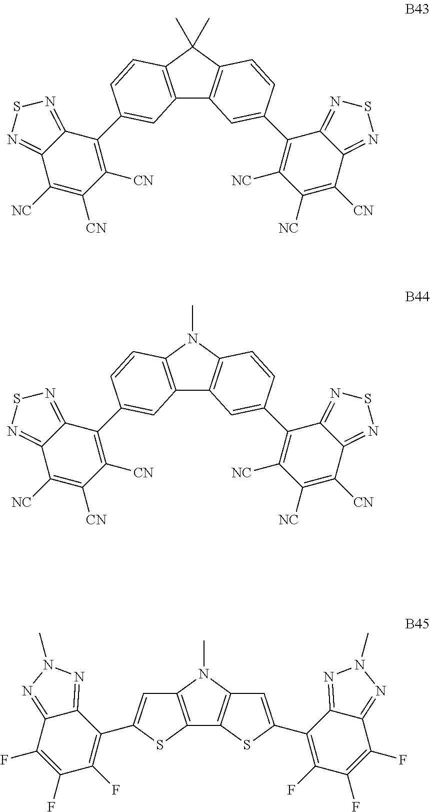 [SMILES: CC1(C)c2ccc(-c3c(C#N)c(C#N)c(C#N)c4nsnc34)cc2-c2cc(-c3c(C#N)c(C#N)c(C#N)c4nsnc34)ccc21 ; Cn1c2ccc(-c3c(C#N)c(C#N)c(C#N)c4nsnc34)cc2c2cc(-c3c(C#N)c(C#N)c(C#N)c4nsnc34)ccc21 ; Cn1nc2c(F)c(F)c(F)c(-c3cc4c(s3)c3sc(-c5c(F)c(F)c(F)c6nn(C)nc56)cc3n4C)c2n1]

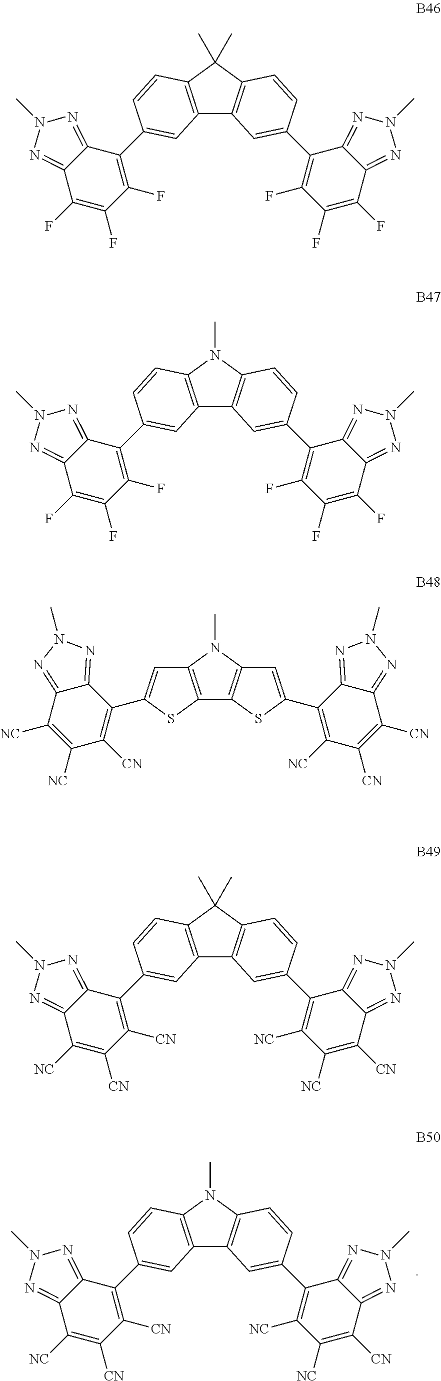

14. The optoelectronic device of claim 1, wherein the photoactive layer is a vacuum deposited photoactive layer.

15. The optoelectronic device of claim 1, wherein the photoactive layer is a single layer.

16. The optoelectronic device of claim 1, further comprising:
a hole transport region between the first electrode and the photoactive layer; and
an electron transport region between the photoactive layer and the second electrode.

17. The optoelectronic device of claim 16, wherein the photoactive layer comprises:
a first layer adjacent to the hole transport region; and
a second layer adjacent to the electron transport region,
the first layer comprising the donor, and
the second layer comprising the acceptor.

18. The optoelectronic device of claim 17, wherein the photoactive layer further comprises a third layer between the first layer and the second layer, the third layer comprising the donor and the acceptor.

19. An electronic apparatus comprising:
the optoelectronic device of claim 1; and
a light-emitting device comprising an emission layer which does not overlap with the photoactive layer.

20. An electronic equipment comprising the electronic apparatus of claim 19,
wherein the electronic equipment is at least one selected from a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, a signboard, and combinations thereof.
